(19) United States
(12) Patent Application Publication
(10) Pub. No.: US 2026/0258297 A1
(43) Pub. Date: Sep. 3, 2026

(54) Transformative synthesis of semiconductor nanoclusters with atomic precision via metal-ligand coordination exchange

(71) Applicant: University of Florida Research Foundation, Incorporated, Gainesville, FL (US)

(72) Inventors: Chenjie ZENG, Gainesville, FL (US); Fuyan MA, Gainesville, FL (US)

(21) Appl. No.: 19/394,820

(22) Filed: Nov. 19, 2025

Related U.S. Application Data
(63) Continuation-in-part of application No. PCT/US2024/030202, filed on May 20, 2024.
(60) Provisional application No. 63/467,627, filed on May 19, 2023.
(60) Provisional application No. 63/528,453, filed on Jul. 24, 2023.

(51) Int. Cl. C09K 11/61; C09K 11/88; C09K 11/89; H10F 77/14; H10H 20/851

(52) U.S. Cl. CPC C09K 11/612; C09K 11/883; C09K 11/892; H10F 77/1433; H10H 20/8512

(57) ABSTRACT

Precision nanosynthesis is crucial for atomic engineering in nanostructures and mechanistic understanding of nanoscale reactions. But it is a daunting task due to emerging complexities in nanostructures and nanosynthesis. Here, we report the precision synthesis of semiconductor nanocluster via synergizing coordination, cluster, and colloidal chemistry at the nanoscale. In particular, by employing Cu₂₆Se₁₃(PEt₂Ph)₁₄ cluster and CdI₂(PPr₃)₂ coordination complex as precise precursors in colloidal cation exchange reaction, an atomically precise Cd₂₆Se₁₇I₁₈(PPr₃)₁₀ cluster is produced at near-unity yield. X-ray crystallography reveals that the child CdSe cluster inherits its icosahedral-packed anion lattice and halide-phosphine-rich surface from parent cluster and complex respectively and further evolves into an enlarged structure. The hybridization of achiral precursors leads to chiral CdSe clusters co-crystallized as a 1:1 mixture of enantiomers. In-situ optical spectroscopy unveils that the reaction proceeds with well-defined pathways. Based on charge and coordination conservations, the structure of child cluster can be atomically linked to precursors via a series of transformations including surface coordination exchange, intra-cluster reorganization, and inter-cluster digestive ripening. The precision nanosynthesis with atomically defined precursors, pathways, and products is expected to further rationalize and diversify nanochemistry.

### BACKGROUND

Semiconductor nanocrystals, also known as quantum dots (QDs), are important building blocks for energy and information technologies^{1,2}. Despite significant advancements in the past three decades³⁻⁵, a major challenge in QD synthesis is their polydisperse sizes and inhomogeneous structures (especially at the surface)⁶. Synthesizing QDs with homogeneous sizes and structures is important to further enhance the performance of QD-based devices, such as consistent emissions in light-emitting diodes, coherent charge transport in field-effect transistors, and uniform fields for quantum computing.^{1,2,7} It is also essential for the fundamental understanding of structure-property correlations, such as size- and surface-dependent absorption and emission properties^{6,8}.

Atomically precise nanoclusters are ultrasmall nanocrystals (~1 nm to ~3 nm) with identical core, interface, and surface structures⁹. These clusters can self-assemble into single crystals with translational, orientational, and rotational orders¹⁰. Thus, the total structure of clusters (core and surface) and their assembly can be determined by single-crystal X-ray diffraction (sc-XRD) at atomic resolution. While the past decades have seen significant advances in atomically precise metal clusters⁹⁻¹², the progress in achieving atomic precision in semiconductor clusters is limited. Compared to metals, binary compound semiconductors contain both cations and anions (e.g., Cd²⁺ and Se²⁻), which leads to more complex precursor conversion¹³, surface coordination¹⁴, and charge balancing^{15,16} issues. In addition, the lability of surface ligands and ionic bonding of the core often result in aggregation or transformation of clusters during the isolation or characterization processes¹⁷. Due to these challenges, only a few structures of semiconductor clusters have been reported, including early works on chalcogenolate-protected CdS and CdSe clusters¹⁸⁻²¹ and recent reports on carboxylate-protected clusters^{22,23}.

In addition to atomic structures, achieving atomic precision in chemical synthesis of nanomaterials is another long pursuing goal in nanochemistry. Akin to molecular synthesis, precision nanosynthesis is crucial for rational constructing of nanostructures, precise tuning of properties, and mechanistic understanding of reactions²⁴. However, extending precision synthesis from molecular scale to nanoscale has been a formidable challenge due to emerging complexity in chemical reactions of nanomaterials²⁵. Compared to a single or a few collision events in a molecular reaction, constructing a nanostructure requires numerous collisions that occur hierarchically at the atomic core, coordination interface, organic surface, and inter-particle levels^{6,14,26,27}. This leads to a broad energy landscape spanning from ~1000 kJ/mol (covalent bonds) to ~1 kJ/mol (intermolecular interactions) as well as entangled kinetics including precursor conversion, nucleation-growth, and ripening.

### BRIEF DESCRIPTION OF DRAWINGS

FIG. 1|Cation exchange reactions across the length scale. a, Reaction of bulk crystal. b, Reaction of nanocrystals with typical conservations in shapes and anion lattices. c, Atomically precise reaction of nanocluster demonstrated in this work, which unveils the cation exchange is accompanied by surface ligand exchange. Yellow/blue/green spheres are anions (E)/original cations (M)/incoming cations (M′); blue/green shades are original ligands (L)/incoming ligands (L′), which includes negatively charged X-type ligands and neutral L-type donors.

FIG. 2A-L|Precise precursors for cation exchange reaction and corresponding characterization of precursor and product clusters. FIG. 2A, Cu₂₆Se₁₃(PEt₂Ph)₁₄ cluster (center) and CdI₂(PPr₃)₂ coordination complexes (periphery) as precise reaction precursors. The structures are determined by X-ray crystallography. FIG. 2B, Shell-by-shell anatomy of Cu₂₆Se₁₃P₁₄ framework viewed along the pseudo C₃ axis (top row) and C₂ axis (bottom row). Superscripts o, i, and ii refer to the core, facet-capping, and edge-bridging Cu⁺ cations respectively. FIG. C-G, Crystals and reaction solution, UV-vis, powder XRD, ¹H NMR, and ³¹P NMR characterization of Cu₂₆Se₁₃(PEt₂Ph)₁₄ cluster, respectively. FIG. 2H-L Corresponding characterization of the exchanged cluster product. The red spectral lines in FIG. 2F and FIG. 2G are obtained at −40° C. (* indicates toluene-d₈ and CDCl₃ solvent peaks).

FIG. 3A-F|Cd₂₆Se₁₇I₁₈(PPr₃)₁₀ as the precise product of cation exchange. FIG. 3A Overall structure. FIG. 3B Shell-by-shell anatomy of Cd₂₆Se₁₇ core viewed from the C₃ axis (top row) and the C₂ axis (bottom row). Superscripts o, i, ii, and iii refer to the core, facet-capping, edge-bridging, and vertex-terminating Cd respectively. FIG. 3C Surface ligand coordination at facet-, edge-, corner-, and all Cd sites, respectively (side view). FIG. 3D-E Chiral structures of left (green) and right (red) enantiomers viewed from top and base, respectively. FIG. 3F Inter-cluster packing structures of enantiomers in the crystal.

FIG. 4A-E|Transformation pathway of cation exchange reaction. FIG. 4A Overall reaction from Cu₂₆Se₁₃(PEt₂Ph)14 to Cd₂₆Se₁₇(PPr₃)₁₀. FIG. 4B-D Reaction process monitored by photos and in-situ UV-vis absorption spectroscopy. FIG. 4E Four stages of the transformation and corresponding reaction intermediates derived based on X-ray structures of precursor and product clusters (viewed from tetrahedron base) following charge and coordination conservations.

FIG. 5A-C|NMR characterization of Cu₂₆Se₁₃(PEt₂Ph)₁₄ clusters. FIG. 5A ³¹P{H}NMR of free PEt₂Ph ligand at room temperature (top) and Cu₂₆Se₁₃(PEt₂Ph)₁₄ cluster at variable temperatures (bottom). Seven peaks of the cluster can be resolved at low-temperature spectrum, matching with seven chemically inequivalent phosphorous (P₁ to P₇) in the crystal structure (left).

FIG. 5B Corresponding ¹H NMR spectra. FIG. 5C ¹H-¹H COSY spectrum of the cluster measured at −40° C. (left) and corresponding 1D spectrum (right). Seven groups of correlated protons in the phenyl group of the PEt₂Ph ligands can be identified. The sample is measured in toluene-d₈. Solvent peaks at 7.09, 6.97-7.01, and 2.08 ppm are labeled by *.

FIG. 6|X-ray crystallographic structure of CdI₂(PPr₃)₂. a, Unit cell structure. b, Tetrahedron coordination of Cd(II) center in individual complex. c, Bond lengths and angles around Cd(II) center.

FIG. 7A-B|MALDI-MS characterization of precursor and product clusters. FIG. 7A Spectrum of Cu₂₆Se₁₃(PEt₂Ph)₁₄ cluster and corresponding assignment of fragmentation peaks. All PEt₂Ph ligands dissociate during the ionization process. The most intense peak is assigned to a dimeric (Cu₂₆Se₁₃)₂Cu fragment. FIG. 7B Spectrum of Cd₂₆Se₁₇I₁₈(PPr₃)₁₀ cluster and corresponding assignment of fragmentation peaks. The cluster framework dissociates during the ionization process and reorganizes into characteristic fragments of CdSe materials.

FIG. 8A-B|Overview of X-ray crystallographic structure of the Cd₂₆Se₁₇I₁₈(PPr₃)₁₀ cluster. FIG. 8A Cd₂₆Se₁₇ core, Cd₂₆Se₁₇I₁₈P₁₀ inorganic framework, and Cd₂₆Se₁₇I₁₈(PPr₃)₁₀ cluster viewed from three orientations. The corresponding sizes are measured based on the atom-to-atom distance along the tetrahedron edge. FIG. 8B Packing and coordination of Se₁₇ anion lattice (top) and Cd₂₆ cation lattice (bottom). The anion lattice features a central icosahedron capped by four apical Se, and the cation lattice can be viewed as four interpenetrating icosahedra. All Se and Cd are tetrahedrally coordinated except for the four apical Se (light yellow). Green: Cd; orange: Se; pink: P; purple: I; grey: C; and white: H.

FIG. 9A-C|NMR characterization of Cd₂₆Se₁₇I₁₈(PPr₃)₁₀ cluster. FIG. 9A ³¹P{¹H} NMR spectra of free PPr₃ ligand, CdI₂(PPr₃)₂ complex, and Cd₂₆Se₁₇I₁₈(PPr₃)₁₀ cluster. A 3:3:3:1 splitting of 10 phosphines is observed for the cluster sample. The satellite peaks observed in both complex and cluster are due to Cd—P couplings. FIG. 9B Corresponding ¹H NMR spectra. FIG. 9C Amplified ¹H NMR spectrum of the cluster at aliphatic region. The four chemically inequivalent phosphine ligands are indicated by numbers (P₁ to P₄), which matches with the C₃ symmetry of the structure (left). The sample is measured in CDCl₃ at room temperature. The solvent peaks are labeled with *.

FIG. 10A-C|The overall transformation reaction. FIG. 10A the reaction between Cu₂₆Se₁₃(PEt₂Ph)₁₄ cluster and CdI₂(PPr₃)₂ complex leads to an atomically precise Cd₂₆Se₁₇I₁₈(PPr₃)₁₀ cluster. FIG. 10B Shell-by-shell structural comparison of the precursors (top) with the product cluster (bottom). FIG. 10C Comparison of Se—Se distances of Se₁₃ icosahedral frameworks in Cu₂₆Se₁₃(PEt₂Ph)₁₄ (left) and Cd₂₆Se₁₇I₁₈(PPr₃)₁₀ (right).

FIG. 11|The origin of chirality in Cd₂₆Se₁₇I₁₈(PPr₃)₁₀ clusters and their chiral packing in the unit cell. a, Adaption of tetrahedral coordination into icosahedral framework induces chirality in the core. Left: icosahedral framework in left Cd₂₆Se₁₇ enantiomer with the Cd—Se bonds leaning to the left against the principal axis. Middle: cuboctahedron in zincblende lattice with vertical alignments of all the Cd—Se bonds. Right: right-leaning Cd—Se bonds in the right Cd₂₆Se₁₇ enantiomer. b, Each unit cell contains two left (dark and light green) and two right (dark and light red) enantiomers. Arrow indicates the direction of the principal C₃ axis. The corresponding orientations of enantiomers are shown in the tetrahedral outlines (right). Solvent molecules (toluene) in the unit cell are omitted for clarity.

FIG. 12|Symmetry breaking induced by surface ligands. The uneven distribution of six phosphines (P atom highlighted in yellow) to four corners of the tetrahedron leads to the symmetry breaking from T to C₃, with three PPr₃ concentrated on the top corner and one PPr₃ on each of the base corners of the tetrahedron.

FIG. 13|Cation exchange reactions with different CdI₂(PR₃)₂ (R=octyl, butyl, propyl, and ethyl) complexes. The same 365 nm (dark blue curves) and 355 nm (light blue curves) intermediates are observed when different phosphines are used in the complex. The 355 nm→372 nm conversion is slower when bulkier phosphine is used. Reaction with CdI₂(PEt₃)₂ leads to aggregation at the end. CdI₂(PPr₃)₂ shows the best results in balancing reaction rates and preventing aggregations. In-situ UV-vis spectra are monitored every 10 minutes in the first hour (left) and every 2 hours for the rest of the reaction (right).

FIG. 14|Cation exchange reaction with different CdX₂(PPr₃)₂ (X=I⁻, Br⁻, Cl⁻) complexes. Compared to the well-defined 365 nm→355 nm→372 nm transitions in CdI₂(PPr₃)₂, the cation exchange reaction using CdBr₂(PPr₃)₂ results in the aggregation of larger and less-defined clusters after around one hour. The aggregation is even faster (within a few minutes) in the case of CdCl₂(PPr₃)₂.

FIG. 15. Transformative synthesis of atomically precise II-VI semiconductor nanoclusters (II=Zn, Cd, Hg; VI=Se). (A) Precise precursors: Cu₂₆Se₁₃(PEt₂Ph)₁₄ cluster (center) as anion template and three MI₂(tmeda) complexes (periphery) as cation carriers. (B) Corresponding reaction schemes. (C-E) Absorption spectra of the product clusters. Dashed line: reaction mixture. Solid line: solution of single crystals in CH₃OH for Zn₁₄Se₁₃, toluene-tmeda for Cd₁₄Se₁₃, and toluene-tmeda for Hg₁₄Se₁₃, respectively. Inset: photos of reaction mixtures and crystals.

FIG. 16. Atomic structures of parent Cu₂₆Se₁₃(PEt₂Ph)₁₄ cluster and child [Zn₁₄Se₁₃(tmeda)₆]²⁺ (1), Cd₁₄Se₁₃(tmeda)₆I₂ (2), Hg₁₄Se₁₃(tmeda)₆I₂ (3) clusters. (A) Overall crystallographic structures. (B) Se₁₃ icosahedral anion lattices. (C) Shell-by-shell assembly of cation and anion polyhedrons. (D) Arrangements of core cations ^{c}M inside Se₁₃ shell. (E) Positions of saturated face-capping cations ^{f}M connected to surface halides and unsaturated face-capping cations ^{f}M without ligands. (F) Arrangement of edge-bridging cations ^{e}M at three orthogonal C₂ axes of the icosahedron. The size difference of II and VI ions is illustrated in the color legend: Se²-(198 pm), Cu⁺ (60 pm), Zn²⁺ (60 pm), Cd²⁺ (78 pm), and Hg²⁺ (96 pm) (71).

FIG. 17. Structural variations of II₁₄VI₁₃ clusters under different synthesis and crystallization conditions. (A-C) Crystal structures of Zn₁₄Se₁₃(tmeda)₆Cl₂ (4), [Cd₁₄Se₁₃(tmeda)₆Cl₂]ₙ (5), and [Hg₁₄Se₁₃(tmeda)₆Cl₂]ₙ (6). The bottom panels highlight the coordination environment of eight dynamic cations. (D-F) Comparison of absorption spectra of six II₁₄VI₁₃ clusters. The Zn₁₄Se₁₃ clusters were measured in CH₃OH. The Cd₁₄Se₁₃ and Hg₁₄Se₁₃ clusters were measured in CH₂Cl₂ with the presence of tmeda.

FIG. 18. Optical properties of II₁₄VI₁₃ clusters. (A) Absorption spectra of clusters 1-3 plotted in energy scale. (B) Plots of first (E₁) and second (E₂) exciton transition energy of M14Se₁₃ clusters against corresponding bulk band gap (E_{g}), with linear fittings of E₁=0.655 E_{g}+2.411 and E₂=0.687 E_{g}+2.619.

FIG. 19. ¹H NMR of free tmeda ligand and three MI₂(tmeda) complexes (M=Zn, Cd, Hg) in CDCl₃. The satellite peaks in CdI₂(tmeda) corresponding to the coupling between ¹H and ¹¹³Cd (J=90 Hz).

FIG. 20A-C. Transformative synthesis of II-VI nanoclusters from Cu₂₆Se₁₃ template cluster and MI₂(tmeda) cation carriers (M=Zn, Cd, Hg). (FIG. 20A) Reaction with ZnI₂(tmeda). (FIG. 20B) Reaction with CdI₂(tmeda) using excess PPr₃ to increase its solubility in toluene. (FIG. 20C) Reaction with HgI₂ and excess tmeda. The initial color changes of the reaction mixtures are shown in the photos (left). The reaction mixture was then diluted and monitored by in-situ UV-Vis spectroscopy (right). The in-situ spectra were recorded every 10 minutes in the first two hours and every one hour for the rest of the time.

FIG. 21. Crystal structures of transformed II-VI clusters and their packing in unit cells. (A) [Zn₁₄Se₁₃(tmeda)₆]²⁺ cluster co-crystallized [BPh₄] counterions and CH₂Cl₂ solvent molecules. Each unit cell contains two whole clusters and four counterions with balanced charges. The counterions and solvent molecules are sandwiched between two layers of clusters. (B) Cd₁₄Se₁₃(tmeda)₆I₂ cluster co-crystallized with one CdI₂(tmeda) complex and several toluene molecules. (C) Hg₁₄Se₁₃(tmeda)₆I₂ cluster. Top: individual cluster; middle: top view of unit cell; bottom: side view of unit cell. The cations are drawn in space-filling mode to highlight the orientation of clusters in unit cells.

FIG. 22 Comparison of Se₁₃ anion lattices of parent and child clusters. Se—Se distances in Se₁₃ icosahedral frameworks are compared among the parent Cu₂₆Se₁₃(PEt₂Ph)₁₄ cluster and three child clusters: [Zn₁₄Se₁₃(tmeda)₆]²⁺, Cd₁₄Se₁₃(tmeda)₆I₂, and Hg₁₄Se₁₃(tmeda)₆I₂ (unit: Å). Top: peripheral Se—Se distances; middle: radial Se—Se distances; bottom: tabulated comparison with corresponding Se—Se distances in bulk lattices.

FIG. 23. Synthesis and crystal structure of Zn₁₄Se₁₃(tmeda)₆Cl₂ cluster (4). (A) Reaction scheme. (B) Corresponding UV-Vis spectra. The crystals were dissolved in CH₃OH for measurement. The E₂ peak was slightly affected by the absorption of CH₂Cl₂ (measured in CH₃OH). Inset: crystal blocks with nearly square shape. (C) Crystal structure of individual cluster. (D) Unit cell structure of the cluster with surrounding CH₂Cl₂ solvent molecules. Left: top view along c axis; right: side view from bc plane.

FIG. 24. Synthesis and crystal structure of [Cd₁₄Se₁₃(tmeda)₆Cl₂]ₙ cluster (5). (A) Reaction scheme. (B) Corresponding UV-Vis spectra. The crystals were dissolved in CH₂Cl₂ with the presence of tmeda. The two peaks are at 354 and 328 nm in both spectra. Inset: Crystals with the shapes of triangular plates. (C) Crystal structure of the individual cluster, featuring four bridging chlorides. Each chloride is shared by two clusters, giving the overall composition of Cd₁₄Se₁₃(tmeda)₆Cl₂. (D) Unit cell structure of the cluster viewed along the body diagonal of the cube (left) and along a axis (right). Inter-cluster connection is built through Cl⁻ tetrahedrally, forming the extended 3D network. The chlorides are shown in space-filling mode to highlight the connection pattern.

FIG. 25. Synthesis and crystal structure of [Hg₁₄Se₁₃(tmeda)₆Cl₂]ₙ cluster (6). (A) Reaction scheme. (B) Corresponding UV-Vis spectra. The crystals were dissolved in CH₂Cl₂ with the assistance of tmeda. Inset: Yellow crystals as thin rods. (C) Crystal structure of the individual cluster. (D) Unit cell structures of the cluster viewed from ab plane (left) and ac plane with only one chain displayed (right). Each cluster features one terminal chloride and two bridging chlorides. Each bridging chloride is shared by two clusters, giving the overall composition of Hg₁₄Se₁₃(tmeda)₆Cl₂ and inter-connected polymeric structure along the a axis. The chlorides are shown in space-filling mode to highlight the connection pattern.

FIG. 26. Synthesis and crystal structure of [Zn₁₄Se₁₃(tmeda)₆(CH₃CN)]²⁺ cluster (7) crystallized from CH₃CN. (A) Reaction scheme. (B) Corresponding UV-Vis spectra. After precipitation, the crude cluster was redissolved in CH₃CN for crystallization. The E₂ peak was better resolved when using CH₃OH as solvent, showing two peaks at 288 nm and 270 nm. The obtained crystals were also dissolved in CH₃OH. Inset: crystals as rhombic blocks. (C) The crystal structure of the cluster is co-crystallized with two equivalent of [BPh₄]⁻ ions and one CH₃CN solvent molecule. (D) Unit cell structure of the cluster viewed along c axis (left) and from bc plane (right).

FIG. 27. Synthesis and crystal structure of Cd₁₄Se₁₃(tmeda)₆I₂ cluster (8) crystallized from CH₂Cl₂. (A) Reaction scheme. (B) Corresponding UV-Vis spectra. The crystal solution was made in CH₂Cl₂ with the presence of tmeda. The two peaks are at 355 and 329 nm in both spectra. Inset: rhombic shaped crystals. (C) The crystal structure of the product as a mixture of two cluster components with different occupancy factors: 75% of [Cd₁₄Se₁₃(tmeda)₆]²⁺ and 25% of [Cd₁₄Se₁₃(tmeda)₆I₈]⁶⁻. (D) Unit cell structure of the cluster viewed along c axis (left) and from ac plane (right).

FIG. 28. Structural variations of Cd₁₄Se₁₃ and Zn₁₄Se₁₃ clusters induced by solvents. (A) Top: overall crystal structures of [Zn₁₄Se₁₃(tmeda)₆]²⁺ and [Zn₁₄Se₁₃(tmeda)₆(CH₃CN)]²⁺; bottom: the arrangement of core and/or face-capping cations. (B) Comparison of UV-Vis spectra for three Zn₁₄Se₁₃ clusters measured on crystal solutions in CH₃OH. (C) The corresponding structural analysis for [Cd₁₄Se₁₃(tmeda)₆]²⁺ and [Cd₁₄Se₁₃(tmeda)₆I₈]⁶⁻. (D) The comparison of UV-Vis spectra for three Cd₁₄Se₁₃ clusters measured on crystal solutions CH₂Cl₂ with the presence of tmeda.

FIG. 29. The comparison of the linear fittings of E₁ energy to bulk band gap of II-VI clusters in literature and this work. The E₁ peak positions of (CdS)₁₃ (CdTe)₁₃, (CdSe)₁₃, (ZnTe)₁₃, and (ZnSe)₁₃ are extracted from ref. (13, 14). The trendlines share similar slopes: 0.655 (black) and 0.679 (orange).

FIG. 30. Provides a diagram of multiple reactions for producing clusters.

### DETAILED DESCRIPTION

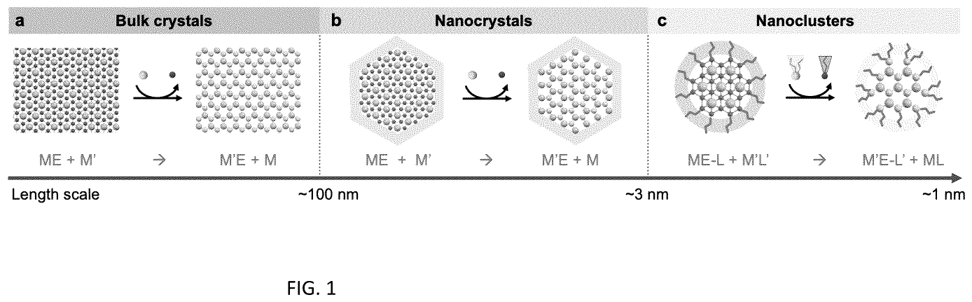

Presented herein embodiments related to precision synthesis of semiconductor nanoclusters involving atomically defined precursors, pathways and products via synergizing colloidal, cluster, and coordination chemistry in the reaction. Typically, cation exchange is selected as a model reaction, inspired by its recent advances in the synthesis of colloidal ionic nanocrystals²⁸⁻³¹ as well as previous success in the transformative synthesis of atomically precise metal clusters^{32,33}. Compared to de novo synthesis with entangled processes, cation exchange provides a facile pathway for compound nanostructures by fixing the anion framework (E) in the template (ME) and exchanging cations (M to M′, FIG. 1a), as shown by early work of solid-state transformation of bulk single crystals (e.g., CdS→Cu₂S)³⁴⁻³⁶. Since its introduction to nanocrystal synthesis (e.g., Ag₂Se↔CdSe)^{37,38}, cation exchange has become a versatile method to access nanocrystals with novel shapes, phases, and heterostructures³⁹⁻⁴⁶. The rigidity of the anion lattices leads to the typical preservation of sizes, shapes, and phases of nanocrystals after transformation (FIG. 1b)³⁹⁻⁴⁶. Despite the advances, atomic insights into the reaction mechanism, especially surface reaction, were still lacking²⁸. Extending cation exchange to clusters has been challenging due to the difficulties to characterize ultrasmall clusters using conventional methods such as powder XRD and electron microscope^{47,48}.

To realize atomic precision in cation exchange reaction (e.g., Cu₂Se→CdSe), atomically defined clusters and coordination complexes were developed as precise precursors for the host anion template (Cu₂Se) and incoming cation carrier (Cd²⁺), respectively (FIG. 1c). The reaction successfully produces an atomically precise CdSe cluster with near-unity conversion yield. The crystallographic structures of precursors and product provide atomic evidence that the anion lattice of the ultrasmall cluster can be preserved during the conversion and unveil that cation exchange is accompanied by surface ligand exchange (FIG. 1c). The precise conversion enables the synthesis of novel CdSe cluster with chiral core (icosahedron-based tetrahedron) and polar surface (halide and phosphine protection). Together with in-situ absorption spectra of the reaction, the precise reaction pathway can be mapped to provide atomic insights into the mechanism of cation exchange and subsequent conversion processes.

Based on the teachings herein, embodiments of the invention may synthesize atomically precise nanoclusters with controllable sizes, shapes, compositions, surface ligands, dopants, and heterostructures.

In certain embodiments, the methods provided herein can provide predictable sizes of nanoclusters as reaction products, typically ranging from 1 nm to 3 nm. For example, 1.1 nm Cd₂₆Se₁₇ (demonstrated). The sizes of product clusters can be tuned by using different templating clusters. Because of its rigidity, the anion framework in the templating cluster can be preserved during cation exchange. Therefore, the core size of the product clusters can be controlled by the choice of templating clusters. Other than Cu₂₆Se₁₃(PEt₂Ph)₁₄ cluster, the reported collection of Cu₂Se clusters provide variable sources of anion frameworks. For example, Cu₄₄Se₂₂(PEt₂Ph)₁₈ cluster has an ellipsoidal shape with a length of ~1.1 nm. Another cluster, Cu₇₀Se₃₅(PEt₂Ph)₂₄, is a triangular plate with an edge of ~1.6 nm and a thickness of ~0.7 nm. In this way, semiconductor nanoclusters can be synthesized with predictable core sizes.

Moreover, shapes of the synthesized nanocluster reaction product can be controlled and include tetrahedrons (demonstrated in Cd₂₆Se₁₇), spheres, and triangular plates. Similar to the sizes, the shapes of the nanocluster reaction product can be adjusted by the shapes of the templating clusters.

Cations used in the transformation reactions may include Cd²⁺, Zn²⁺, Hg²⁺, Pb²⁺ and other transition metals, as well as other metals such as Indium and Gallium, to access various metal chalcogenide nanoclusters. Atomically precise nanoclusters with different core compositions can be obtained using the corresponding metal complexes. With the presence of a soft Lewis base such as phosphine, Cu(I) ions in the template cluster can be extracted and replaced by incoming cations to form the new compositions. In addition to Cd(II) ions, other metal precursors such as Zn(II), Hg(II), Pb(II), and various transition metal complexes could also replace the original Cu(I) cations and lead to ZnSe, HgSe, PbSe, and other metal selenide nanoclusters, respectively. By exchanging with various cations, the core composition can be further diversified to show various properties. Anions utilized in the templating clusters may include S²⁻ and Te²⁻, other than Se²⁻.

As is described further herein, the templating clusters may also comprise one or more surface ligands, and typically the coordination complex will comprise different surface ligands and carry them into the product clusters. Examples of suitable surface ligands include but are not limited to, halides, phosphines, amines, carboxylates, carbenes, and the like. Surface modification is important for tuning the chemical (stability and solubility), optical (absorption and emission), electronic (charge transport), and catalytical properties of semiconductor nanoclusters. Therefore, controlling the surface structure is critical for applications in LEDs, solar cells, photocatalysis, etc. As demonstrated herein for the transformation of Cu₂₆Se₁₃(PEt₂Ph₃)₁₄ cluster into a Cd₂₆Se₁₇I₁₈(PPr₃)₁₀ cluster via cation exchange with a CdI₂(PPr₃)₂ coordination complex, the capping ligands of the product cluster are inclusively inherited from the incoming metal complex. Thus, the surface passivating ligands of nanocluster can be tailored by altering ligands in the metal complex. For instance, tetramethylethylenediamine can be introduced as a replacement for the neutral phosphine ligand. As for the anionic ligand, carboxylate could take the position of iodide to balance the charge as well as protect the core.

The templating clusters may also include one or more dopants, such as, but not limited to Mn²⁺. Doping with extraneous cations can also be achieved by cation exchange to tune the properties of semiconductor nanoclusters. Although doping has been widely utilized in conventional quantum dots, it is challenging to control and characterize the precise concentrations and positions of dopants. Cation exchange provides an efficient pathway to achieve homogeneous doping, therefore enabling the precise control of dopant concentrations and positions. For example, extraneous metal complex Mn(II) and host metal complex of Cd(II) can be pre-mixed to react with the cluster template. Dopant concentration and reactivity can be adjusted by changing the ratio of cations or the ligands of the complexes. The positions of dopants in the core framework will be determined by the thermodynamically favored arrangements depending on the strength of host cation-ligand interactions.

Nanocluster with heterostructures could be obtained as cation exchange reaction products, i.e., core-shell structure (such as CdSe core and ZnSe/ZnS shell). Heterostructures are important for improving the photoluminescent efficiency and the stability of semiconductor clusters. Similar to the synthesis of colloidal heterostructures, precise core/shell clusters can also be realized by sequential cation exchange. For example, Cu₂Se cluster will first be converted to CdSe cluster, followed by exchange with Zn(II) complex to replace surface Cd(II). The reaction can be limited on the surface by controlling the amounts and reactivity of the Zn(II) complex.

### Advantages

Cation exchange between clusters and metal complexes is a transformative approach to synthesizing atomically precise semiconductor nanoclusters. As compared to de novo synthesis from molecular precursors, the disclosed method circumvents a series of obstacles in the synthetic system, including the identification of metal and chalcogenide sources, control of reactivities, precursor conversion, nucleation, growth kinetics, size distribution, etc. Cation exchange will be developed into a versatile tool for a library of atomically precise semiconductor nanoclusters with various sizes, shapes, core compositions, surface ligands, and dopants.

### Potential Applications

Photoluminescent emission for light-emitting diodes (e.g., ZnS/CdSe core/shell clusters)
Building blocks for solution-processible solar cells (e.g., PbSe clusters)
Photocatalysis (e.g., CdSe clusters)
Chiral optics

According to certain method embodiments, disclosed is a method for precision synthesis of nanoclusters that involves mixing a templating nanocluster comprising a plurality of each of Cat¹-An¹-L¹, wherein Cat¹ is Cu(I) or Ag(I), An¹ is selected from S, Se, or Te, and L¹ is a surface ligand, with a coordination complex comprising a Cat²-X²-L², wherein Cat² is selected from Cd²⁺, Zn²⁺, Pb²⁺, Hg²⁺, or other transitional metal cations or other metal cations but, optionally, not Cat¹, X² is selected from halides, carboxylates, thiolates, and other anionic ligands, and L² is a neutral ligand, under conditions to form a nanocluster as reaction product that comprises Cat², An¹, X², and L². In a specific embodiment, L¹ is usually a phosphine, including PEt₃, PBu₃, PEt₂Ph, etc. In another specific embodiment, L² is selected from phosphines (PEt₃, PPr₃, PBu₃, P(octyl)₃), amines, carbenes, alcohol, or other neutral ligands. In a more specific embodiment L² is PPr₃, NR₃ (R is various CₓH_{y} group, including H), or multidentate ligands (R₂N—CₓH_{y}—NR₂), with a specific multidentate ligand being (CH₃)₂NCH₂CH₂N(CH₃)₂. Typically, X² may be halides (Cl⁻, Br⁻, and I⁻).

In an exemplary embodiment of the method, the first reagent is a Cu₂₆Se₁₃(PEt₂Ph)₁₄ template nanocluster the second reagent is a CdI₂(PPr₃)₂ coordination complex. Using these clusters and coordination complexes in the reaction produces a Cd₂₆Se₁₇I₁₈(PPr₃)₁₀ product nanocluster as the reaction product.

As used herein, the term “nanocluster” refers to a nanomaterial with a diameter less than 5 nanometers, typically about 1 to about 5 nanometers, that includes a core structure comprising at least 2 or 3 elements. The term “coordination complex” refers to a reagent with less than a few metal cations, typically one metal center, a few anionic ligands, and a few neutral ligands. In an exemplary embodiment of the method, the first reagent is a Cu₂₆Se₁₃(PEt₂Ph)₁₄ template nanocluster, and the second reagent is a CdI₂(PPr₃)₂ coordination complex. Their reaction produces a Cd₂₆Se₁₇I₁₈(PPr₃)₁₀ nanocluster as the reaction product.

According to another embodiment, provided is a nanocluster comprising Cat²-An¹-X²-L², wherein Cat² is selected from Cd²⁺, Zn²⁺, Hg²⁺, Pb²⁺ or other transitional metal cations, or other metal cations, wherein An¹ is selected from S, Se, or Te, wherein X² is selected from halides (Cl⁻, Br⁻, I⁻), carboxylates (⁻O₂CR, R is various CₓH_{y} group), or other anionic ligands, and wherein L² is a neutral surface ligand.

In a specific example, L² is selected from a phosphine, amine, carbene, alcohol, or other neutral ligands, wherein L² is, optionally, is PPr₃, NR₃ (R is various CₓH_{y} group, including H), multidentate ligands (R₂N—CₓH_{y}—NR₂). In another specific example, the nanocluster comprises a size of 0.5-5 nm. The nanocluster may optionally include at least one dopant such as Mn²⁺. In a specific embodiment, the nanocluster is Cd₂₆Se₁₇I₁₈(PPr₃)₁₀. Nanoclusters described herein may take possess a shape selected from tetrahedron, sphere, ellipsoidal, or triangular plate.

Another embodiment relates to device that incorporates nanoclusters described herein. In a specific example, provided is a solar cell that includes a plurality of nanoclusters as described herein. In another example, provided is a light-emitting diode comprising a plurality of nanoclusters as described herein.

In a further example, provided is a photocatalysis process that involves use of a nanocluster as described herein.

### EXAMPLES

### Example 1: Methods

### Chemicals

Selenium (Se, pellets, <5 mm, ≥99.99%, trace metal basis), lithium triethylborohydride solution (LiBEt₃H, 1.0 M in tetrahydrofuran), chlorotrimethylsilane (SiMe₃Cl, ≥99%), copper (I) acetate (97%), diethyl ether (Et₂O, anhydrous, ≥99.7%), methanol (MeOH, anhydrous, 99.8%), dichloromethane (CH₂Cl₂, anhydrous), tetrahydrofuran (THF, anhydrous, ≥99.9%), trioctylphosphine (P(octyl)₃, 97%), tri-n-butylphosphine (PBu₃, 99%), tri-n-propylphosphine (PPr₃, 97%), triethylphosphine (PEt₃, 99%), cadmium chloride (CdCl₂, 99.99%), toluene (anhydrous, 99.8%), and toluene-d8 (anhydrous, 99.6 atom % D) were purchased from Sigma-Aldrich. Diethylphenylphosphine (PEt₂Ph, 97%), cadmium iodide (CdI₂, 98%), cadmium bromide (CdBr₂, 99.99%), and anhydrous n-heptane (99%) were purchased from Alfa Aesar. Chloroform-d (CDCl₃, ≥99.8 atom % D+0.05% v/v TMS) was purchased from Cambridge Isotope Laboratories and stored in a nitrogen-filled glovebox after degassing via freeze-pump-thaw.

### Synthesis of Precursors and Products

General considerations: All synthetic steps were carried out in an air-free environment using a nitrogen-filled glovebox or standard Schlenk techniques.

Synthesis and crystallization of Cu₂6Se₃(PEt₂Ph)₁₄ cluster precursor: Cu₂₆Se₁₃(PEt₂Ph)₁₄ cluster was prepared based on the reported method⁴⁹. In atypical synthesis, Cu(I) acetate (0.37 g, 3 mmol) was suspended in 27 mL of diethyl ether. A clear colorless solution was obtained after adding PEt₂Ph (1.0 mL, 6 mmol). The solution was cooled to −78° C., and bis(trimethylsilyl)selenide⁷⁰ (0.37 mL, 1.5 mmol) was added. The reaction mixture turned from yellow, orange, to dark red in ten minutes. Then the reaction vessel was stored at −20° C. Red rhombic crystals formed after one to two weeks. The crystals were washed with cold methanol to remove the impurities on the surface and dried under a vacuum. Yield: 0.403 g (69.7% based on Se).

Synthesis and crystallization of CdI₂(PPr₃)₂ complex precursor: CdI₂ (200 mg, 0.546 mmol) was suspended in 4 mL of toluene. Two equivalents of PPr₃ (220 μL, 1.092 mmol) were added at room temperature while stirring, yielding a clear colorless solution. The reaction solution was stored at −20° C., and colorless needle-like crystals of CdI₂(PPr₃)₂ came out after one week.

Synthesis and crystallization of Cd₂6Se₁₇I₁₈(PPr₃)₁₀ cluster product via cation exchange reaction: Two equivalents of PPr₃ (208 μL, 1.04 mmol) were added into a suspension of CdI₂ (190.4 mg, 0.52 mmol) in 3 mL of toluene. After stirring for 10 minutes at room temperature, a clear colorless solution formed. Cu₂₆Se₁₃(PEt₂Ph)₁₄ cluster (50 mg, 0.01 mmol) was dissolved in 1 mL of toluene and injected into the vigorously stirred CdI₂(PPr₃)₂ solution at room temperature. The color of the solution changed from red to colorless in a few seconds. The reaction mixture was stirred at room temperature for 24 hours. To isolate the product, the reaction mixture was first concentrated under vacuum to remove most of the solvent. Around 1.2 mL of n-heptane was added to the concentrated mixture to form a suspension. The mixture was centrifuged at 10,000 rpm for 3 minutes, and the supernatant was discarded. The pellets were redispersed in 0.8 mL of toluene and 1.2 mL of n-heptane followed by centrifugation. The washing cycle was repeated one more time. The final precipitates were dissolved in CH₂Cl₂ and dried under vacuum, resulting in 41 mg of light-yellow powder. The powder was dissolved in 0.5 mL of CH₂Cl₂ and layered with 1 mL of toluene. Colorless hexagonal crystalline plates were observed after three days at room temperature. The crystals were washed with toluene and dried, giving a yield of 26 mg (41.7% based on Se). The obtained clusters were stable in crystalline form for more than a month but gradually aggregate in CH₂Cl₂. The aggregation can be slowed down by diluting the CH₂Cl₂ solution of clusters with a large amount of toluene.

### Characterization

Ultraviolet-visible (UV-vis) absorption spectra were recorded on a Cary 5000 spectrophotometer in the range from 200 nm to 800 nm with a 1 nm step size. The spectra of Cu₂₆Se₁₃(PEt₂Ph)₁₄ crystals and Cd₂₆Se₁₇I₁₈(PPr₃)₁₀ crystals were measured in toluene and CH₂Cl₂, respectively.

For the in-situ experiments, a time interval of five minutes was set for the first hour of data collection and then changed to one hour in the following period. The toluene solution of CdI₂(PPr₃)₂(1.07 mg/mL, 1.56 mM) and Cu₂₆Se₁₃(PEt₂Ph)₁₄ (1 mg/mL, 0.2 mM) were prepared separately. In a typical experiment, Cu₂₆Se₁₃(PEt₂Ph)₁₄ solution (1 mL, 0.2 mol) was injected into the CdI₂(PPr₃)₂ solution (10 mL, 15.6 μmol) upon stirring. The final concentration was 18.2 M based on initial Cu₂₆Se₁₃(PEt₂Ph)₁₄ (or 236 M based on Se element). The color of the mixture turned colorless within one second. The reaction solution was transferred into a cuvette and sealed before bringing out of the glovebox for in-situ measurements. The time between mixing and the first scan was around two minutes. In-situ experiments with different CdI₂(PR₃)₂ complexes, temperatures, and concentrations were carried out in a similar procedure by changing the corresponding parameter accordingly. The stock solutions of CdI₂(PR₃)₂ complexes (PR₃=P(octyl)₃, PBu₃, or PEt₃) were prepared in a similar method as CdI₂(PPr₃)₂.

NMR data were recorded on a 600 MHz Bruker Avance III HD NMR spectrometer using 16 scans for ¹H spectra and 64 scans for ³¹P spectra. The gradient-selected Double-Quantum Correlation Spectroscopy (gDQCOSY) was used for two-dimensional NMR spectra at low temperature (−40° C.). The temperature controller functioned with liquid nitrogen and a heater was employed to collect data at variable temperatures (−40 to 20° C.). Samples of PEt₂Ph (20 μL) and Cu₂₆Se₁₃(PEt₂Ph)₁₄ cluster (50 mg) were prepared in 0.6 mL of toluene-d8. Samples of PPr₃ (20 μL), CdI₂(PPr₃)₂(20 mg) and Cd₂₆Se₁₇I₁₈(PnPr₃)₁₀ (40 mg) were made in 0.6 mL of CDCl₃. Chemical shifts are given in 6 ppm and residual solvent peaks were used as internal reference in ¹H spectra (δ_{CH3}=2.08 ppm for toluene-d8 and 6=7.26 ppm for CDCl₃).

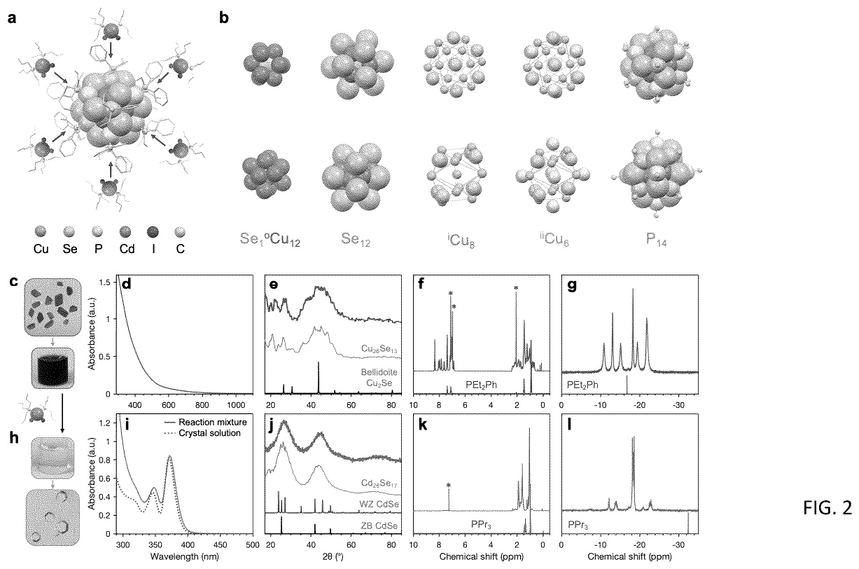

Powder XRD characterization was carried out on a Panalytical X′Pert Powder diffractometer using Cu Kα radiation (λ=1.54056 Å) operated at 45 kV and 40 mA. Finely-ground powder samples were deposited on a glass plate holder and loaded into the flat stage. Data were collected at 2θ values from 5° to 90° using stepwise scans of 0.0080 with a time per step of 10.16 seconds under ambient conditions. The reference XRD patterns (see FIG. 2e, j) were simulated from bulk bellidoite Cu₂Se (ICSD-30230), zinc blende CdSe (ICSD-41528), and wurtzite CdSe (ICSD-41491).

Matrix-Assisted Laser Desorption Ionization-Time of Flight (MALDI-TOF) Mass Spectrometry was performed on a Bruker Autoflex LRF instrument with a laser (335 nm). For sample preparation, 1,8,9-trihydroxyanthracene was used as a matrix, which was dissolved in toluene or CH₂Cl₂ with a concentration of 88 mM (i.e., 20 mg in 1.0 mL of solvent). Solid samples of Cu₂₆Se₁₃(PEt₂Ph)₁₄ cluster and Cd₂₆Se₁₇I₁₈(PPr₃)₁₀ cluster were dispersed in toluene and CH₂Cl₂, respectively, with a concentration of 1 mg/mL. 50 μL of matrix solution and 50 μL of analyte solution were mixed in air. 0.8 μL of the mixture was spotted onto a stainless-steel target plate and allowed to dry followed by spotting another 0.8 μL of the mixture. A mixture of insulin, cytochrome, myoglobin, and ubiquitin was used as the external standard for calibration in the mass range of 4-20 kDa. The sample was measured at the laser power of 80-90%. The detector gain (linear detector, positive mode) was set as 17.6′ (2936 V).

### X-Ray Crystallographic Determination

The X-ray intensity data were collected at 100 K on a Bruker Dual micro source D8 Venture diffractometer equipped with PHOTON III detector using Mo Kα radiation (λ=0.71073 Å). The data frames were integrated, and multi-scan scaling was applied using APEX3 software package of programs. Intrinsic phasing structure solution provided all the non-H atoms. The structure was refined using full-matrix least-squares refinement in the Bruker SHELXTL Software Package. The non-H atoms were refined with anisotropic displacement parameters (ADPs). All the H atoms were calculated in idealized positions and refined riding on their parent atoms. For the Cd₂₆Se₁₇I₁₈(PPr₃)₁₀ cluster, a hexagonal crystal specimen (approximate dimensions: 0.404 mm×0.240 mm×0.172 mm) was used for X-ray crystallographic analysis. The nanocluster crystallizes in the space group P3̅c1, with Z=4 (Z′=0.3333) for the formula-unit content Cd₂₆Se₁₇I₁₈P₁₀C_{142.5}H₂₇₀. The final cell constants are a=26.2849(4) Å, b=26.2849(4) Å, c=42.3692(11) Å, α=90°, β=90°, γ=120°, volume=25350.9(10) Å³. The integration of the data yielded a total of 459723 reflections to a maximum θ angle of 27.5° (0.75 Å resolution), of which 19433 were independent (average redundancγ=4.32, completeness=100.0%, Rᵢₙₜ=6.68%, R_{sig}=2.23%). Data were corrected for absorption effects using the multi-scan method (SADABS). The ratio of minimum to maximum apparent transmission was 0.640.

For the Cu₂₆Se₁₃(PEt₂Ph)₁₄ cluster, a red rhombic crystalline plate (approximate dimensions: 0.178 mm×0.176 mm×0.122 mm) was used for the X-ray crystallographic analysis. The nanocluster crystallizes in the space group P1̅, with Z=2 for the formula-unit content Cu₁₃Se_{6.5}P₇C₇₄H₁₁₅O₁. The final cell constants are a=17.432(3) Å, b=18.014(3) Å, c=18.257(3) A, α=98.808(5°), β=109.168(4°), γ=118.101(5°), volume=4439.1(13) Å³. The integration of the data yielded a total of 260538 reflections to a maximum θ angle of 32.802° (0.75 A resolution), of which 30802 were independent (average redundancγ=7.53, completeness=99.9%, Rᵢₙₜ=6.99%, R_{sig}=4.19%). Data were corrected for absorption effects using the multi-scan method (SADABS). The ratio of minimum to maximum apparent transmission was 0.708.

For the CdI₂(PPr₃)₂ complex, a colorless needle-like crystal (approximate dimensions: 0.337 mm×0.100 mm×0.057 mm) was used for the X-ray crystallographic analysis. The complex crystallizes in the space group P2₁/c, with Z=4 for the formula-unit content Cd₁I₂P₂C₂₅H₅₀. The final cell constants are a=7.9162(3) Å, b=14.8295(7) Å, c=28.1826(13) Å, α=90°, β=94.3040(10)°, γ=90°, volume=3299.1(3) Å³. The integration of the data yielded a total of 142002 reflections to a maximum θ angle of 35.273° (0.75 Å resolution), of which 13999 were independent (average redundancγ=6.30, completeness=99.6%, Rᵢₙₜ=5.22%, R_{sig}=2.95%). Data were corrected for absorption effects using the multi-scan method (SADABS). The ratio of minimum to maximum apparent transmission was 0.381.

### Example 2: Precise Precursors for Cation Exchange Reaction

To achieve atomic precision in the cation exchange reaction, an atomically defined Cu₂₆Se₁₃(PEt₂Ph)₁₄ cluster was selected, where PEt₂Ph is diethylphenylphosphine⁴⁹, as a precise reaction precursor (FIG. 2a, center). Copper(I) chalcogenide (Cu₂₋ₓE, E=S, Se, Te) NCs are common host templates for cation exchange⁴⁰⁻⁴⁶. The high mobility of Cu⁺ as well as its favorable solvation with soft Lewis bases (e.g., phosphines) drive the complete exchange of Cu⁺ with various harder cations⁵⁰. In addition, an existing library of atomically precise Cu₂₋ₓE clusters has been developed by Fenske and coworkers⁵¹, which serves as ideal cluster templates for precise transformation.

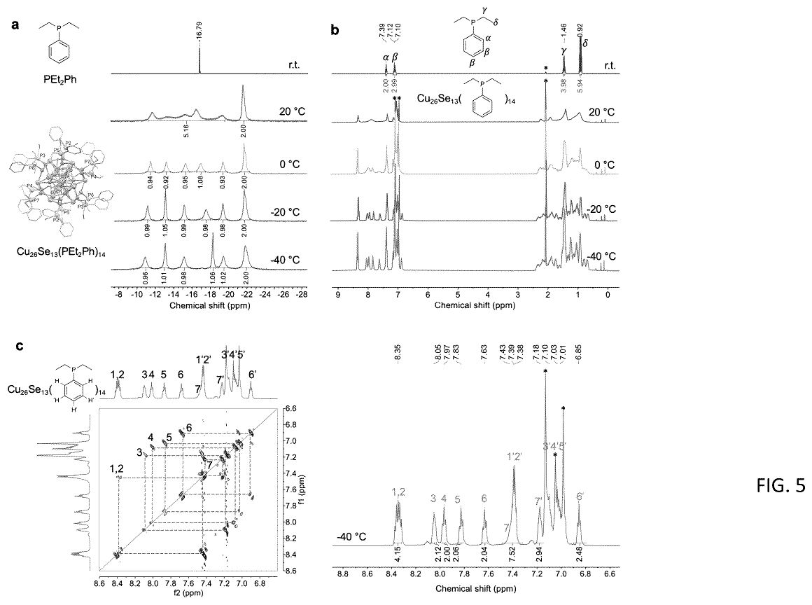

The Cu₂₆Se₁₃(PEt₂Ph)₁₄ cluster was synthesized based on previously reported method⁴⁹ (see Methods). The cluster crystallized as red rhombic crystals (FIG. 2c) and its structure was verified by sc-XRD. As shown in the shell-by-shell anatomy of Cu₂₆Se₁₃P₁₄ framework (FIG. 2b), the cluster features a Se center surrounded by twelve core Cu(I) cations (labeled as ^{o}Cu) in a distorted icosahedron mode, which is orthogonally covered by another Se₁₂ icosahedral shell. Eight Cu cap the triangular facets of the Se₁₂ icosahedron (labeled as ⁱCu) and another six Cu bridge its edges (labeled as ⁱⁱCu), forming the surface Cu₁₄ rhombic dodecahedral shell. Each surface Cu is datively coordinated to a PEt₂Ph ligand. The overall symmetry of the cluster is Cᵢ. The absorption spectrum of the cluster dissolved in toluene shows a decay curve (FIG. 2d), which is consistent with that of non-plasmonic Cu₂E nanocrystals⁵². Powder XRD shows broad diffraction peaks because of the ultrasmall size of the cluster and its icosahedron-based packing (FIG. 2e, red line), which matches the pattern simulated from Cu₂₆Se₁₃(PEt₂Ph)₁₄ structure (FIG. 2e, grey line). NMR is performed to examine cluster structure in the solution phase. Due to the fluxionality of phosphine ligands⁵³, broad peaks are observed at room temperature. But seven groups of peaks with two-fold degeneracy can be resolved in low-temperature ¹H, ³¹P and ¹H-¹H COSY spectra (FIG. 2f, g and FIG. 5). The splitting matches with seven chemical environments of fourteen PEt₂Ph ligands under Cᵢ symmetry, suggesting the cluster remains intact in toluene solution⁵⁴.

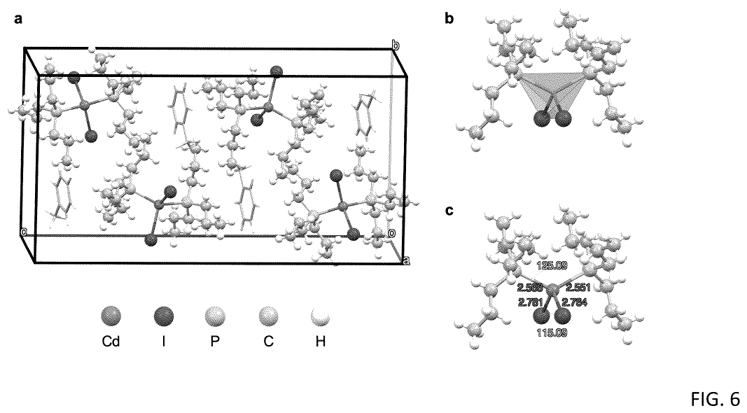

Another crucial reagent is the cation precursor. We identify a precisely defined CdI₂(PPr₃)₂ coordination complex, where PPr₃ is tri-n-propylphosphine, as the carrier for incoming cation (FIG. 2a, periphery) after multiple optimizations (vide infra). Common cation carriers used in colloidal cation exchange, such as metal oleate or oleylamine compounds^{28,41-45}, often form coordination polymers with undefined coordination centers and flexible hydrocarbon groups^{13,55}, which introduce randomness to the reaction system. In contrast, the Cd(II) complex coordinated to halides and phosphines shows a discrete and tetrahedrally coordinated cation center⁵⁶, which can simplify diffusion kinetics and enable precise collision pathways. In addition, the phosphine ligands in the complex concurrently serve as soft bases to extract Cu⁺ and drive the forward exchange reaction°. It was also found that the coordination complex not only controls the reactivity of the cation precursor but also determines the stability of the product cluster (vide infra). The CdI₂(PPr₃)₂ complex was prepared by reacting CdI₂ and PPr₃ in toluene (see Methods). Colorless needle-like crystals were obtained at −20° C. and the tetrahedrally coordinated Cd(II) complex was confirmed by sc-XRD (FIG. 6).

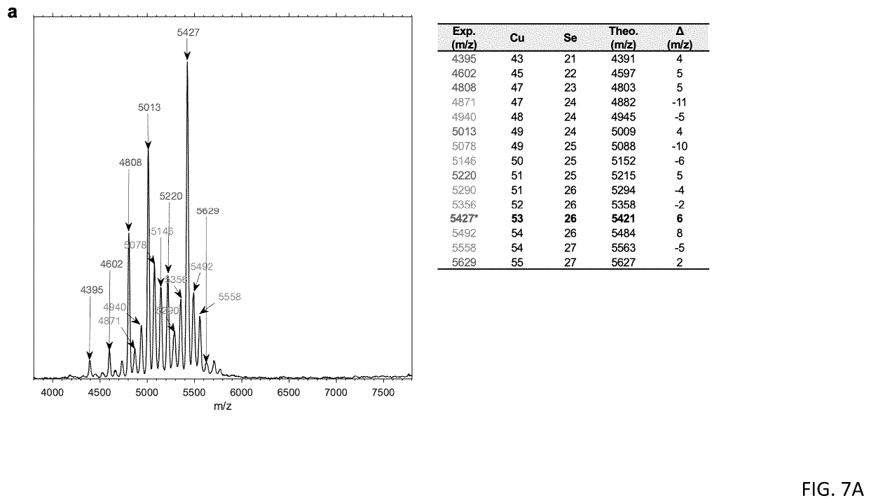

In a typical cation exchange reaction, one equivalent of Cu₂₆Se₁₃(PEt₂Ph)₁₄ was mixed with 52 equivalents of CdI₂(PPr₃)₂ in toluene at room temperature. The solution color changes from dark red to colorless within a few seconds (FIG. 2h, top), and two sharp absorption peaks at 372 nm and 347 nm are observed after one day (FIG. 2i, solid line). The distinct peaks are characteristics of excitonic transitions of CdSe nanomaterial^{22,57}. The same absorption profile can be reproducibly observed in different batches of syntheses, indicating the two peaks belong to a single CdSe cluster. The cluster was isolated by precipitation with heptane. Powder XRD shows two broad peaks centered at ~26° and ~45° (FIG. 2j, green line), which deviate from the bulk zincblende (ZB) and wurtzite (WZ) phases (FIG. 2j, black lines) but match the simulated pattern of resolved structure described below (FIG. 2j, grey line). Matrix-assisted laser desorption ionization mass spectrometry (MALDI-MS) reveals a series of characteristic fragmentation peaks of CdSe materials^{22,57,58}, which are different from Cu₂₆Se₁₃ fragments (FIG. 7). Interestingly, the ¹H NMR spectrum of the isolated product only shows peaks in the aliphatic region (FIG. 2k), suggesting that the original PEt₂Ph ligands are replaced with PPr₃. Although the characterization cannot provide detailed composition and structure of the product, it confirms the reaction proceeds and results in a well-defined CdSe cluster.

### Example 3: Atomically Precise CdSe Cluster as the Product of Cation Exchange Reaction

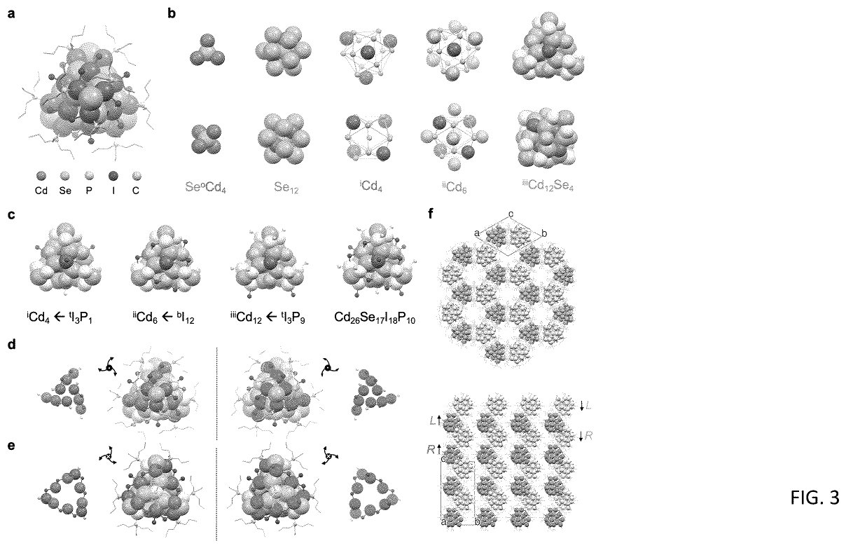

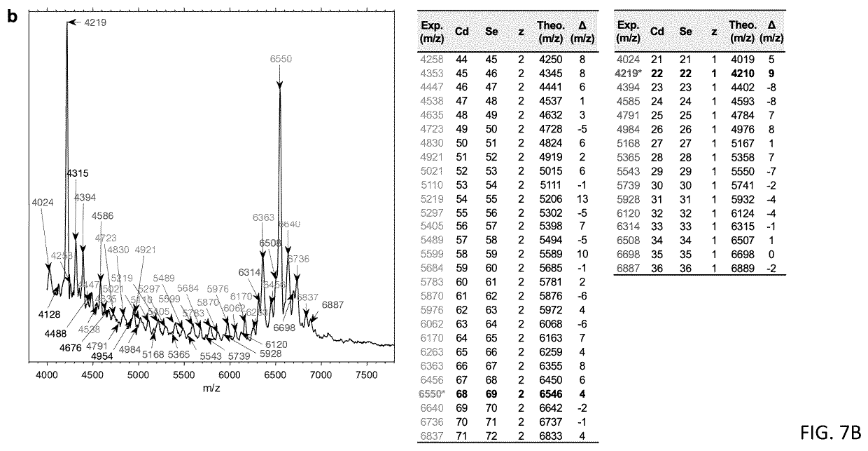

The CdSe cluster produced by the reaction of Cu₂₆Se₁₃(PEt₂Ph)₁₄ and CdI₂(PPr₃)₂ can be crystallized into colorless hexagonal plates in CH₂Cl₂/toluene solution (FIG. 2h, bottom). The total structure of a Cd₂₆Se₁₇I₁₈(PPr₃)₁₀ cluster was solved by sc-XRD (FIG. 3a). The cluster features a tetrahedron-based but non-close-packed Cd₂₆Se₁₇ core with an edge length of 1.1 nm (FIG. 8a). The overall size including the ligands is 2.2 nm. The Se₁₇ anion lattice is composed of a Se₁₃ icosahedron and four apical Se, while the Cd₂₆ cation lattice can be viewed as four interpenetrating icosahedra in a tetrahedral arrangement (FIG. 8b). All the Se and Cd are tetrahedrally coordinated except the four apical μ₃-Se. The shell-by-shell anatomy of the Cd₂₆Se₁₇ core is shown in FIG. 3b. The cluster features a Se center surrounded by four core Cd (labeled as ° Cd). Each ° Cd is further connected to three Se and the total twelve Se assemble into an icosahedron shell. The Se₁₂ shell is face-capped by four Cd (labeled as ⁱCd), edge-bridged by six Cd (labeled as ⁱⁱCd), and vertex-terminated by twelve Cd (labeled as ⁱⁱⁱCd). The ⁱCd₄ⁱⁱCd₆ⁱⁱⁱCd₁₂ forms the surface Cd₂₂ shell, with ⁱⁱⁱCd₁₂ capped by four apical Se.

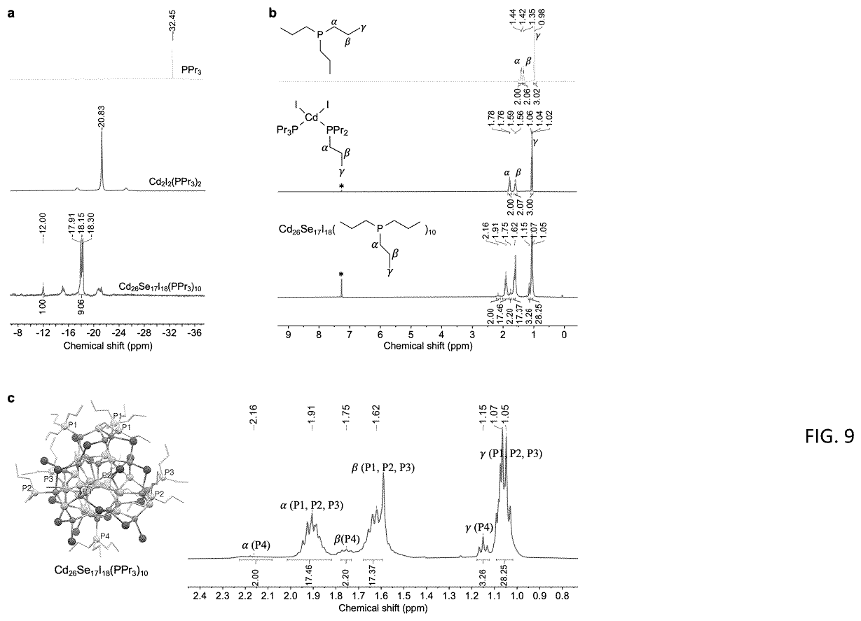

Significantly, the icosahedral Se₁₃ lattice of Cd₂₆Se₁₇ contrasts with zincblende and wurtzite lattices commonly observed in CdSe NCs^{3,4,59} and clusters^{21,22}, but is nearly identical to that of Cu₂₆Se₁₃ (FIG. 10). The resemblance indicates the Se₁₃ lattice of the child Cd₂₆Se₁₇ cluster is inherited from that of the parent Cu₂₆Se₁₃ cluster, and the anion sublattice can be preserved during cation exchange in the ultrasmall cluster. The rigidity of anion lattice can be explained by the favored cohesion energy between cations and anions in the cluster framework, while it is energetically unfavored to dissociate and solvate ionic building blocks in the nonpolar reaction medium. It is worth noting that the icosahedron is a frequently observed structural motif in metal clusters due to its low surface energy^{9,24}. A few reported semiconductor clusters also show deviation from bulk phases (e.g., In₃₇P₂₀, Cd₁₄Se₁₃, and Zn₁₄Se₁₃)^{23,60,61}. A careful examination of these structures shows that their anion lattices are also based on icosahedron (e.g., interpenetrating bi-icosahedra P₁₉ in In₃₇P₂₀). It is interesting that semiconductor clusters could share similar atomic packings with metal clusters when cation and anion lattices are considered independently.^{23,60,61} Note that the expansion of the anion lattice from Se₁₃ to Se₁₇ is attributed to the subsequent reaction of CdSe clusters after cation exchange (vide infra).

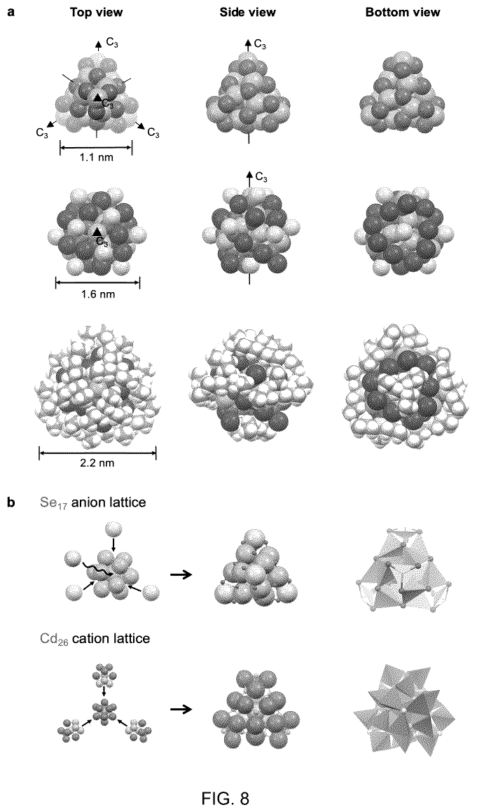

In contrast to core anions, the surface ligands of child Cd₂₆Se₁₇I₁₈(PPr₃)₁₀ cluster are exclusively inherited from CdI₂(PPr₃)₂ precursor, revealing that cation exchange is accompanied by surface ligand exchange. All the ligands are coordinated to surface Cd²⁺ (FIG. 3c). While iodides can be found on facets, edges, and corners (FIG. 3c, purple), phosphines are mainly on vertexes except for one at the bottom facet (FIG. 3c, pink). Based on the tetrahedral coordination of Cd(II), each surface Se₃ⁱCd, Se₂ⁱⁱCd, and Se₂ⁱⁱⁱCd site exposes 1, 2, and 2 dangling bonds, respectively. The empty sites on four facet ⁱCd are saturated by three terminal iodide (^{t}I) and one PPr₃. The six edge ⁱⁱCd are passivated by twelve bridging iodides (^{b}I), which further connect to ⁱⁱⁱCd. The remaining sites on twelve vertex ⁱⁱⁱCd are protected by three ^{t}I and nine PPr₃. In addition to saturating coordination sites, the eighteen iodides also balance the positive charges of the Cd₂₆Se₁₇ core and the ten phosphines provide steric protection around the cluster. The ligands also partially shield the undercoordinated apical Se sites (FIG. 8a). While the Cd₂₆Se₁₇ core has a T symmetry, the symmetry of entire cluster is reduced to C₃ due to the distribution of ligands around the principal axis. ³¹P and ¹H NMR spectra display a 3, 3, 3, 1 distribution of the ten PPr₃, which matches with the C₃ symmetry of the ligand shell (FIG. 2l, FIG. 9).

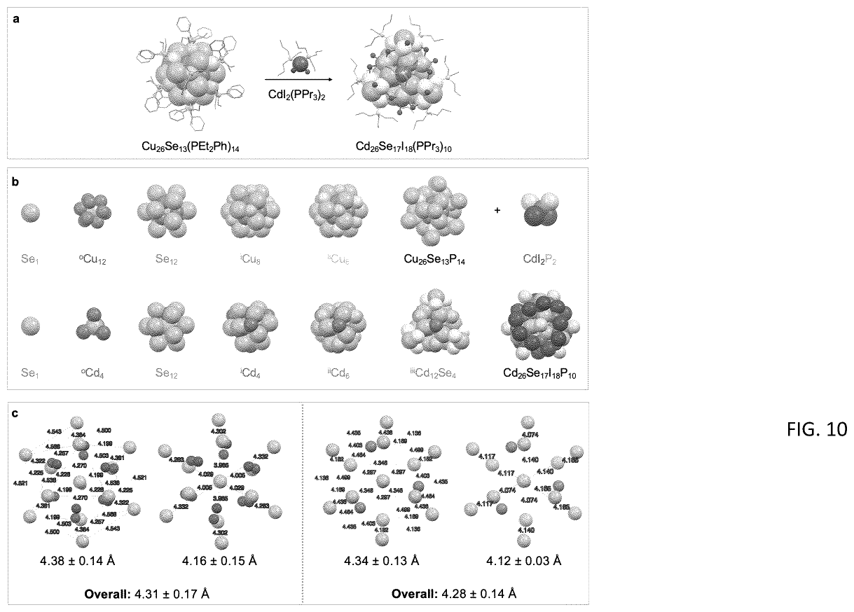

The product cluster not only hybridizes the structural features from both parent precursors but also evolves into an enlarged anion lattice with extended surface patterns. Linked by bridging iodides, three P-ⁱⁱⁱCd-I-ⁱⁱCd-I-ⁱⁱⁱCd-P chains emanate from the top corner of the tetrahedron (FIG. 3d), and another three P-ⁱⁱⁱCd-I-ⁱⁱCd-I-ⁱⁱⁱCd-I chains wrap the base (FIG. 3e). While both precursors are achiral, chirality emerges in the product, as reflected in the clockwise or counterclockwise rotation of surface patterns (FIG. 3d, e). Surface chirality can be traced back to the core, which originates from the integration of tetrahedral coordination of Cd into the icosahedral framework of Se (FIG. 11a). The core chirality is manifested by the twisted alignment of Cd—Se bonds along the principal axis, while achiral Se₁₃ cuboctahedron based on the zincblende phase exhibits vertically aligned Cd—Se bonds. The cluster also features an intrinsic dipole moment due to the uneven distribution of ligands, with phosphines concentrated at the top and iodides at the base (FIG. 8a). The inter-cluster dipole interactions²⁷ facilitate the head-to-tail alignment of enantiomers in the unit cell (FIG. 11b) and their ordered assembly into single crystals (FIG. 3f).

The Cd₂₆Se₁₇I₁₈(PPr₃)₁₀ crystals dissolved in CH₂Cl₂ show two sharp excitonic absorption transitions at 371 nm (E₁) and 346 nm (E₂) and a hump at 317 nm (E₃) (FIG. 2i, dash line). The peaks blueshift by 1 nm compared to that of the reaction mixture due to different solvent permittivity. The full widths at half maximum of E_{L} and E₂ are 18 nm (161 meV) and 20 nm (207 meV), respectively. The molar extinction coefficients are 1.08×10⁵ M⁻¹ cm⁻¹ for E₁ and 5.83×10⁴ M⁻¹ cm⁻¹ for E₂. The E_{L} peak position is comparable to that of a zincblende-based selenolate-protected Cd₃₂Se₁₄ cluster (373 nm)²¹. In addition, many CdSe magic-sized clusters (MSCs) have been identified by their characteristic absorption^{57,58,62}, including a series of carboxylate-protected MSCs with peaks at −360 nm, 384 nm, 406 nm, and 431 nm. These MSCs are theoretically assigned as (CdSe)₁₃, (CdSe)₁₉, (CdSe)₃₃, and (CdSe)₆₆, respectively⁶³. The Cd₂₆Se₁₇ seems to fit into this sequence when the total number of CdSe units is considered. We shall note that excitonic transitions of ultrasmall clusters could be sensitive to structural details such as core shape and symmetry⁶⁴ as well as surface ligands^{59,65} in addition to sizes. No photoluminescence is detected at room temperature. This is consistent with other structurally resolved semiconductor clusters¹⁹⁻²², where broad emissions could only be observed at cryogenic temperature. The lack of emission can be attributed to the ultrasmall core size and large surface area, which enhance the coupling between excitons and surface/lattice vibration and increase the energy dissipation via nonradiative pathways.¹⁹⁻²² Also, the dangling bonds on apical Se could lead to the trap states in the optical gap that quench the emission^{6,15,16}.

### Example 4: Precise Transformation Pathways and Atomic Insights into the Reaction Mechanism

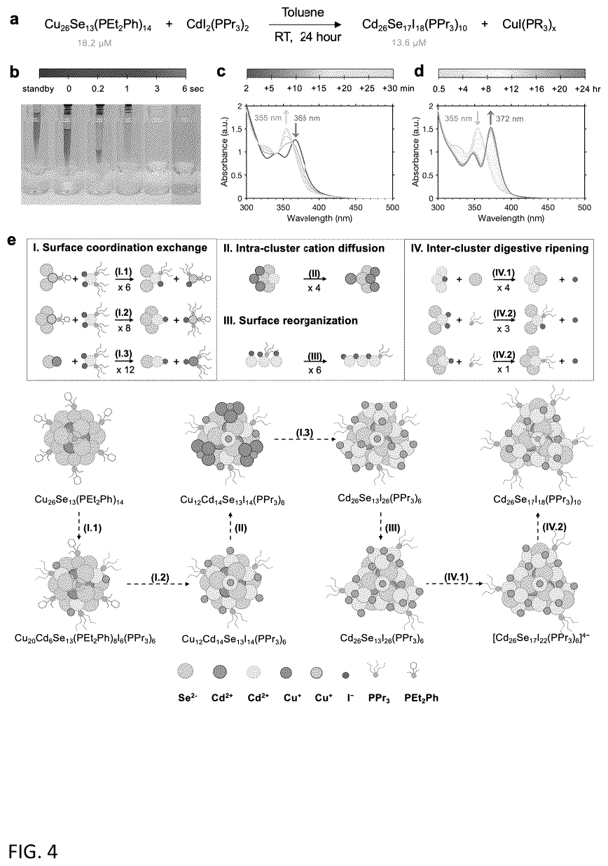

Two interesting questions arise in Cu₂₆Se₁₃(PEt₂Ph)₁₄ to Cd₂₆Se₁₇I₁₈(PPr₃)₁₀ transformation (FIG. 4a): how does the anion framework expand from Se₁₃ to Se₁₇? and how are surface ligands exchanged? To answer these questions, the reaction was monitored by in-situ UV-vis spectroscopy. Upon injecting one equivalent of Cu₂₆Se₁₃ solution into 78 equivalents of CdI₂(PPr₃)₂ solution, the reaction mixture changes to colorless within one second (FIG. 4b). Interestingly, the 2 min reaction mixture shows a well-defined peak at 365 nm, which blueshifts to 355 nm in the next ~10 min and stabilizes for another ~20 min (FIG. 4c). In the next 24 hours, the 355 nm peak slowly redshifts to the characteristic 372 nm of the final product (FIG. 4d). Both shifts (365 nm→355 nm→372 nm) occur in a quantized manner with the presence of isosbestic points, indicating the reaction proceeds with direct conversion among well-defined intermediates. The final spectrum is stabilized for more than 72 hours with only a subtle change in absorbance. According to the final absorbance of the 372 nm peak and its extinction coefficient, the conversion yield from Cu₂₆Se₁₃ to Cd₂₆Se₁₇ is near unity on the Se basis.

The precise structures of precursors and products determined by X-ray crystallography and the pathways mapped by in-situ spectroscopy enable us to study reaction mechanisms at the atomic level (FIG. 4e). Remarkably, the structure of the child cluster (including core and surface) can be atomically linked to precursors by following two assumptions: (i) the reaction intermediates should be nearly neutral as highly charged species are unstable in a nonpolar medium; (ii) the coordination of intermediates should be close to saturation to minimize uncontrolled aggregations. Based on these charge and coordination conservations, the overall reaction can be roughly divided into the following stages (FIG. 4e).

The first stage can be described as surface coordination exchange: instead of simply exchanging cations, the exchange occurs between the entire surface coordination moiety and the incoming complex (FIG. 4e, I). For example, upon interacting with CdI₂(PPr₃)₂, each edge-bridging [ⁱⁱCu(PEt₂Ph)]⁺ moiety gains an I⁻ and a PPr₃ and leaves the host cluster as a charge-neutral CuI(PEt₂Ph)(PPr₃) complex (FIG. 4e, I.1). Concurrently, the residual [CdI(PPr₃)]⁺ re-bridges the exposed Se edge sites and restores its tetrahedral coordination. In this way, the charge and coordination of the cluster and the complex are conserved during the conversion. Similarly, each face-capping [ⁱCu(PEt₂Ph)]⁺ sites can be exchanged into [ⁱCdI]⁺, with CuI(PEt₂Ph)(PPr₃)₂ as the leaving group (FIG. 4e, I.2). Altogether, the Se^{o}Cu₁₂Se₁₂[ⁱCu(PEt₂Ph)]₈[ⁱCu(PEt₂Ph)]₆ is converted to Se^{o}Cu₁₂Se₁₂[ⁱCdI]₈[ⁱⁱCdI(PPr₃)]₆.

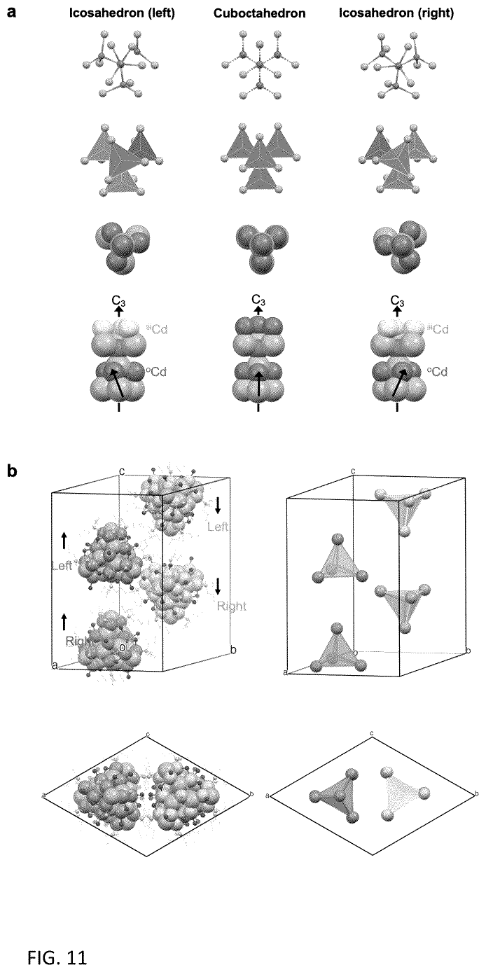

The second stage should be intra-cluster cation diffusion to exchange core ^{o}Cu (FIG. 4e, II). This can be achieved by the inward diffusion of four ⁱCd to form the Se^{o}Cd₄ center and the outward diffusion of 12 ^{o}Cu to occupy the vertex positions of Se₁₂ icosahedron. The ^{o}Cu⁺ can subsequently be replaced by [ⁱⁱⁱCdI]⁺ and removed as CuI(PPr₃)₂, leading to a fully exchanged Cd₂₆Se₁₃I₂₆(PPr₃)₆ intermediate (FIG. 4e, I.3). The following stage could be surface reorganizations, as the newly exchanged ⁱⁱⁱCd sites are undercoordinated and unstable (FIG. 4e, III). One way to saturate ⁱⁱⁱCd sites is to convert twelve terminal iodides into bridging ones, which links originally isolated ⁱⁱCd and ⁱⁱⁱCd sites into six chains. In the meantime, the PPr₃ on ⁱⁱCd is shuffled to the end of the chain. The uneven distribution of six PPr₃ to four corners breaks the T symmetry into C₃ (FIG. 12).

The last stage should be inter-cluster digestive ripening (FIG. 4e, IV). The reorganized Cd₂₆Se₁₃I₂₆(PPr₃)₆ is still unstable due to high-energy face-capping iodides (^{f}I⁻) at four corners and insufficient steric shielding from PPr₃. During inter-cluster collisions, some clusters could dissociate and release Se²⁻, which can be readily captured by other clusters to replace ^{f}I⁻ and form [Cd₂₆Se₁₇I₂₂(PPr₃)₆]⁴⁻ (FIG. 4e, IV.1). The introduced negative charges can be rebalanced by converting four terminal iodides (three at ⁱⁱⁱCd and one at ⁱCd) to PPr₃ (FIG. 4e, IV.2), which concurrently provides more shielding to the cluster. Finally, a stable Cd₂₆Se₁₇I₁₈(PPr₃)₁₀ product is reached with balanced charges, saturated surface Cd sites, and sufficient steric protection.

The observed ligand exchange during cation exchange can be readily explained by surface coordination exchange (FIG. 4e, I). This process can be very fast considering the lability of phosphine and its favorable solvation with Cu⁺, which is reflected in the initial rapid color exchange from red to colorless in seconds (FIG. 4b). The expansion of the anion lattice from Se₁₃ to Se₁₇ can be explained by the digestive ripening (FIG. 4e, IV), which is evidenced in the slow 355 nm→372 nm redshift in hours (FIG. 4d). The inter-cluster reaction is expected to be slow because it requires the dissociation and reassembly of the entire cluster framework. The ripening process can also be understood as precise aggregation, which is indeed frequently observed in semiconductor cluster synthesis, including the earlier work of converting Cd₁₀S₄(SPh)₁₂ cluster into Cd₃₂S₁₄(SPh)₃₆ in coordination solvent of pyridine¹⁹ as well as converting 350 nm CdSe cluster into 380 nm and 408 nm species²².

While the redshift period can be readily correlated to the anion lattice enlargement, the initial blueshift period (365 nm→355 nm in minutes, FIG. 4c) is more puzzling. One possibility is to assign the 365 nm species to partially exchanged core-shell Cu₁₂Cd₁₄Se₁₃I₁₄(PPr₃)₆ (FIG. 4e, I.2). This is reasoned by the slower exchange of core cations compared to surface ones³⁶, leading to the temporally trapped core-shell species. The blueshift can thus be explained by the exclusion of core ^{o}Cu, since the excitonic transition is known to be shifted in heavily doped or core-shell semiconductor nanocrystals^{66,67}. The other possibility is to assign the 365 nm species as the fully exchanged iodide rich Cd₂₆Se₁₃I₂₆(PPr₃)₆(FIG. 4e, I.3) and the 355 nm species as alternative surface reorganized [Cd₁₄Se₁₃I₄(PPr₃)₁₂]²⁻. The blueshift can thus be explained by the depletion of iodides on the surface (from I₂₂ to I₄). This assignment is also supported by a recently resolved Cd₁₄Se₁₃Cl₂L₆ cluster (L=Me₂NC₂H₄NMe₂), which shows E₁ at 354 nm⁶⁰. It is noted that the intermediates are highly dynamic and constantly exchanging (especially on surfaces). The 365 nm and 355 nm species could correspond to a group of clusters with the same core but dynamic surface structures. It is unclear yet to what extent the depletion of core Cu⁺ or surface I⁻ will cause the absorption shift. Future studies on precise structure-property correlations for doped or ligand-exchanged clusters are necessary to confirm the mechanism.

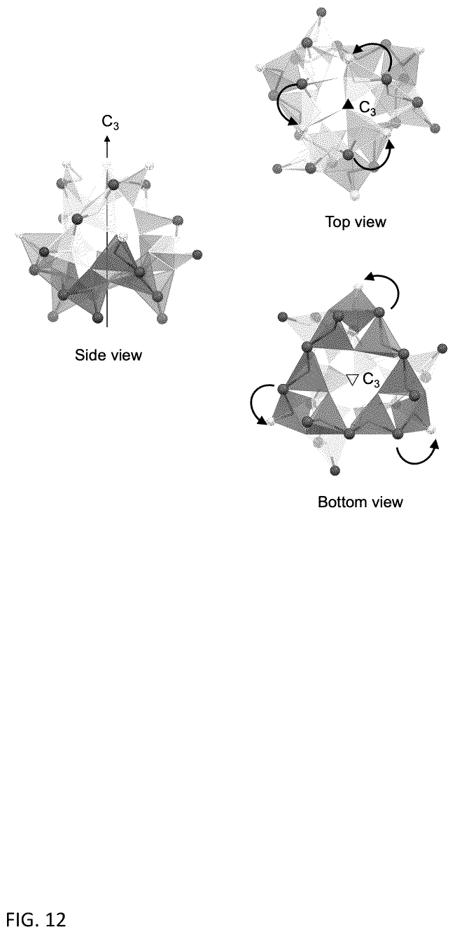

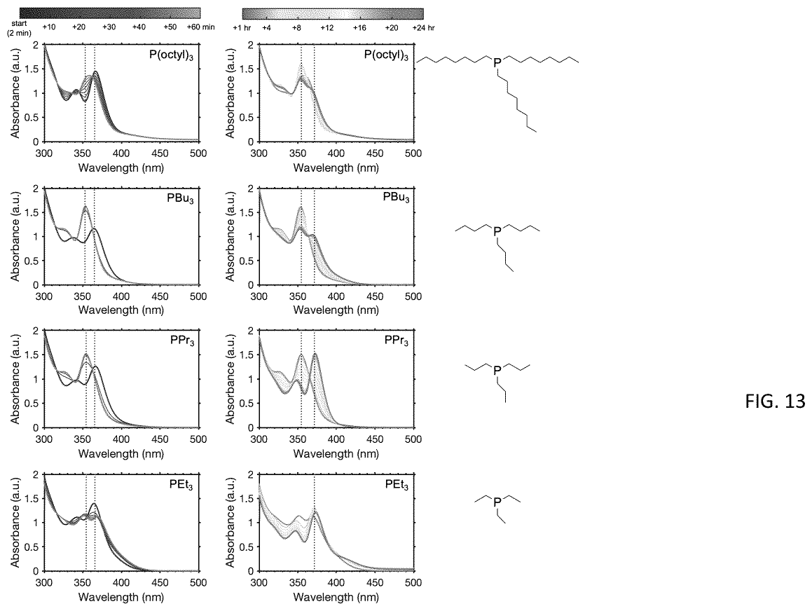

The effects of various reaction conditions on cation exchange were investigated. Varying alkyl chains of phosphine from octyl, butyl to ethyl in CdI₂(PR₃)₂ complex does not alter the reaction pathway and intermediates. The same 365 nm→355 nm→372 nm conversions are observed (FIG. 13). But the reaction is much faster with CdI₂(PEt₃)₂ due to reduced diffusion and collision barriers for complexes with shorter ligands. In contrast, changing halide ligands has more significant effects in the final product: the reaction with CdBr₂(PPr₃)₂ or CdCl₂(PPr₃)₂ complex leads to uncontrolled aggregations into larger CdSe clusters (FIG. 14). This can be explained by the smaller sizes of chloride (3.3 Å) and bromide (3.9 Å)⁶⁸, making them less effective than iodide (4.4 Å) as bridging ligands required by Cd₂₆Se₁₇ structure (the average ⁱⁱCd-ⁱⁱⁱCd distance is 4.46±0.07 Å, FIG. 3c). The reaction is faster when performed at 40° C., but further increasing the temperature to 75° C. leads to the aggregation of CdSe clusters. The reaction is nonstoichiometric but kinetically controlled: insufficient amounts of CdI₂(PPr₃)₂(13 to 26 equivalents to Cu₂₆Se₁₃) result in irreversible aggregations at the initial stage of reaction probably due to the lack of instant surface passivation, while excess amounts (52 to 117 equivalents) promote the reaction and accelerate the final product formation. These results further demonstrate the complexity of cation exchange on nanoclusters, which require precise reactions not only in the atomic core but also at the coordination surface and inter-cluster level to reach a stable product. Thus, fine-tuning reaction conditions and balancing hierarchical interactions are important for precise transformations.

### Conclusion

In summary, Examples 1-4 report the precision synthesis of Cd₂₆Se₁₇I₁₈(PPr₃)₁₀ cluster via cation exchange reaction between Cu₂₆Se₁₃(PEt₂Ph)₁₄ cluster and CdI₂(PPr₃)₂ complex. The employment of atomically defined precursors is crucial to the precise transformation. While Cu₂₆Se₁₃(PEt₂Ph)₁₄ cluster provides the template for anion framework, the coordination complex CdI₂(PPr₃)₂ controls the reactivity of incoming cations, the solvation of outgoing cations, and the surface structures and stability of the resulting cluster. It is shown that cation exchange on nanocluster bridges the solid-state conversion in the core and molecular coordination reaction on the surface. The precise reaction provides atomic evidence that anion lattice can be preserved in ultrasmall clusters and unveils that cation exchange is accompanied by surface ligand exchange. This enables the access of atomically precise CdSe nanoclusters with novel core and surface structures. The child Cd₂₆Se₁₇I₁₈(PPr₃)₁₀ cluster inherits its icosahedral anion lattice from the parent cluster and its tetrahedrally coordinated cation surface from the parent complex, and further evolves into an enlarged core and extended surface with emerging chirality and polarity. The precise reaction also provides atomic insights into the reaction mechanism, which include surface coordination exchange occurred in seconds; intra-cluster core or surface reorganizations in minutes; and inter-cluster digestive ripening in hours.

Despite numerous collisions, exchanges, and reorganizations required to construct a nanostructure, Examples 1-4 demonstrate that precision nanosynthesis with atomically defined precursors, pathways, and products can be realized via synergizing coordination, cluster, and colloidal chemistry in the nanoscale reaction. The emergence of atomic precision in the complex nanoscale reaction is reminiscent of biomolecular reactions in living systems, which all proceed with atomically defined pathways despite the intricacies of the process⁶⁹. It is expected that precision nanosynthesis will provide a designable approach to access a diverse library of atomically precise nanoclusters and further facilitate atomic engineering of functional nanostructures for energy and information applications.

### Example 5: Transformative Syntheses of Atomically Precise II₁₄VI₁₃ Clusters Using MX₂(Tmeda) Complexes

### Introduction

Semiconductor nanocrystals or quantum dots (QDs) are often considered “artificial atoms” because of their discrete electronic states with confined excitonic transitions resembling those of atoms (1-3) as well as their spherical shapes allowing their assembly into exotic “artificial solids” (4, 5). An important challenge in artificial atoms is their size dispersity and structural defects, which hinder the precise structure-property correlation. A generalizable and precise synthetic strategy is highly desired for the atomic engineering of artificial atoms to enhance their performance in energy conversion applications and emerging technologies including quantum computing and exotic artificial solids (6).

Compared to small molecules, colloidal QDs have much more complex structures composed of tens to thousands of core atoms and surface-capping molecules. The precise construction of colloidal nanocrystals is more challenging, which requires controlling not only individual bonds between atoms and molecules but also their ensemble packing at hierarchical levels (7, 8). Despite the challenges, a few atomically precise semiconductor nanoclusters have been discovered during the past four decades, including Cd₃₂S₁₄, Cd₅₄S₂₀, and In₃₇P₂₀ (9-17). While these clusters have precise structures, their syntheses are less defined, which has hindered further investigation of their properties. On the other hand, semiconductor magic-sized clusters (MSCs) are often observed during the colloidal synthesis of QDs. They are characterized by distinct and consistent absorption features, such as CdSe MSCs with peaks at 350, 384, and 406 nm (18-23). Despite their precise optical properties, their atomic structures remain largely elusive, as their characterization is hampered by ultrasmall sizes and dynamic structures (23). To decipher the enigma of precise structure-property correlation in artificial atoms calls for a generalizable method that could bridge the gaps between conventional coordination and colloidal chemistry.

Compared to the direct synthesis of QDs from molecular precursors via nucleation and growth (24-26), colloidal transformation reaction via cation exchange (e.g., CdSe QDs+Ag⁺→Ag₂Se QDs+Cd²⁺) has provided a shortcut to access QDs with novel phases, shapes, and heterostructures (27-29). Examples 1-4 above, present the “precisionalization” of cation exchange reaction: by using atomically defined precursors, including a parent Cu₂₆Se₁₃(PEt₂Ph)₁₄ cluster as the template and a CdI₂(PPr₃)₂ complex as cation carrier, a child Cd₂₆Se₁₇I₁₈(PPr₃)₁₀ cluster was produced with near-unity yield (see also 30). While the child cluster inherits its anion lattice from the parent cluster, its cations and surface ligands are dictated by the parent coordination complex. It is envisioned that such a transformative approach is highly modulable, as it decouples the controls of cations, anions, and surface ligands of nanoclusters into different reaction precursors, therefore allowing rational control and atomic engineering of semiconductor nanoclusters.

In this Example 5, the generalization of transformative synthesis to access a library of atomically precise II-VI clusters is demonstrated. To introduce different IIB cations, a universal MX₂L coordination molecule (“coordination complex”) was identified as the cation carrier, where M (“Cat²”)=Zn²⁺, Cd²⁺, Hg²⁺; X=I⁻, Cl⁻; L=tetramethylethylenediamine (tmeda). Their reactions with the parent Cu₂₆Se₁₃ cluster lead to a family of Zn₁₄Se₁₃, Cd₁₄Se₁₃, and Hg₁₄Se₁₃ clusters with high purity. The precise synthesis enables the resolution of both atomic structures and distinct optical absorption of the sequence of II-VI clusters, which further facilitates the theoretical calculation to decipher the electronic structures and “periodic” rules of these artificial atoms.

### Chemicals

Selenium (Se, pellets, <5 mm, ≥99.99%, trace metal basis), lithium triethylborohydride solution (LiBEt₃H, 1.0 M in tetrahydrofuran), chlorotrimethylsilane (SiMe₃Cl, ≥99%), copper (I) acetate (CuOAc, 97%), zinc iodide (ZnI₂, ≥98%), mercury iodide (HgI₂, ≥99%), zinc chloride (ZnCl₂, ≥98%), cadmium chloride (CdCl₂, 99.99% trace metal basis), N,N,N′,N′-tetramethylethylenediamine (tmeda, 99%), tri-n-propylphosphine (PPr₃, 97%), sodium tetraphenylborate (NaBPh₄, 99.5%), diethyl ether (Et₂O, anhydrous, ≥99.7%), methanol (CH₃OH, anhydrous, 99.8%), dichloromethane (CH₂Cl₂, anhydrous), pentane (anhydrous, ≥99%), toluene (anhydrous, 99.8%), and acetonitrile (CH₃CN, anhydrous, 99.8%) were purchased from Sigma-Aldrich. Diethylphenylphosphine (PEt₂Ph, 97%), cadmium iodide (CdI₂, 98%), and anhydrous n-heptane (heptane, 99%) were purchased from Alfa Aesar. Mercury chloride (HgCl₂, ≥99.5%) was purchased from Thermo Scientific Chemicals. Chloroform-d (CDCl₃, ≥99.8 atom % D+0.05% v/v TMS) was purchased from Cambridge Isotope Laboratories and stored in a nitrogen-filled glovebox after being degassed using the freeze-pump-thaw method.

### Synthesis of the Anion Template Cluster and Cation Carrier Complexes

General considerations. All synthetic steps were performed in air-free environment using nitrogen-filled glovebox or standard Schlenk techniques.

Cu₂₆Se₁₃(PEt₂Ph)₁₄ cluster. The synthesis was based on the previous report.(1, 2) CuOAc (0.37 g, 3 mmol) and PEt₂Ph (1.0 mL, 6 mmol) were added into 27 mL of diethyl ether. After stirring for 2 hours at room temperature, a clear solution formed and was cooled to −78° C. Se(SiMe₃)₂ (0.37 mL, 1.5 mmol) synthesized based on the literature (3) was cooled too and then injected into the Cu(I) precursor solution. The color of the reaction mixture changed from yellow, orange, to dark red in about ten minutes, indicating the formation of cluster species. Red rhombic crystals were obtained after storing the reaction mixture at −20° C. for one to two weeks. After separating the mother liquor, the crystals were rinsed with cold methanol and dried under vacuum. Yield: 0.47 g (81.4%).

ZnI₂(tmeda) complex. ZnI₂ (319 mg, 1 mmol) was suspended in −3 mL of CH₂Cl₂. Tmeda (300 μL, 2 mmol) was added, and the suspension became a clear colorless solution after stirring for 15 minutes at room temperature. The solution was filtered to remove a trace amount of unreacted ZnI₂. After reducing the volume to 1 mL under vacuum, heptane (4 mL) was added to precipitate the complex. The resulting white suspension was brought out of the glovebox and centrifuged at 6,000 rpm for 5 min. The precipitates were extracted with −5 mL of CH₂Cl₂. After filtration, the CH₂Cl₂ solution was dried under vacuum and white powders were obtained. Yield: 364 mg (83.6%). Colorless needle-like crystals were grown in one day by layering heptane onto the CH₂Cl₂ solution of the product. The structure was confirmed by X-ray crystallography, which matched the reported structure of ZnI₂(tmeda).(4) Unit cell parameters: a=12.905(5) Å, b=7.751(2) Å, c=13.351(7) Å, α=90.000°, β=110.247(9°), γ=90.000°, and a cell volume of 1253.04 Å³ in C2/c space group.

CdI₂(tmeda) complex. CdI₂ (366.2 mg, 1 mmol) was suspended in −3 mL of CH₂Cl₂, and tmeda (150 μL, 1 mmol) was added. After ten minutes of stirring at room temperature, the suspension became a clear colorless solution. The solution was filtered and layered with heptane. Needle-like crystals were obtained after one day. The crystals were rinsed with heptane and dried under vacuum. Yield: 275 mg (57.0%). The product can be recrystallized from CH₂Cl₂/heptane for X-ray crystallography. The structure matched the reported CdI₂(tmeda) complex.(5) Unit cell parameters: a=8.4514(8) Å, b=12.1012(12) Å, c=12.4691(12) Å, α=90.000°, β=97.209(2°), γ=90.000°, and a cell volume of 1265.16 Å³ in P2₁/n space group.

HgI₂(tmeda) complex. HgI₂ (91 mg, 0.2 mmol) was suspended in −2 mL of CH₂Cl₂, and tmeda (60 μL, 0.4 mmol) was added. After ten minutes of stirring at room temperature, the red powders disappeared, and a clear colorless solution was obtained. The solution was filtered and dried under vacuum. Yield: 99 mg (86.8%). Needle-like crystals were obtained after two to three days by layering heptane on top of a CH₂Cl₂ solution. The structure matched the reported HgI₂(tmeda) complex.(5) Unit cell parameters: a=23.182(2) Å, b=7.2605(7) Å, c=15.0566(13) A, α=90.000°, β=111.233(3°), γ=90.000°, and a cell volume of 2362.17 Å³ in C2/c space group.

### Transformative Synthesis and Crystallization of II-VI Child Clusters

[Zn₁₄Se₁₃(tmeda)₆][BPh₄]2 cluster (1). The as-synthesized ZnI₂(tmeda) complex (26.1 mg, 60 μmol) and PPr₃ (24 μL, 120 μmol) were mixed in 0.5 mL of CH₂Cl₂. Cu₂₆Se₁₃(PEt₂Ph)₁₄ cluster (10 mg, 2 μmol) dissolved in 0.5 mL of CH₂Cl₂ was injected into the complex solution at room temperature. The reaction mixture gradually changed from red to colorless in about two minute. After stirring for another 16 hours, the reaction volume was reduced to 0.5 mL and transferred outside the glove box. 4.5 mL of pentane was added to precipitate the cluster. White precipitate was collected after centrifuging at 6,000 rpm for 5 minutes and redispersed in 1.5 mL of CH₂Cl₂ followed by filtration. To grow high-quality crystals, a solution of NaBPh₄ (20 mg, 58 μmol) in 0.5 mL of CH₃CN was combined with the CH₂Cl₂ solution. Around 1 mL of heptane was layered on top of the mixture. Rod-like crystals of [Zn₁₄Se₁₃(tmeda)₆][BPh₄]2 were obtained after two to three days at room temperature. Yield: ~4.1 mg (77.7% on Se basis).

Cd₁₄Se₁₃(tmeda)₆I₂ cluster (2). CdI₂(tmeda) complex (29 mg, 60 μmol) and PPr₃ (72 μL, 360 μmol) were combined in 0.5 mL of toluene to form a clear colorless solution at room temperature. Cu₂₆Se₁₃(PEt₂Ph)₁₄ cluster (10 mg, 2 μmol) dissolved in toluene (0.5 mL) was injected. The reaction mixture changed to colorless within one second. The reaction vial was stored at −20° C. Rod-like crystals of Cd₁₄Se₁₃(tmeda)₆I₂ were obtained after a couple of weeks. The cluster was found to co-crystallize with one CdI₂(tmeda) complex and two toluene molecules. Yield: ~3.6 mg (50.7% on Se basis).

Hg₁₄Se₁₃(tmeda)₆I₂ cluster (3). The addition of tmeda (1 mL) to HgI₂ (27.2 mg, 60 μmol) led to a clear colorless solution after stirring for 20~30 minutes, which was used as a stock solution. In a typical synthesis, 0.1 mL of the stock solution (6 μmol of Hg²⁺) and PPr₃ (2.4 μL, 12 μmol) were combined with 0.8 mL of tmeda. The total volume of tmeda is 0.9 mL (6 mmol). Cu₂₆Se₁₃(PEt₂Ph)₁₄ cluster (1 mg, 0.2 μmol) dissolved in 0.1 mL of toluene was injected at room temperature. The color of the reaction mixture changed to bright yellow in one minute. After about one hour, the reaction mixture was filtered into an NMR tube and layered with heptane. Yellow needle-like crystals of Hg₁₄Se₁₃(tmeda)₆I₂ formed after one to two days, together with small amounts of black precipitates. Yield: ~0.8 mg (83.6% on Se basis).

Zn₁₄Se₁₃(tmeda)₆Cl₂ cluster (4). ZnCl₂ (8.2 mg, 60 μmol) was suspended in 0.5 mL of CH₂Cl₂. Tmeda (18 μL, 120 μmol) and PPr₃ (24 μL, 120 μmol) were added and stirred for 20 minutes until the suspension turned into a clear colorless solution. A fresh solution of Cu₂₆Se₁₃(PEt₂Ph)₁₄ cluster (10 mg, 2 μmol) in 0.5 mL of CH₂Cl₂ was made and injected into the precursor solution at room temperature. The color of the reaction mixture gradually changed into colorless in about 20 minutes. After reacting overnight, the reaction mixture was layered with ~1 mL of pentane and stored at −20° C. Rectangular block-shaped crystals were obtained after one day. X-ray crystallography unveiled the structure of a Zn₁₄Se₁₃(tmeda)₆Cl₂ surrounded by four CH₂Cl₂ molecules, which matches the reported structure.(6) Yield: ~4.5 mg (83.0% on Se basis).

[Cd₁₄Se₁₃(tmeda)₆Cl₂]ₙ cluster (5). CdCl₂ (11 mg, 60 μmol) was combined with tmeda (36 μL, 240 μmol) and PPr₃ (24 μL, 120 μmol) in 0.5 mL of CH₂Cl₂. A clear colorless solution was obtained after five minutes of stirring. Cu₂₆Se₁₃(PEt₂Ph)₁₄ cluster (10 mg, 2 μmol) dissolved in 0.5 mL of CH₂Cl₂ was injected. The reaction mixture changed from red to colorless in 2-3 seconds. The addition of 4 mL of pentane generated white precipitates, which were washed with 1 mL of toluene and dried under vacuum. The crude product was redissolved in 1 mL of CH₂Cl₂ together with the help of 50 μL tmeda. The solution was filtered and layered with 1 mL of toluene. After two days at −20° C., crystals with triangular plate shape were obtained, which were composed of Cd₁₄Se₁₃(tmeda)₆Cl₂ linked into a three-dimensional network. Yield: ~5.1 mg (75.7% on Se basis).

[Hg₁₄Se₁₃(tmeda)₆Cl₂]ₙ cluster (6). HgCl₂ (16.3 mg, 60 μmol) and 0.5 mL of tmeda were combined with 0.5 mL of CH₂Cl₂. After stirring for 20-30 minutes, a clear colorless solution was obtained, which was used as a stock solution. In a typical synthesis, 0.05 mL of the stock solution (6 μmol of Hg²⁺) and PPr₃ (2.4 μL, 12 μmol) were combined with 0.85 mL of tmeda. The total volume of tmeda is 0.9 mL (6 mmol). Cu₂₆Se₁₃(PEt₂Ph)₁₄ cluster (1 mg, 0.2 μmol) dissolved in 0.1 mL of toluene was injected at room temperature. The color of the reaction mixture changed to bright yellow in 2-3 minutes. After one hour, the reaction mixture was filtered into an NMR tube and layered with heptane. Yellow crystals formed after 4-5 days at room temperature, which were composed of Hg₁₄Se₁₃(tmeda)₆Cl₂ interconnected into a three-dimensional network. Yield: ~0.7 mg (76.1% on Se basis).

[Zn₁₄Se₁₃(tmeda)₆(CH₃CN)][BPh₄]₂ (7). The synthesis and purification procedure were the same as (1). For crystallization, the white precipitate was redissolved in about 0.5 mL of CH₃CN instead of 1.5 mL of CH₂Cl₂. After adding the CH₃CN solution of NaBPh₄ and layering the mixture with heptane, small rhombic crystals came out after a couple of hours, which were identified to be [Zn₁₄Se₁₃(tmeda)₆(CH₃CN)][BPh₄]₂. Yield: 5.4 mg (80.4% on Se basis).

[Cd₁₄Se₁₃(tmeda)₆]_{0.75}[Cd₁₄Se₁₃(tmeda)₆I₈]_{0.25} cluster (8). The synthesis was similar to (2), except CH₂Cl₂ was used as the reaction solvent instead of toluene. For crystallization, around 1 mL of heptane was layered on top of the reaction mixture. Colorless rhombic crystals were observed after sitting at room temperature for two days, which were identified to be [Cd₁₄Se₁₃(tmeda)₆]_{0.75}[Cd₁₄Se₁₃(tmeda)₆I₈]_{0.25}. The overall composition is Cd₁₄Se₁₃(tmeda)₆I₂. Yield: 2.8 mg (39.4% on Se basis).

### Characterization

Ultraviolet-visible (UV-Vis) absorption spectroscopy. The absorption spectra were recorded on a Cary 5000 UV-Vis-NIR spectrophotometer with a 1 nm step size. For in-situ measurements, the time interval was set to 10 minutes for the first two hours and 60 minutes for the next 14 hours. The first scan was measured around two minutes after mixing the reactant solutions.

Nuclear Magnetic Resonance (NMR) spectroscopy. The ¹H NMR data were collected on a 400 MHz Bruker Avacne III HD spectrometer with 16 scans. Chemical shifts are given in 6 (ppm) and the solvent peak was used as internal reference (6=7.26 ppm for CDCl₃).

### Single-Crystal X-Ray Diffraction (Sc-XRD)

All the data were collected at 100 K on a Bruker Dual micro source D8 Venture diffractometer with Mo Kα radiation (X=0.71073 Å) and PHOTON III detector. The data frames were integrated and scaled using APEX4 software package. Multi-scan method (SADABS) was used for absorption correction. Intrinsic phasing structure solution provided all the non-H atoms. The structures were refined using full-matrix least-squares refinement using SHELXL program. The non-H atoms were refined with anisotropic displacement parameters. All the H atoms were calculated in idealized positions and refined riding on their parent atoms. The refinement cycles were carried out by minimizing the wR₂ function using F² rather than F values. R₁ is calculated to provide a reference to the conventional R value but its function is not minimized.

For [Zn₁₄Se₁₃(tmeda)₆][BPh₄]₂ (1), a rhombic crystal specimen (approximate dimensions: 0.371 mm×0.050 mm×0.050 mm) was used for analysis. The nanocluster crystallizes in the space group P2₁/c, with Z=4 for the formula-unit content Zn₇Se_{6.5}N₆C₁₄B₁C₄₄H₇₂. The integration of the data yielded a total of 192546 reflections to a maximum θ angle of 31.6° (0.68 Å resolution), of which 20332 were independent (completeness=99.9%, Rᵢₙₜ=7.59%, R_{sig}=4.57%). The final cell constants are a=17.3474(5) Å, b=21.3861(6) Å, c=17.9790(5) Å, α=90°, β=112.5730(10°), γ=90°, volume=6159.1(3) Å³. The asymmetric unit consists of half of a [Zn₁₄Se₁₃(tmeda)₆]²⁺ cluster around an inversion center, one [BPh₄]⁻ counterion, and two CH₂Cl₂ solvent molecules. In the final cycle of refinement, 20332 reflections (of which 15557 are observed with I>2σ(I)) were used to refine 630 parameters. The final refinement on F² converged at R₁=3.99%, wR₂=8.89% and S (goodness of fit)=1.040.

For Cd₁₄Se₁₃(tmeda)₆I₂ (2), a rod-like crystal specimen (approximate dimensions: 0.176 mm×0.104 mm×0.045 mm) was used for analysis. The nanocluster crystallizes in the space group P1̅, with Z=2 for the formula-unit content Cd₁₅Se₁₃N₁₄I₄C₅₆H₁₂₈. The final cell constants are a=15.0219(17) Å, b=21.0500(2) Å, c=21.3200(2) Å, α=93.781(3°), β=97.483(3°), γ=100.579(4°), volume=6542.4(13) Å³. The integration of the data yielded a total of 410183 reflections to a maximum θ angle of 30.7° (0.70 Å resolution), of which 40113 were independent (completeness=100.0%, Rᵢₙₜ=10.13%, R_{sig}=5.39%). The asymmetric unit consists of one Cd₁₄Se₁₃(tmeda)₆I₂ cluster, one CdI₂(tmeda) complex, and two toluene solvent molecules. There is a positional disorder around Cd₆ atom, which is refined in two parts with site occupation factors of 60% and 40%. Three of the tmeda ligands possess disordered areas around the —CH₂CH₂-moieties. All the disordered areas were refined in two parts, each with their site occupation factors fixed in the latter stages of refinement. One of the toluene molecules is also disordered. The two parts are refined with their geometry restricted to ideal hexagonal geometry (AFIX66) and the carbon atoms are restrained to idealized values (EADP, SADI). Program SQUEEZE, a part of the PLATON package of crystallographic software, was used to calculate the solvent accessible void and remove its contribution to the overall intensity data. The total voids added up to a volume of 1578 Å³ and a total electron count of 467 e⁻. In the final cycle of refinement, 40113 reflections (of which 27989 are observed with I>2σ(I)) were used to refine 980 parameters. The final refinement on F² converged at R₁=4.72%, wR₂=11.05% and S (goodness of fit)=1.033.

For Hg₁₄Se₁₃(tmeda)₆I₂ (3), a yellow needle-like crystal specimen (approximate dimensions: 0.107 mm×0.060 mm×0.053 mm) was used for analysis. The nanocluster crystallizes in the space group P2₁2₁2₂ with Z=4 for the formula-unit content Hg₁₄Se₁₃N₁₂I₂C₃₆H₉₆. The final cell constants are a=15.3894(9) Å, b=24.8074(14) Å, c=26.3346(14) Å, α=β=γ=90°, volume=10053.8(10) Å³. The integration of the data yielded a total of 142799 reflections to a maximum θ angle of 28.4° (0.75 Å resolution), of which 25228 were independent (completeness=99.9%, Rᵢₙₜ=7.12%, R_{sig}=5.21%). The asymmetric unit consists of one Hg₁₄Se₁₃(tmeda)₆I₂ cluster. Program SQUEEZE was used to remove the solvent accessible voids that added up to a total volume of 2358 Å³ and a total electron count of 1480 e⁻. In the final cycle of refinement, 25228 reflections (of which 22982 are observed with I>2σ(I)) were used to refine 718 parameters. The final refinement on F² converged at R₁=5.18%, wR₂=12.32% and S (goodness of fit)=1.119.

For Zn₁₄Se₁₃(tmeda)₆Cl₂ (4), a rectangular block crystal specimen (approximate dimensions: 0.095 mm×0.067 mm×0.048 mm) was used for analysis. The nanocluster crystallizes in the space group P1̅, with Z=2 for the formula-unit content Zn₁₄Se₁₃N₁₂Cl₁₀C₄₀H₁₀₄. The final cell constants are a=13.609(3) Å, b=13.646(3) Å, c=27.393(6) Å, α=90.058(7°), β=103.997(5°), γ=95.430(4°), volume=4912.2(18) Å³. The integration of the data yielded a total of 161107 reflections to a maximum θ angle of 28.0° (0.76 Å resolution), of which 22987 were independent (completeness=99.9%, Rᵢₙₜ=22.56%, R_{sig}=12.11%). The data quality was affected by the degradation of crystal during data collection. The asymmetric unit consists of a Zn₁₄Se₁₃(tmeda)₆Cl₂ cluster surrounded by four CH₂Cl₂ solvent molecules, which is possibly the reason of the crystallinity loss. Two of the Cl atoms in solvent molecules are disordered and refined as two parts. Program SQUEEZE was used to remove the solvent accessible voids that added up to a total volume of 665 Å³ and a total electron count of 267 e⁻. In the final cycle of refinement, 22987 reflections (of which 13011 are observed with I>2σ(I)) were used to refine 844 parameters. The final refinement on F² converged at R₁=9.26%, wR₂=22.08% and S (goodness of fit)=1.035.

For [Cd₁₄Se₁₃(tmeda)₆Cl₂]ₙ (5), a triangular crystal specimen (approximate dimensions: 0.155 mm×0.068 mm×0.052 mm) was used for analysis. The nanocluster crystallizes in the space group Fd3̅, with Z=16 for the formula-unit content Cd₇Se_{6.5}N₆C₁₁C₁₈H₄₈. The final cell constants are a=b=c=29.1627(14) Å, α=β=γ=90°, volume=24801.81(1) Å³. The integration of the data yielded a total of 35638 reflections to a maximum θ angle of 30.9° (0.69 Å resolution), of which 3283 were independent (completeness=99.8%, Rᵢₙₜ=6.19%, R_{sig}=3.09%). The asymmetric unit consists of 1/12 of a Cd₁₄Se₁₃(tmeda)₆Cl₂ cluster owing to the high symmetry in cubic space group. Individual clusters are linked by bridging Cl atoms into a polymeric structure in the 3D space. Program SQUEEZE was used to remove the solvent accessible voids that added up to a total volume of 10544 Å³ and a total electron count of 2225 e⁻. In the final cycle of refinement, 3283 reflections (of which 2654 are observed with I>2σ(I)) were used to refine 62 parameters. The final refinement on F² converged at R₁=2.29%, wR₂=6.07% and S (goodness of fit)=0.727.

For [Hg₁₄Se₁₃(tmeda)₆Cl₂]ₙ (6), a thin needle-like crystal specimen (approximate dimensions: 0.159 mm×0.039 mm×0.017 mm) was used for analysis. The nanocluster crystallizes in the space group P2₁/n, with Z=4 for the formula-unit content Hg₁₄Se₁₃N₁₂C₂C₃₆H₉₆. The final cell constants are a=20.7519 (7) Å, b=25.9453 (10) Å, c=22.7039 (8) Å, α=γ=90°, β=108.1230 (10°), volume=11617.7 (7) Å³. The integration of the data yielded a total of 303921 reflections to a maximum θ angle of 28.3° (0.75 Å resolution), of which 28967 were independent (completeness=100%, Rᵢₙₜ=10.75%, R_{sig}=5.63%). The asymmetric unit consists of a Hg₁₄Se₁₃(tmeda)₆Cl₂ cluster, which contains one terminal chloride and two bridging chloride ligands that shared by neighboring clusters. Two organic groups in the tmeda ligands are disordered and refined as two parts. Program SQUEEZE was used to remove the solvent accessible voids that added up to a total volume of 4403 Å³ and a total electron count of 1535 e⁻. In the final cycle of refinement, 28967 reflections (of which 20766 are observed with I>2σ(I)) were used to refine 758 parameters. The final refinement on F² converged at R₁=3.31%, wR₂=7.56% and S (goodness of fit)=1.017.

For [Zn₁₄Se₁₃(tmeda)₆(CH₃CN)][BPh₄]₂ (7), a rhombic crystal specimen (approximate dimensions: 0.209 mm×0.095 mm×0.067 mm) was used for X-ray crystallographic analysis. The nanocluster crystallizes in the space group P1̅, with Z=2 for the formula-unit content Zn₇Se_{6.5}N_{7.5}B₁C₄₅H_{72.5}. The final cell constants are a=13.789(7) Å, b=14.268(7) Å, c=17.402(8) Å, α=101.262(13°), β=99.500(10°), γ=106.776(12°), volume=3124.0(3) Å³. The integration of the data yielded a total of 173286 reflections to a maximum θ angle of 30.7° (0.70 Å resolution), of which 19205 were independent (completeness=100.0%, Rᵢₙₜ=8.48%, R_{sig}=4.51%). The asymmetric unit consists of half of a [Zn₁₄Se₁₃(tmeda)₆(CH₃CN)]²⁺ cluster, one BPh₄ counterion and one CH₃CN solvent molecule. There is positional disorder around the Zn₄ atom, which is refined in two parts. Another CH₃CN solvent molecule around the cluster is disordered and could not be properly refined. Program SQUEEZE was used to remove the solvent accessible voids that added up to a total volume of 248 Å³ and a total electron count of 76 e⁻. In the final cycle of refinement, 19205 reflections (of which 15240 are observed with I>2σ(I)) were used to refine 642 parameters. The final refinement on F² converged at R₁=5.38%, wR₂=14.73% and S (goodness of fit)=1.064.

For [Cd₁₄Se₁₃(tmeda)₆]_{0.75}[Cd₁₄Se₁₃(tmeda)₆I₈]_{0.25} (8), a rhombic crystal specimen (approximate dimensions: 0.176 mm×0.104 mm×0.045 mm) was used for X-ray crystallographic analysis. The nanocluster crystallizes in the space group R3̅, with Z=6 for the formula-unit content Cd₇Se_{6.5}N₆I₁C₁₈H₄₈. The final cell constants are a=16.0727(11) Å, b=16.0727(11) Å, c=35.1330(4) Å, α=90°, β=90°, γ=120°, volume=7850.1(14) Å³. The integration of the data yielded a total of 44266 reflections to a maximum θ angle of 27.5° (0.77 Å resolution), of which 3967 were independent (completeness=98.2%, Rᵢₙₜ=7.36%, R_{sig}=3.61%). The asymmetric unit consists of one sixth of a Cd₁₄Se₁₃(tmeda)₆I₂ cluster around the inversion center and a three-fold rotation axis. Due to the positional disorder at the Cd atoms around center Se1, the whole structure can be considered as a mixture of a Cd₁₄Se₁₃(tmeda)₆ and a Cd₁₄Se₁₃(tmeda)₆I₈ cluster with their occupation factor of 75% and 25%, respectively. The disordered areas on the tmeda ligand are refined in two parts. Program SQUEEZE was used to remove the solvent accessible voids that added up to a total volume of 1198 Å³ and a total electron count of 168 e⁻. In the final cycle of refinement, 3967 reflections (of which 3088 are observed with I>2σ(I)) were used to refine 980 parameters. The final refinement on F² converged at R₁=6.95%, wR₂=22.64% and S (goodness of fit)=1.072.

### Results

Transformative Syntheses of Atomically Precise II₁₄VI₁₃ Clusters

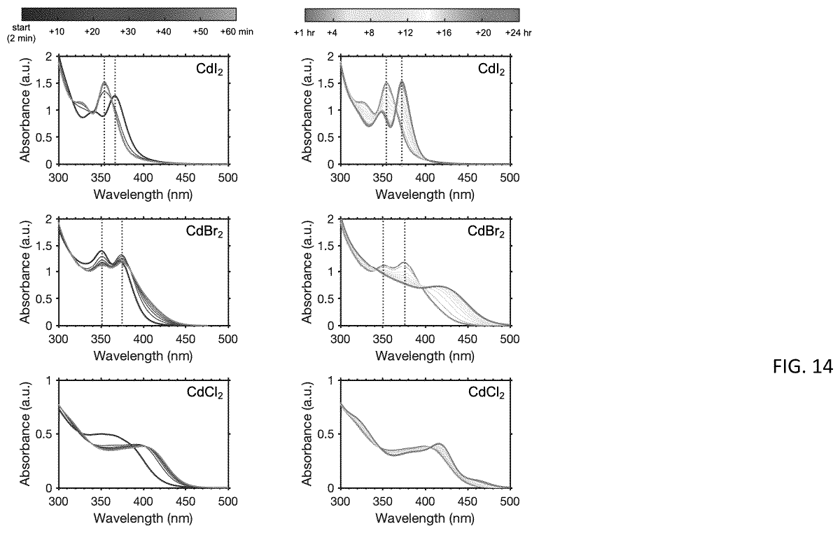

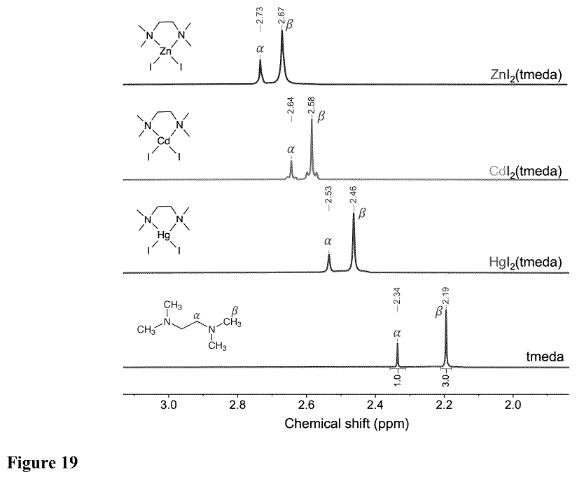

Metal-ligand coordination complexes play crucial roles in precise cation exchange, as they not only control the reactivity of cations but also determine the stability, solubility, and surface structures of the products (30). In this example, MX₂(tmeda) complexes were selected as the common carriers for IIB cations (FIG. 15A, B), as the tmeda ligand could coordinate with various IIB metal halides to form well-defined tetrahedral complexes (31). The chelating effect enhances complex stability, while the methyl groups increase their solubility in various organic solvents. MX₂(tmeda) complexes were synthesized by mixing MI₂ salts with tmeda ligands in CH₂Cl₂ solution (see SI for details). ¹H NMR measurements of synthesized complexes showed that the ZnI₂(tmeda) exhibited the largest downshift among three IIB cations (FIG. 19), indicating the strongest interaction between Zn and tmeda. This is consistent with hard-soft acid-base theory (HSAB), as Zn²⁺ is a harder acid (η=10.88 eV) compared with Cd², (10.29 eV) and Hg²⁺ (7.7 eV) and should bind more tightly to hard base amine (32). The relative strength of metal-ligand interactions is also assessed by the formation constants (K) of analogous metal-ethylenediamine complexes, with K_{Zn} (3.1′10¹¹)>K_{Cd} (4.0′10¹⁰)>K_{Hg} (5.4′10⁹) (33).

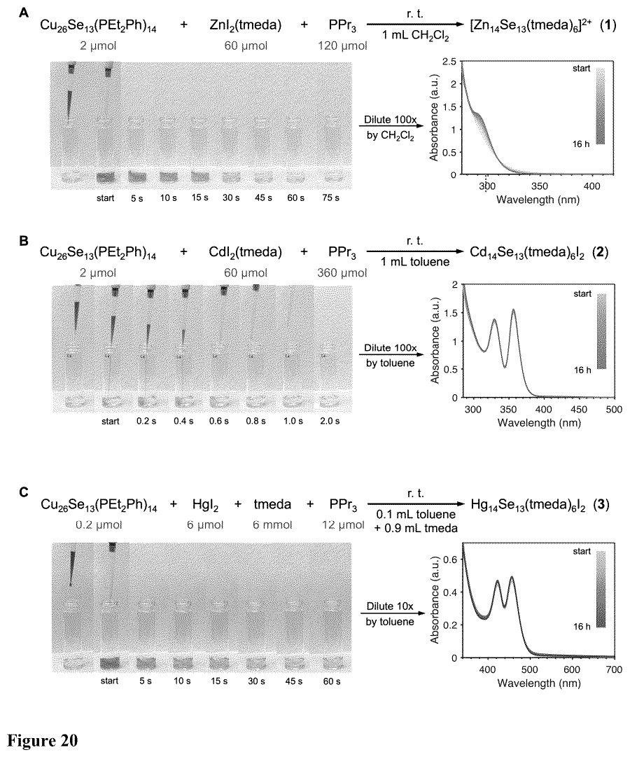

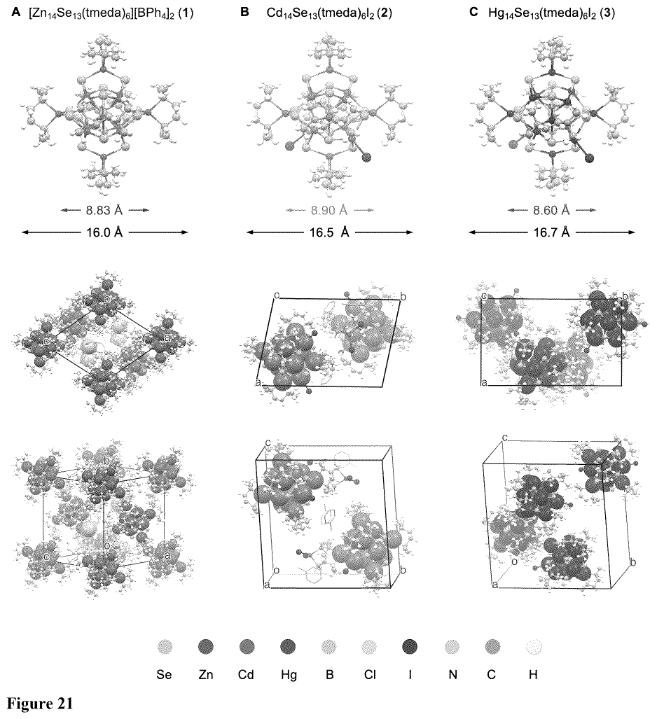

The template Cu₂₆Se₁₃(PEt₂Ph)₁₄ cluster was prepared based on the previously reported method (30, 34). It is noted that similar to colloidal cation exchange, soft base trialkylphosphine (PR₃) was added to promote the extraction of soft acid Cu⁺ (η=6.28 eV) and their complete exchange with harder M²⁺ ions (27, 28, 35). Without phosphine, the Cu⁺ to M²⁺ exchange was sluggish, resulting in undefined aggregations. In a typical Zn²⁺× exchange, Cu₂₆Se₁₃ cluster (2 mol) dissolved in CH₂Cl₂ was injected into a solution containing ZnI₂(tmeda) complex (60 mol) and PPr₃ (120 mol). The reaction mixture gradually changed from red to colorless within two minutes (FIG. 20), and an absorption feature at 292 nm appeared in half an hour (FIG. 15C, dashed line). A pair of distinct excitonic transitions at 288 nm (E₁) and 270 nm (E₂) were further resolved after purification and re-dissolving the clusters in methanol, which has a shorter solvent cut (FIG. 15C, solid line). Colorless rod-shaped crystals were obtained by layering heptane on a CH₂Cl₂ solution of purified clusters together with sodium tetraphenylborate (NaBPh₄, added as the bulkier counterion to facilitate crystal growth). Sc-XRD unveiled a [Zn₁₄Se₁₃(tmeda)₆]²⁺ cluster co-crystallized with two [BPh₄]⁻ (FIG. 21).

When CdI₂(tmeda) complex was used in the transformation, the red color of Cu₂₆Se₁₃ cluster disappeared within one second, and two sharp peaks at 356 nm and 329 nm were observed (FIG. 15D, dashed line), which remained unchanged throughout the reaction (FIG. 20). The faster Cd²⁺ exchange compared with Zn², could be explained by the weaker Cd-tmeda bond, leading to easier dissociation and release of Cd²⁺. The peak positions are reminiscent of previously reported (CdSe)₁₃ and Cd₁₄Se₁₃ species (17, 20). Rod-shaped crystals formed after storing the reaction mixture at −20° C. for about two to three weeks, and a Cd₁₄Se₁₃(tmeda)₆I₂ was resolved by sc-XRD (FIG. 21). Redissolving the crystals in toluene with the assistance of tmeda results in identical absorption peaks as the reaction mixture (FIG. 15D, solid line).

However, applying similar reaction conditions to Hg²⁺× exchange resulted in black precipitates immediately. The aggregation is consistent with previous observations for mercury chalcogenide QDs (37-39). It is hypothesized that the weaker Hg-tmeda bond led to instant ligand dissociation and aggregation of exchange clusters. Increasing tmeda concentration could reinforce their coordination with Hg²⁺, thus stabilizing the HgSe cluster. Indeed, when using excess tmeda as the solvent, the injection of Cu₂₆Se₁₃ into HgI₂(tmeda) resulted in a clear yellow solution in about one minute, and a pair of peaks at 457 nm and 423 nm appeared (FIG. 15E, dashed line), which were preserved over one day (FIG. 20). By layering heptane on the reaction mixture, yellow crystalline rods of Hg₁₄Se₁₃(tmeda)₆I₂ cluster were obtained. The crystals can be redissolved in toluene and tmeda, which shows nearly identical peaks at 456 nm and 423 nm (FIG. 15E, solid line).

Characterization of Atomic Structures of the Child II₁₄VI₁₃ Clusters

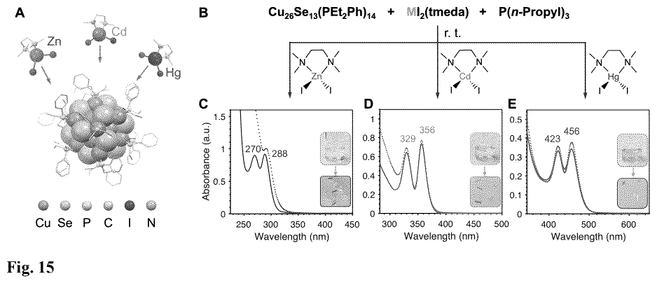

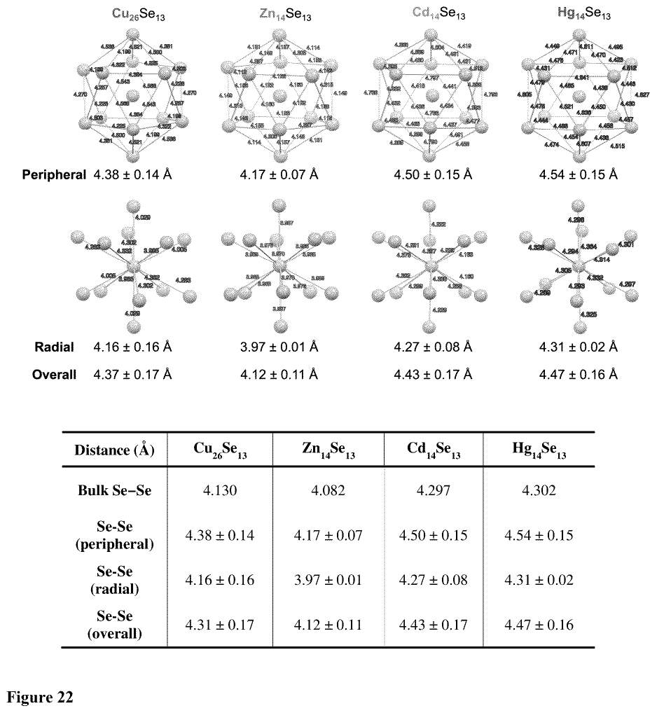

The total structures of parent and child clusters are compared in FIG. 16. Significantly, all the child clusters are constructed based on a common A₁₄B₁₃ skeleton, with 13 anions packed into a highly symmetric icosahedron, 6 edge bridging cations (^{e}M), and the remaining 8 cations distributed as core (cM) or face capping (^{f}M) cations. The Se₁₃ icosahedral lattices of child clusters are nearly identical to that of the parent Cu₂₆Se₁₃ cluster with slight variation in sizes (FIG. 16A, B). Based on the Se—Se distance measurements in Cu₂₆Se₁₃ (4.31±0.17 Å), contraction was found for Zn₁₄Se₁₃ (4.12±0.11 Å), while expansion was noted for Cd₁₄Se₁₃ (4.43±0.17 Å) and Hg₁₄Se₁₃ (4.47±0.16 Å, FIG. 22). The trend is comparable to that observed in bulk materials, which can be attributed to the size difference of cations. In addition, all the cluster frameworks are marginally expanded by ~1% to ~4% compared to their bulk lattices.

While the cation positions are ostensibly intricate, careful analysis shows a shell-by-shell assembly of cations into symmetric polyhedrons (FIG. 16C). In general, cations are bonded to Se₁₃ icosahedron (Iₕ) in three modes: (i) core cation inside the Iₕ shell (^{c}M, FIG. 16D); (ii) face-capping cation connected to three Se on Iₕ facet (^{f}M-Se₃, FIG. 16E); and (iii) edge-bridging cation bonded to two Se at the Iₕ edge (^{e}M-Se₂, FIG. 16F). In Cu₂₆Se₁₃ cluster, twelve ^{e}Cu form an inner Iₕ shell orthogonal to the anion Iₕ; eight ^{f}Cu form a distorted cube; and six ^{e}Cu are arranged into a distorted octahedron (FIG. 2C-F, blue). Each ^{f}Cu₈ and ^{e}Cu₆ cation is further coordinated to a PEt₂Ph ligand to form a complete cluster.

In all child clusters, six cations are located at the same edge-bridging sites (^{e}M) as the parent cluster (FIG. 16F). Each ^{e}M is further chelated by a tmeda ligand to form a ^{e}MSe₂(tmeda) surface motif. The saturated tetrahedral coordination resembles that of parent MI₂(tmeda) complexes, which further verifies cation exchange is accompanied by surface ligand exchange and that the surface structures of the child clusters are dictated by the parent coordination complex (30).

The positions of the remaining eight cations vary slightly among child clusters (FIG. 16D, E). In Hg₁₄Se₁₃, the eight cations are distributed as four core ^{c}Hg, two face-capping ^{f}HgSe₃I with saturated coordination, and two unsaturated ^{f′}HgSe₃. The unsaturated ^{f′}Hg is closer to the central Se (3.47±0.03 Å) compared to the saturated ^{f}Hg (4.03±0.01 Å). The Cd₁₄Se₁₃ cluster resembles Hg₁₄Se₁₃, except the two unsaturated ^{f′}Cd are pushed further inward (FIG. 16E). The ^{c}Cd₄, ^{f}Cd₂, and ^{f}Cd₂ distances to central Se are 2.75±0.01, 3.01±0.01, 4.17±0.02 Å, respectively. In Zn₁₄Se₁₃, the ^{f}Zn₄ and ^{c}Zn₄ are equivalent, forming a cubic ^{c}Zn₈ shell surrounding the central Se (FIG. 16C-E). They are closer to the shell Se (2.42±0.01 Å) than the central Se (2.80±0.05 Å). The absence of iodides on ZnSe cluster could be attributed to the unfavored bonding between hard Zn²⁺ and soft I⁻ (32). In all clusters, the cations bind more tightly to the shell Se than the central Se. The bond lengths with shell Se follow the trend of ^{c}M>^{f}M>^{f}M>^{e}M.

Structural Diversity in II₁₄VI₁₃ Clusters

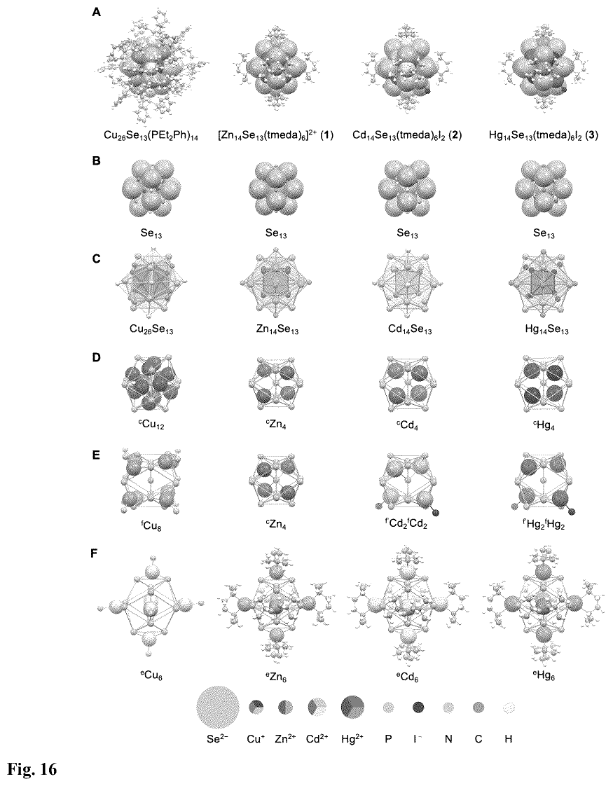

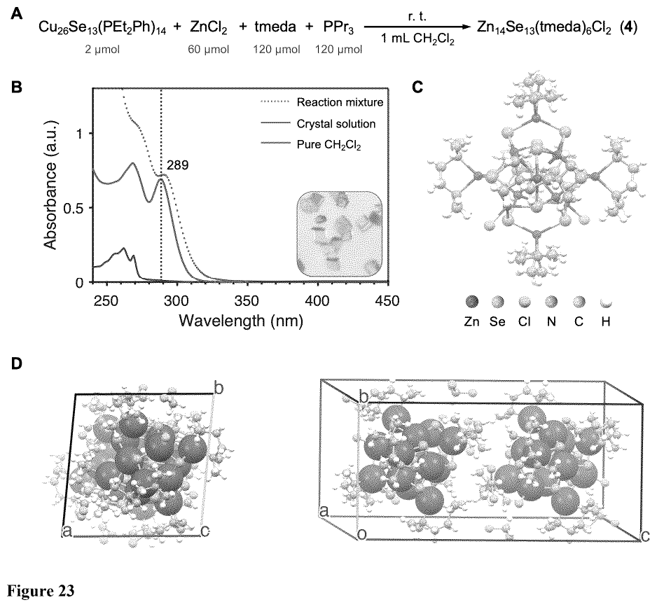

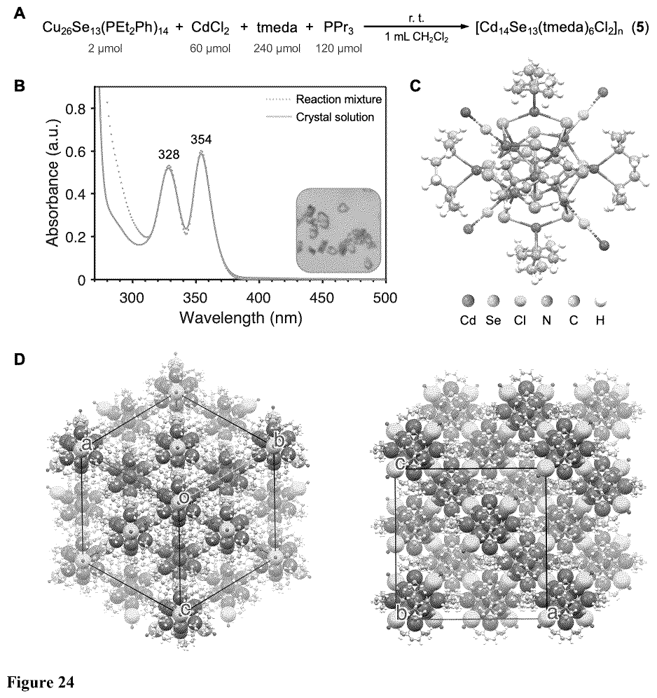

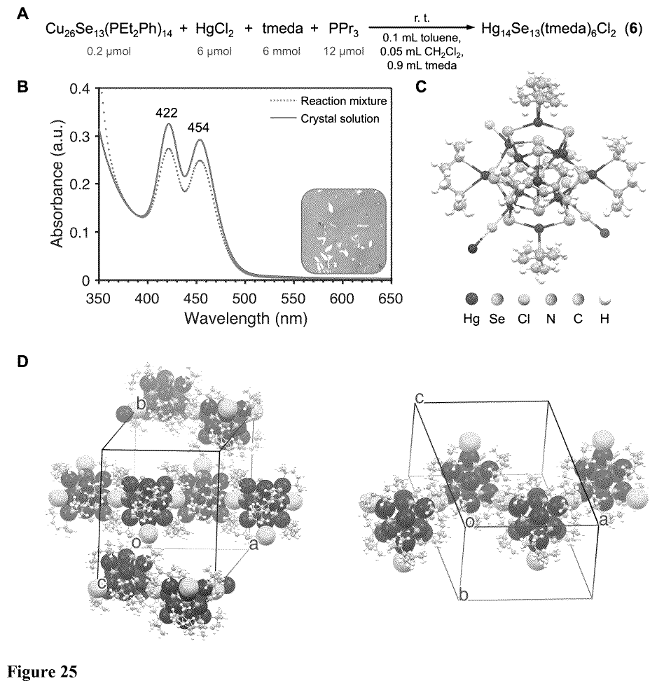

While the Se₁₃ framework and ^{e}M₆ surface motifs are consistent, the remaining eight cations are quite dynamic and vary with synthetic and crystallization conditions (FIG. 17). For example, when ZnCl₂ was used in the transformation (FIG. 17A and FIG. 23), a neutral Zn₁₄Se₁₃(tmeda)₆Cl₂ cluster was obtained, similar to the previously reported structure (15). The cluster shows the same symmetry as Cd₁₄Se₁₃(tmeda)₆I₂, with two chlorides pulling two Zn out of the Se shell to form face-capping ^{f}ZnSe₃Cl sites. The use of CdCl₂ results in a highly symmetric network of Cd₁₄Se₁₃(tmeda)₆Cl₂ cluster (FIG. 17B and FIG. 24). The eight Cd split evenly to form inner ^{c}Cd₄ and outer ^{f}Cd₄ tetrahedral shells. Such cation arrangement is nearly identical to the Cd₁₄Se₁₃ fragment in the Cd₂₆Se₁₇ cluster (30). The ^{f}Cd is each bonded to a Cl⁻. Through the linear Cd—Cl—Cd bridging bond, each cluster is further connected to four neighboring ones, forming infinite diamond superlattices (11, 12). When HgCl₂ was used, a polymeric chain of Hg₁₄Se₁₃(tmeda)₆Cl₂ cluster was obtained (FIG. 17C and FIG. 25). Three ^{f}Hg are coordinated to Cl⁻, and one ^{f}Hg is undercoordinated. The clusters are linked into helical chains via the two bridging chlorides (FIG. 25).

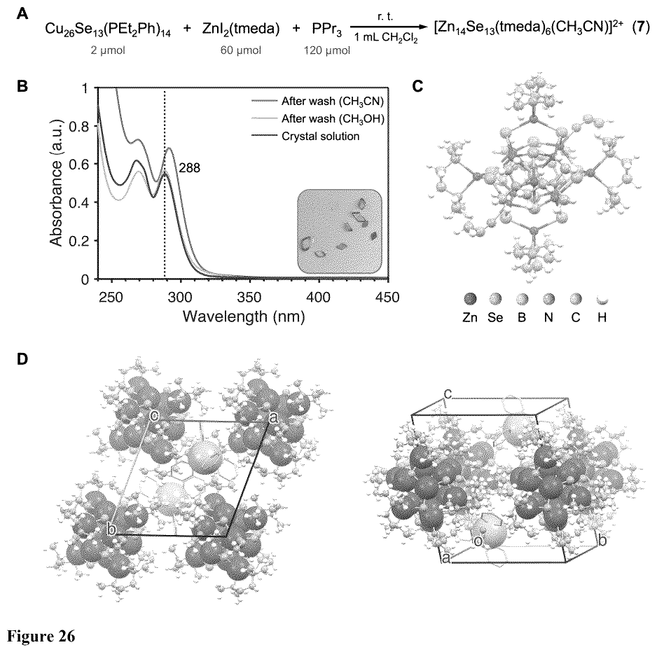

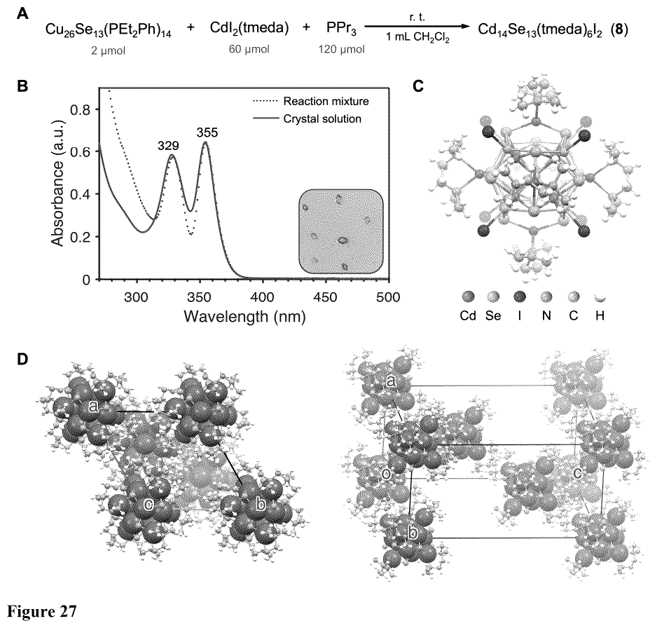

Solvents also play a critical role in positioning the eight cations. When CH₃CN was used in the crystallization of ZnSe clusters, two CH₃CN molecules were found to coordinate and pull out the ^{f}Zn in the body diagonal direction (FIG. 26). The occupancy of the ^{f}Zn—CH₃CN moieties is refined to 50% in XRD analysis, resulting in an overall formula of [Zn₁₄Se₁₃(tmeda)₆(CH₃CN)]²⁺ (FIG. 27). When the iodide-capped CdSe cluster was synthesized in CH₂Cl₂ instead of toluene, the resulting crystal can be viewed as a mixture of two clusters with 75% occupancy for [Cd₁₄Se₁₃(tmeda)₆]²⁺ and 25% occupancy for [Cd₁₄Se₁₃(tmeda)₆I₈]⁶⁻, comprising the overall composition of Cd₁₄Se₁₃(tmeda)₆I₂ (FIG. 27, 28). The polar CH₂Cl₂ could help shuffle the iodides among clusters during synthesis and crystallization.

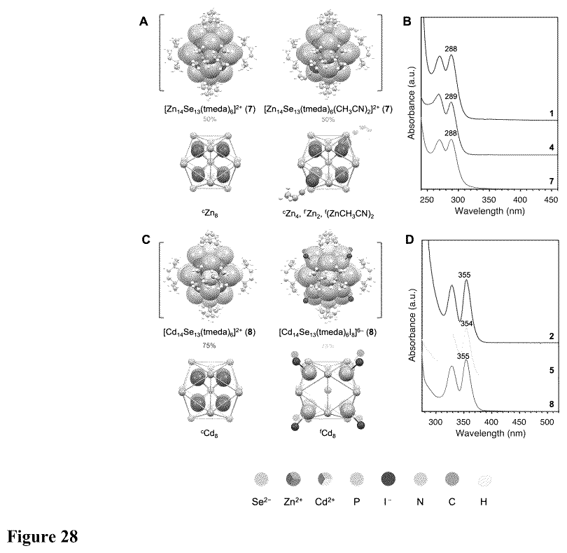

Significantly, despite the differences in cation positions, cluster charges, and coordinating halides, the absorption spectra remain nearly the same (FIG. 28). The peaks of neutral Zn₁₄Se₁₃(tmeda)₆Cl₂ cluster (289 nm/268 nm) are close to the positively charged cluster at 288 nm/270 nm (FIG. 17D). Minimal blueshifts of both peaks were observed in chloride-capped Cd₁₄Se₁₃ and Hg₁₄Se₁₃ cluster compared to the iodide-coordinated ones (FIG. 17E, F).

Correlation of Optical Properties and Electronic Structures of II₁₄VI₁₃ Artificial Atoms

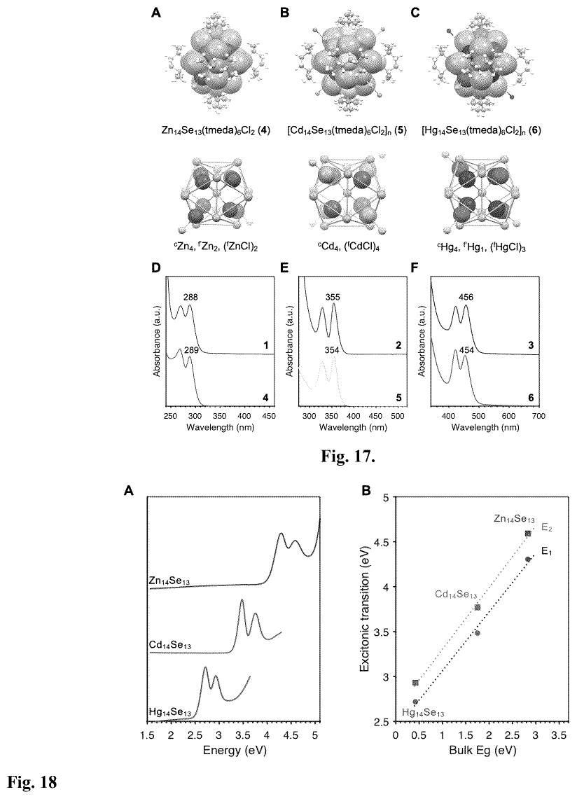

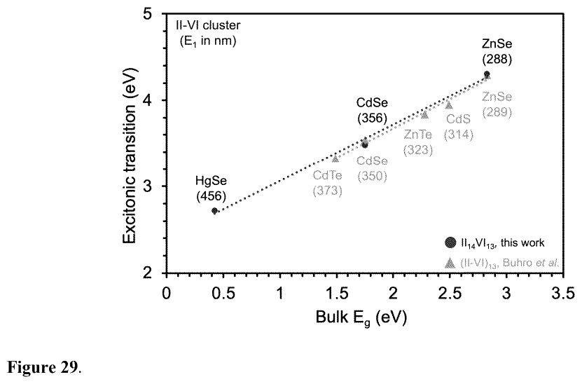

The sequence of homolog II-VI clusters enables the study of the precise structure-property correlation and the “periodic” rules in these artificial atoms. Notably, the Zn₁₄Se₁₃, Cd₁₄Se₁₃, and Hg₁₄Se₁₃ clusters all feature a “doublet” of absorption peaks with similar energy of 0.287, 0.286, and 0.212 eV, respectively (Table 1). The peaks redshift as the atomic number of the cation increases (FIG. 18A). A nearly linear fitting curve was observed when plotting E₁ (or E₂) peaks against the optical gaps (E_{g}) of corresponding bulk materials (FIG. 18B). (41, 42) Similar linear relationship of E₁ ~E_{g} was documented for a series of II-VI MSCs (22, 43). While the atomic structures of those MSCs are unknown, the resemblance in fittings indicates those clusters could share the same core structures with II₁₄VI₁₃ clusters (FIG. 29).

TABLE 1
The optical characteristics of the II₁₄VI₁₃ clusters (1-3)

| | Zn₁₄Se₁₃ | | Cd₁₄Se₁₃ | | Hg₁₄Se₁₃ | |
|---|---|---|---|---|---|---|
| Bulk E_{g} (eV) | 2.83 | | 1.75 | | 0.42 | |
| E₁ (nm, eV) | 288 | 4.306 | 356 | 3.483 | 456 | 2.719 |
| E₂ (nm, eV) | 270 | 4.593 | 329 | 3.769 | 423 | 2.931 |
| FWHM₁ (nm, eV) | 20.3 | 0.299 | 17.1 | 0.165 | 34.1 | 0.203 |
| FWHM₂ (nm, eV) | 25.0 | 0.426 | 20.5 | 0.233 | 34.8 | 0.241 |

| ε₁ (cm⁻¹ M⁻¹) | 6.5 × 10⁴ | 7.7 × 10⁴ | 2.3 × 10⁴ |
|---|---|---|---|
| ε₂ (cm⁻¹ M⁻¹) | 6.5 × 10⁴ | 6.9 × 10⁴ | 2.2 × 10⁴ |
| ε₁/ε₂ | 1.02 | 1.12 | 1.05 |
| ΔE = E₂ − E₁ (eV) | 0.287 | 0.286 | 0.212 |

### CONCLUSION

In conclusion, Example 5 builds on the findings in Examples 1-4 and validates the generalization of transformation synthesis to access a library of atomically defined II-VI artificial atoms with atomic engineering over their cations and surface ligands. By using universal MX₂(tmeda) coordination complexes as precise cation carriers, a family of homologous Zn₁₄Se₁₃, Cd₁₄Se₁₃, and Hg₁₄Se₁₃ clusters were obtained from the parent Cu₂₆Se₁₃ cluster. The shared A₁₃B₁₄ skeleton with nearly spherical shape, ensemble icosahedral packing and local tetrahedral coordination could be a general blueprint for constructing various semiconductor artificial atoms, akin to the zincblende and wurtzite as the common phases for bulk compound semiconductors. All the child clusters are characterized by a “doublet” of excitonic transitions which redshifts as the cation size increases. The generalization of the transformative synthesis is an important step towards atomic engineering of artificial atoms and expanding their diversity for various applications in energy, information, and biomedical nanotechnologies.

### Example 6: Synthesis of Additional Nanoclusters

Further to the methodologies provided above, additional nanoclusters can be formed as follows:

### Reaction Overview:

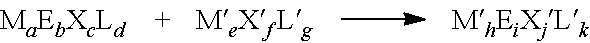

M, M′: cations, such as Cu⁺, Zn²⁺, Cd²⁺, Hg²⁺, Ga³⁺, In³⁺, Pb²⁺,
E: anions, such as S²⁻, Se²⁻, Te²⁻, . . .
X, X′: anionic ligands, such as halides (Cl⁻, I⁻), carboxylates (—O₂CR), thiolates (⁻SR), . . .
L, L′: neutral ligands, such as phosphines (PR₃), amines (NH₂R), . . .
a to k: numbers

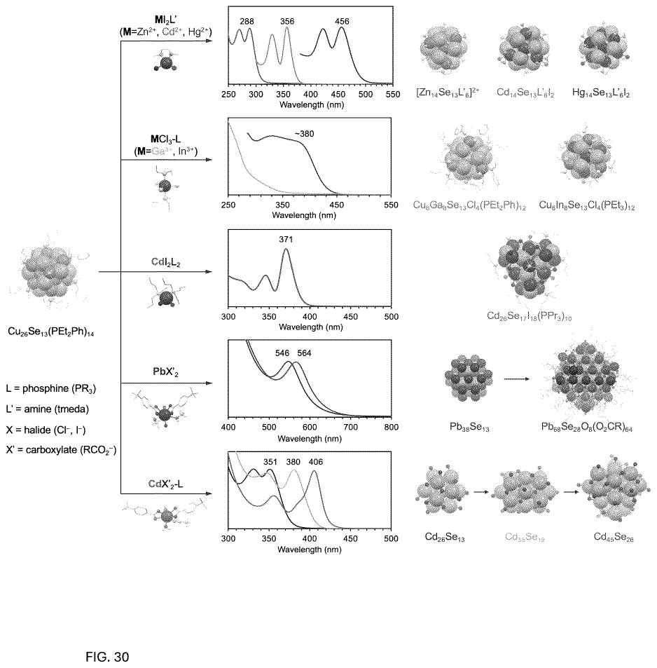

FIG. 30 provides an illustration of template clusters coordinating complexes exemplifying the above reaction overview.

### Specific Reactions for Nanocluster Synthesis are Provided Below:

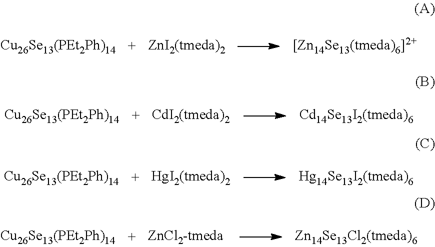

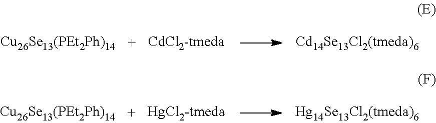

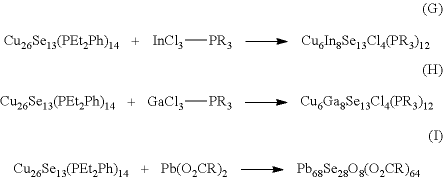

### Synthesis Methods Related to the Above Reactions and Resulting Clusters are Provided Below:

### Methods Related to Reactions (A)-(F)

### Chemicals

Selenium (pellets, <5 mm, 99.99%, trace metal basis), lithium triethylborohydride solution (1.0 M in tetrahydrofuran), chlorotrimethylsilane (99%), copper (I) acetate (97%), zinc iodide (ZnI₂, 98%), mercury iodide (HgI₂, 99%), zinc chloride (ZnCl₂, 98%), cadmium chloride (CdCl₂, 99.99% trace metal basis), sodium tetraphenylborate (NaBPh₄, 99.5%), N,N,N′,N′-tetramethylethylenediamine (tmeda, 99%), tri-n-propylphosphine (PPr₃, 97%), diethyl ether (anhydrous, 99.7%), methanol (CH₃OH, anhydrous, 99.8%), dichloromethane (CH₂Cl₂, anhydrous), pentane (anhydrous, 99%), toluene (anhydrous, 99.8%), and acetonitrile (CH₃CN, anhydrous, 99.8%) were purchased from Sigma-Aldrich. Diethylphenylphosphine (PEt₂Ph, 97%), cadmium iodide (CdI₂, 98%), and anhydrous n-heptane (99%) were purchased from Alfa Aesar. Mercury chloride (HgCl₂, 99.5%) was purchased from Thermo Scientific Chemicals. Chloroform-d (CDCl₃, 99.8%+0.03% v/v TMS) and methylene chloride-d₂ (CD₂Cl₂, 99.8%) were purchased from Cambridge Isotope Laboratories.

### Synthesis of the Anion Template Cluster and Cation Carrier Complexes

General considerations: All synthetic steps were performed in an air-free environment using a nitrogen-filled glovebox or standard Schlenk techniques.

Cu₂₆Se₁₃(PEt₂Ph)₁₄ cluster was prepared as described in Example 5 above. The structure and purity were confirmed by SC-XRD and low-temperature NMR analysis (400 MHz, −40° C., toluene-d₈). ³¹P{¹H}NMR: δ=−10.89 (1P), −13.08 (1P), −15.15 (1P), −18.30 (1P), −19.46 (1P), −21.81 (2P) ppm. The peak integrals matched with the seven different ligand environments in the centrosymmetric cluster.

ZnI₂(tmeda) complex: The suspension of ZnI₂ (319 mg, 1 mmol) and tmeda (300 μL, 2 mmol) in CH₂Cl₂ (~3 mL) became a clear colorless solution after stirring at room temperature for 15 minutes, followed by filtration to remove unreacted ZnI₂. After reducing the volume to 1 mL, a white suspension was obtained after adding heptane (4 mL) and centrifuged (4430 g, 5 min) outside the glove box. The precipitates were dissolved in CH₂Cl₂ (~5 mL) and filtered. White powders were obtained after drying under vacuum. Yield: 364 mg (83.6%). Colorless needle-like crystals were grown in about one day by layering heptane onto the CH₂Cl₂ solution of the product. The structure was confirmed by X-ray crystallography, matching the reported structure of ZnI₂(tmeda)⁶². Unit cell parameters: a=12.905(5) Å, b=7.751(2) Å, c=13.351(7) Å, α=90.000°, β=110.247(9°), γ=90.000°, cell volume of 1253.04 Å³ in C2/c space group. ¹H NMR (400 MHz, CDCl₃): δ=2.73 ppm (s, 4H, —CH₂—), 2.67 ppm (s, 12H, CH₃).

CdI₂(tmeda) complex: The suspension of CdI₂ (366.2 mg, 1 mmol) and tmeda (150 μL, 1 mmol) in CH₂Cl₂ (~3 mL) became clear after ten minutes of stirring at room temperature. The solution was filtered and layered with heptane. Needle-like colorless crystals formed after one day, which were rinsed with heptane and dried under vacuum. Yield: 275 mg (57.0%). The product can be recrystallized from CH₂Cl₂/heptane for X-ray crystallography. The structure matched the reported CdI₂(tmeda) complex³⁶. Unit cell parameters: a=8.4514(8) Å, b=12.1012(12) Å, c=12.4691(12) Å, α=90.000°, β=97.209(2°), γ=90.000°, cell volume of 1265.16Δ in P2₁/n space group. ¹H NMR (400 MHz, CDCl₃): δ=2.64 ppm (s+d satellites, J=4 Hz, 4H, —CH₂—), 2.58 ppm (s+d satellites, J=4 Hz, 12H, CH₃).

HgI₂(tmeda) complex: The suspension of HgI₂ (91 mg, 0.2 mmol) and tmeda (60 μL, 0.4 mmol) in CH₂Cl₂ (~2 mL) became a clear colorless solution after ten minutes of stirring at room temperature, with the red powders disappeared. The solution was filtered and dried under vacuum. Yield: 99 mg (86.8%). Layering heptane on top of a CH₂Cl₂ solution produced needle-like crystals after two to three days. The structure matched the reported HgI₂(tmeda) complex³⁶. Unit cell parameters: a=23.182(2) Å, b=7.2605(7) Å, c=15.0566(13) Å, α=90.000°, β=111.233(3)°, γ=90.000°, cell volume of 2362.17 Å³ in C2/c space group. ¹H NMR (400 MHz, CDCl₃): δ=2.53 ppm (s, 4H, —CH₂—), 2.46 ppm (s, 12H, CH₃).

Reaction (A). Zn₁₄Se₁₃(tmeda)₆:

ZnI₂(tmeda) complex (26.1 mg, 60 μmol) and PPr₃ (24 μL, 120 μmol) were mixed in 0.5 mL of CH₂Cl₂. Cu₂₆Se₁₃(PEt₂Ph)₁₄ cluster (10 mg, 2 μmol) dissolved in 0.5 mL of CH₂Cl₂ was injected into the complex solution at room temperature. The reaction mixture gradually changed from red to colorless in about two minutes. After stirring overnight, the reaction volume was reduced to 0.5 mL and transferred outside the glove box. After adding 4.5 mL of pentane and centrifuging (4430 g, 5 min), white precipitates were collected, redispersed in CH₂Cl₂ (1.5 mL) and filtered. To improve crystal quality, the CH₂Cl₂ solution was combined with a solution of NaBPh₄ (20 mg, 58 μmol) in 0.5 mL of CH₃CN and layered with heptane (~1 mL). Rod-like crystals of [Zn₁₄Se₁₃(tmeda)₆][BPh₄]₂ were obtained after 2-3 days at room temperature. Yield: 4.1 mg (77.7% on Se basis).

Reaction (B). Cd₁₄Se₁₃I₂(tmeda)₆:

Cd₄Se₃(tmeda)₆I₂ (2): CdI₂(tmeda) complex (29 mg, 60 μmol) and PPr₃ (72 μL, 360 μmol) were combined in 0.5 mL of toluene to form a clear colorless solution. Cu₂₆Se₁₃(PEt₂Ph)₁₄ cluster (10 mg, 2 μmol) dissolved in 0.5 mL of toluene was injected. The reaction mixture changed to colorless within one second and was stored at −20° C. Rod-like crystals of Cd₁₄Se₁₃(tmeda)₆I₂ were obtained after a few weeks. The cluster co-crystallized with one CdI₂(tmeda) complex and several toluene molecules. Yield: ~3.6 mg (50.7% on Se basis).

Reaction (C). Hg₁₄Se₁₃(tmeda)₆I₂:

A stock solution was prepared by mixing HgI₂ (27.2 mg, 60 μmol) with tmeda (1 mL) and stirring for 20-30 minutes. In a typical synthesis, 0.1 mL of the solution (6 μmol of Hg²⁺) and PPr₃ (2.4 μL, 12 μmol) were combined with tmeda (0.8 mL). The total volume of tmeda is 0.9 mL (6 mmol). Cu₂₆Se₁₃(PEt₂Ph)₁₄ cluster (1 mg, 0.2 μmol) in 0.1 mL of toluene was injected at room temperature. The color of the reaction mixture changed to bright yellow in one minute. After about one hour, the reaction mixture was filtered into an NMR tube and layered with heptane. Yellow needle-like crystals of Hg₁₄Se₁₃(tmeda)₆I₂ formed after 1-2 days, together with small amounts of black precipitates. Yield: ~0.8 mg (83.6% on Se basis).

Reaction (D) Zn₁₄Se₁₃(tmeda)₆Cl₂:

A clear colorless solution of ZnCl₂ (8.2 mg, 60 μmol), tmeda (18 μL, 120 μmol) and PPr₃ (24 μL, 120 μmol) in 0.5 mL of CH₂Cl₂ formed by stirring for 20 minutes. A fresh solution of Cu₂₆Se₁₃(PEt₂Ph)₁₄ (10 mg, 2 μmol) in 0.5 mL of CH₂Cl₂ was injected at room temperature, turning to colorless in about 20 minutes. After reacting overnight, the reaction mixture was layered with pentane (~1 mL) and stored at −20° C. Rectangular block-shaped crystals of Zn₁₄Se₁₃(tmeda)₆Cl₂ were obtained after one day. The cluster surrounded by several CH₂Cl₂ molecules matches the reported structure⁴⁶. Yield: ~4.5 mg (83.0% on Se basis).

Reaction (E) [Cd₁₄Se₁₃(tmeda)₆Cl₂]ₙ:

CdCl₂ (11 mg, 60 μmol) was combined with tmeda (36 μL, 240 μmol) and PPr₃ (24 μL, 120 μmol) in 0.5 mL of CH₂Cl₂. A clear colorless solution was obtained after five minutes of stirring. Cu₂₆Se₁₃(PEt₂Ph)₁₄ cluster (10 mg, 2 μmol) in 0.5 mL of CH₂Cl₂ was injected at room temperature. The reaction mixture changed from red to colorless in 2-3 seconds. White precipitates were produced by adding 4 ml of pentane and washed with 1 mL of toluene. After drying under vacuum, the crude product was redissolved in CH₂Cl₂ (~1 mL) and tmeda (50 μL). The solution was filtered and layered with 1 mL of toluene. After two days at −20° C., crystals as triangular plates formed, consisting of Cd₁₄Se₁₃(tmeda)₆Cl₂ clusters linked into a 3D diamond network. Yield: ~5.1 mg (75.7% on Se basis).

Reaction (F) [Hg₁₄Se₁₃(tmeda)₆Cl₂]ₙ: A colorless stock solution was prepared by stirring HgCl₂ (16.3 mg, 60 μmol) in tmeda (0.5 mL) and CH₂Cl₂ (0.5 mL) for 20-30 minutes. In a typical synthesis, the stock solution (0.1 mL, 6 μmol of Hg²⁺) and PPr₃ (2.4 μL, 12 μmol) were combined with 0.85 mL of tmeda. The total volume of tmeda is 0.9 mL (6 mmol). Cu₂₆Se₁₃(PEt₂Ph)₁₄ cluster (1 mg, 0.2 μmol) in 0.1 mL of toluene was injected at room temperature. The reaction mixture changed to bright yellow in 2-3 minutes. After one hour, the reaction mixture was filtered into an NMR tube and layered with heptane. Yellow crystals formed after 4-5 days at room temperature, which contained Hg₁₄Se₁₃(tmeda)₆Cl₂ clusters connected into polymeric chains. Yield: ~0.7 mg (76.1% on Se basis).

### Overview of Reactions (G) and (H)

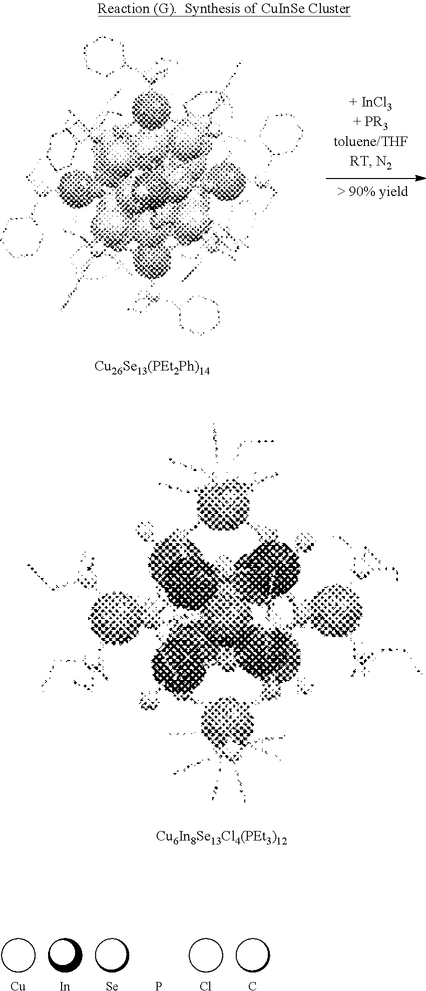

In a typical In³⁺ exchange reaction (above), Cu₂₆Se₁₃(PEt₂Ph)₁₄ cluster dissolved in toluene was injected into a tetrahydrofuran (THF) solution containing 13 equivalents of InCl₃ and 78 equivalents of phosphine ligands. Note that excess phosphine was added to solvate InCl₃ in organic solvents as well as to promote Cu⁺ extraction from the cluster framework. Upon injection, the reaction mixture changed from dark red to light yellow in a few seconds. In contrast to the absorption spectrum of the Cu₂₆Se₁₃ cluster as a decay curve, the yellow solution exhibited a hump at ~380 nm with an onset at ~440 nm. The disappearance of the absorption tail in 500-900 nm indicates the completed conversion of the Cu₂₆Se₁₃ cluster.

The absorption spectrum remained unchanged for more than a day, suggesting that there was no further growth or conversion. When the crystals were redissolved in toluene, the absorption spectrum showed the same shoulder band at −380 nm, and a second peak at −330 nm was resolved. The resemblance between the absorption spectra of the reaction mixture and the crystal solution suggests the high purity of the as-synthesized cluster.

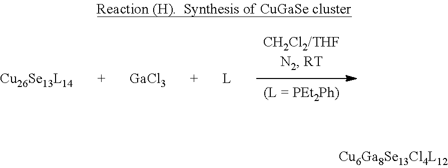

The precise cation exchange in Reaction (G) above can be readily applied to Ga³⁺, resulting in a homologous Cu₆Ga₈Se₁₃Cl₄(PR₃)₁₂ cluster. The Ga³⁺ exchange is slightly slower than the In³⁺ exchange, taking eight seconds for color change instead of one second. This is likely due to the stronger Ga—Cl interaction, as Ga³⁺ (η=17 eV) is a harder acid than In³⁺ (13 eV). The absorption spectrum shows an onset at −330 nm, which is blueshifted compared to Cu₆In₈Se₁₃ cluster, consistent with the larger band gap of bulk CuGaSe2 (1.68 eV) than CuInSe2 (1.04 eV).4 No well-defined absorption peaks were observed, probably due to the overlapping with ligand absorption in the UV region. While lacking features, the absorption spectra from different reaction mixtures are consistent, as well as that of the crystal solution, confirming the purity of the clusters.

### Methods for Reactions G. and H.

### Chemicals

Indium (III) chloride (InCl₃, 98%), triphenylphosphine (PPh₃, 97%), N,N,N′,N′-tetramethylethylenediamine (TMEDA, 99%), and toluene (anhydrous, 99.8%) were purchased from Sigma Aldrich. Triethylphosphine (PEt₃, 99%), tetrahydrofuran (THF, anhydrous, 99.8%), methylene chloride (CH₂Cl₂, 99.5%), and n-heptane (anhydrous, 99%) were purchased from Fisher Scientific. Diethylphenyl phosphine (PEt₂Ph, 98%) was purchased from aablocks. Chloroform-d (CDCl₃, ≥99.8 atom % D+0.05% v/v TMS) was purchased from Cambridge Isotope Laboratories. Cu₂₆Se₁₃(PEt₂Ph)₁₄ cluster was synthesized as described in Example 5 above.

### Synthesis of Ternary Clusters Via Cation Exchange

Cu₆In₈Se₁₃Cl₄(PEt₃)₁₂ cluster. InCl₃ (11.6 mg, 52 μmol) was dissolved in 0.5 mL of THF, followed by addition of PEt₃ (48 μL, 312 μmol). The dark red solution of Cu₂₆Se₁₃(PEt₂Ph)₁₄ cluster (20 mg, 4 μmol) in toluene (0.5 mL) was injected into the colorless In³⁺ precursor solution at room temperature, leading to a clear light-yellow solution in a few seconds. Layering the reaction mixture with −1 mL of heptane led to yellow crystalline blocks after 3~4 days. The mother liquor was discarded, and the crystals were rinsed with heptane, followed by drying under vacuum. Yield: 12~13 mg (77-84% based on Se).

Cu₆In₈Se₁₃Cl₄(PEt₂Ph)₁₂ cluster. The procedure was adapted from the synthesis of the cluster above by replacing PEt₃ with PEt₂Ph (83.6 μL, 312 μmol). After injection of Cu₂₆Se₁₃(PEt₂Ph)₁₄ cluster solution, a clear light-yellow solution was obtained within a few seconds. The reaction mixture was layered using ~0.8 mL heptane and stored at room temperature. Light yellow rod-like crystals formed overnight. After removing the mother liquor, the crystals were rinsed using heptane and dried under vacuum. Yield: 16-17 mg (90-95% based on Se).

Cu₆Ga₈Se₁₃Cl₄(PEt₂Ph)₁₂ cluster. GaCl₃ (9.2 mg, 52 μmol) was dissolved in 0.5 mL of THF, and combined with PEt₂Ph (83.6 μL, 312 μmol). Cu₂₆Se₁₃(PEt₂Ph)₁₄ cluster (20 mg, 4 μmol) was dissolved in CH₂Cl₂ (0.5 mL) and injected into the Ga³⁺ precursor solution at room temperature. Upon injection, the dark red solution turned pale yellow in one second, then faded into a clear colorless solution after 6-7 seconds. Colorless crystal blocks formed after 4-5 days via vapor diffusion method using hexane as the antisolvent.

Cation exchange for testing reaction parameters. In a standard test reaction, Cu₂₆Se₁₃(PEt₂Ph)₁₄ cluster was dissolved in toluene with a concentration of 10 mg/mL. InCl₃ (0.6 mg, 2.6 μmol) was dissolved in 0.1 mL of THF and combined with PEt₂Ph (4.2 μL, 15.6 μmol) diluted by toluene (0.3 mL). 0.1 mL of Cu₂₆Se₁₃ (1 mg, 0.2 μmol) was injected at room temperature. The molar ratio between In³⁺ and Cu₂₆Se₁₃ was 13:1. The conditions were varied based on this, and only one parameter was modified for each test reaction, including the ratio of InCl₃ (13-104 equiv.), replacement by InI₃ (1.3 mg, 2.6 μmol), addition of TMEDA (0.1 mL). The reaction mixtures were diluted to 0.02 mM (calculated based on input Cu₂₆Se₁₃ cluster) for absorption measurements.

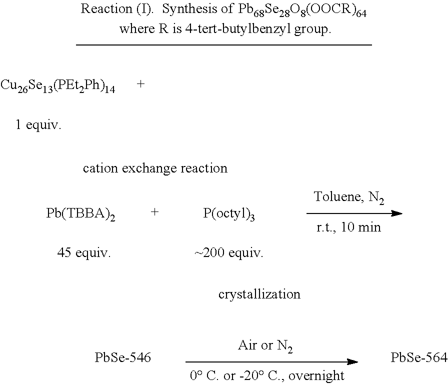

### Chemicals

Lead (II) acetate trihydrate (Pb(OAc)₂·3H₂O, ≥99.99% trace metals basis), 4-tert-butylbenzoic acid (TBBAH, 99%), tri-n-octylphosphine (TOP, 97%), and anhydrous toluene (99.8%) were purchased from Sigma Aldrich. Methylene chloride (CH₂Cl₂, 99.5%), methanol (CH₃OH, 99.8%), acetonitrile (CH₃CN, 99.9%), and n-hexane (98.5%) were purchased from Fisher Scientific. Cu₂₆Se₁₃(PEt₂Ph)₁₄ cluster was synthesized as described in Example 5 above and lead (II) 4-tert-butylbenzoate compound [Pb(TBBA)₂(CH₃OH)₂]ₙ was synthesized following the published procedure. Nano Lett. 2025, 25, 16, 6382-6389.

Synthesis and Crystallization of Pb₆₈Se₂₈O₈(TBBA)₆₄

The reaction was performed under an inert atmosphere in a nitrogen-filled glove box. [Pb(TBBA)₂(CH₃OH)₂]ₙ crystals (25 mg, 45 μmol) were dissolved in 0.4 mL of toluene. Cu₂₆Se₁₃(PEt₂Ph)₁₄ cluster (5 mg, 1 μmol) was dissolved in 0.3 mL of toluene and combined with TOP (0.1 mL, 224 μmol). The Cu₂₆Se₁₃-phosphine solution was injected into the vigorously stirred Pb(II) solution at room temperature, leading to a dark reddish reaction mixture. The reaction mixture was stored at −20° C., and dark red crystals formed overnight. The crystals were collected and gently rinsed with toluene. Yield: 4-5 mg (31-38% based on Se). Red crystals were also observed when the reaction mixture was stored in air at 0° C. after several days. When the reaction mixture was stored at low temperatures (0 or −20° C.) for several days, red crystals were obtained and a Pb₆₈Se₂₈O₈(TBBA)₆₄ NC was resolved by SC-XRD. The Pb₆₈Se₂₈ crystals redissolved in hexane show a sharp absorption peak at 564 nm with a linewidth of 64 nm or 248 meV.

### REFERENCES FOR EXAMPLE 5

1. R. C. Ashoori, Electrons in artificial atoms. Nature 379, 413-419 (1996).
2. M. A. Kastner, Artificial Atoms. Phys Today 46, 24-31 (1993).
3. A. L. Efros, L. E. Brus, Nanocrystal Quantum Dots: From Discovery to Modern Development. ACS Nano 15, 6192-6210 (2021).
4. C. B. Murray, C. R. Kagan, M. G. Bawendi, Self-organization of CdSe nanocrystallites into three-dimensional quantum dot superlattices. Science (1979) 270, 1335 (1995).
5. E. V. Shevchenko, D. V. Talapin, N. A. Kotov, S. O'Brien, C. B. Murray, Structural diversity in binary nanoparticle superlattices. Nature 439, 55-59 (2006).
6. C. R. Kagan, E. Lifshitz, E. H. Sargent, D. V. Talapin, Building devices from colloidal quantum dots. Science 353, 885-892 (2016).
7. C. Zeng, Y. Chen, K. Kirschbaum, K. J. Lambright, R. Jin, Emergence of hierarchical structural complexities in nanoparticles and their assembly. Science 354, 1580-1584 (2016).
8. C. Zeng, Precision at the nanoscale: on the structure and property evolution of gold nanoclusters. Pure Appl. Chem. 90, 1409-1428 (2018).
9. I. G. Dance, A. Choy, M. L. Scudder, Syntheses, properties, and molecular and crystal structures of (Me₄N)4[E₄M10(SPh)16] (E=sulfur or selenium; M=zinc or cadmium): molecular supertetrahedral fragments of the cubic metal chalcogenide lattice. J Am Chem Soc 106, 6285-6295 (1984).
10. N. Herron, J. C. Calabrese, W. E. Farneth, Y. Wang, Crystal structure and optical properties of Cd₃₂Si₄(SC₆H₅)₃₆. DMF₄, a cluster with a 15 angstrom CdS core. Science 259, 1426-1428 (1993).
11. T. Vossmeyer, G. Reck, L. Katsikas, E. T. K. Haupt, B. Schulz, H. Weller, A “Double-Diamond Superlattice” Built Up of Cd₁₇S₄(SCH₂CH₂OH)₂₆ Clusters. Science 267, 1476-1479 (1995).
12. N. Zheng, X. Bu, H. Lu, Q. Zhang, P. Feng, Crystalline Superlattices from Single-Sized Quantum Dots. J Am Chem Soc 127, 11963-11965 (2005).
13. V. N. Soloviev, A. Eichhöfer, D. Fenske, U. Banin, Size-dependent optical spectroscopy of a homologous series of CdSe cluster molecules. J. Am. Chem. Soc. 123, 2354-2364 (2001).
14. A. N. Beecher, X. Yang, J. H. Palmer, A. L. Lagrassa, P. Juhas, S. J. L. Billinge, J. S. Owen, Atomic structures and gram scale synthesis of three tetrahedral quantum dots. J. Am. Chem. Soc. 136, 10645-10653 (2014).
15. C. B. Khadka, A. Eichhöfer, F. Weigend, J. F. Corrigan, Zinc Chalcogenolate Complexes as Precursors to ZnE and Mn/ZnE (E=S, Se) Clusters. Inorg. Chem. 51, 2747-2756 (2012).
16. D. C. Gary, S. E. Flowers, W. Kaminsky, A. Petrone, X. Li, B. M. Cossairt, Single-crystal and electronic structure of a 1.3 nm indium phosphide nanocluster. J. Am. Chem. Soc. 138, 1510-1513 (2016).
17. M. S. Bootharaju, W. Baek, G. Deng, K. Singh, O. Voznyy, N. Zheng, T. Hyeon, Structure of a subnanometer-sized semiconductor Cd14Se₁₃ cluster. Chem 8, 2978-2989 (2022).
18. A. Kasuya, R. Sivamohan, Y. A. Barnakov, I. M. Dmitruk, T. Nirasawa, V. R. Romanyuk, V. Kumar, S. V Mamykin, K. Tohji, B. Jeyadevan, K. Shinoda, T. Kudo, O. Terasaki, Z. Liu, R. V Belosludov, V. Sundararajan, Y. Kawazoe, Ultra-stable nanoparticles of CdSe revealed from mass spectrometry. Nat. Mater. 3, 99-102 (2004).
19. S. Kudera, M. Zanella, C. Giannini, A. Rizzo, Y. Li, G. Gigli, R. Cingolani, G. Ciccarella, W. Spahl, W. J. Parak, L. Manna, Sequential growth of magic-size CdSe nanocrystals. Adv. Mater. 19, 548-552 (2007).
20. Y. Wang, Y.-H. Liu, Y. Zhang, F. Wang, P. J. Kowalski, H. W. Rohrs, R. A. Loomis, M. L. Gross, W. E. Buhro, Isolation of the Magic-Size CdSe Nanoclusters [(CdSe)₁₃(n-octylamine)₁₃] and [(CdSe)₁₃(oleylamine)₁₃]. Angew. Chem. Int. Ed. 51, 6154-6157 (2012).
21. A. S. Mule, S. Mazzotti, A. A. Rossinelli, M. Aellen, P. T. Prins, J. C. van der Bok, S. F. Solari, Y. M. Glauser, P. V Kumar, A. Riedinger, D. J. Norris, Unraveling the Growth Mechanism of Magic-Sized Semiconductor Nanocrystals. J. Am. Chem. Soc. 143, 2037-2048 (2021).
22. Y. Zhou, R. Jiang, Y. Wang, H. W. Rohrs, N. P. Rath, W. E. Buhro, Isolation of Amine Derivatives of (ZnSe)34 and (CdTe)34. Spectroscopic Comparisons of the (II-VI)13 and (II-VI)34 Magic-Size Nanoclusters. Inorg. Chem. 58, 1815-1825 (2019).
23. C. B. Williamson, D. R. Nevers, A. Nelson, I. Hadar, U. Banin, T. Hanrath, R. D. Robinson, Chemically reversible isomerization of inorganic clusters. Science 363, 731-735 (2019).
24. C. B. Murray, D. J. Norris, M. G. Bawendi, Synthesis and characterization of nearly monodisperse CdE (E=sulfur, selenium, tellurium) semiconductor nanocrystallites. J. Am. Chem. Soc. 115, 8706-8715 (1993).
25. Z. A. Peng, X. Peng, Formation of high-quality CdTe, CdSe, and CdS nanocrystals using CdO as precursor. J. Am. Chem. Soc. 123, 183-184 (2001).
26. R. Garcia-Rodriguez, M. P. Hendricks, B. M. Cossairt, H. Liu, J. S. Owen, Conversion reactions of cadmium chalcogenide nanocrystal precursors. Chem. Mater. 25, 1233-1249 (2013).
27. D. H. Son, S. M. Hughes, Y. Yin, A. P. Alivisatos, Cation exchange reactions in ionic nanocrystals. Science 306, 1009-1012 (2004).
28. L. De Trizio, L. Manna, Forging colloidal nanostructures via cation exchange reactions. Chem. Rev. 116, 10852-10887 (2016).
29. J. L. Fenton, B. C. Steimle, R. E. Schaak, Tunable intraparticle frameworks for creating complex heterostructured nanoparticle libraries. Science 360, 513-517 (2018).
30. F. Ma, K. A. Abboud, C. Zeng, Precision synthesis of a CdSe semiconductor nanocluster via cation exchange. Nat. Synth. 2, 949-959 (2023).
31. S. Htoon, M. F. C. Ladd, Crystallographic studies of dihalogenotetramethylethylenediamine complexes of zinc, cadmium, and mercury. IV: General crystallography and molecular geometry. J. Cryst. Mol. Struct. 6, 55-58 (1976).
32. R. G. Pearson, Absolute Electronegativity and Hardness: Application to Inorganic Chemistry. Inorg Chem 27, 734-740 (1988).
33. P. Paoletti, International union of pure and applied chemistry analytical chemistry division commission on equilibrium data formation of metal complexes with ethylenediamine: A critical survey of equilibrium constants, enthalpy and entropy values. Pure and Applied Chemistry 56, 491-522 (1984).
34. A. Deveson, S. Dehnen, D. Fenske, Syntheses and structures of four new copper(I)-selenium clusters: size dependence of the cluster on the reaction conditions. J. chem. Soc., Dalton Trans. 23, 4491-4497 (1997).
35. J. Gui, M. Ji, J. Liu, M. Xu, J. Zhang, H. Zhu, Phosphine-initiated cation exchange for precisely tailoring composition and properties of semiconductor nanostructures: old concept, new applications. Angew. Chem. Int. Ed. 54, 3683-3687 (2015).
36. L. R. Snyder, J. J. Kirkland, J. W. Dolan, “Appendix I: Properties of HPLC Solvents” in Introduction to Modern Liquid Chromatography (2010 John Wiley & Sons, Inc., 2009), pp. 879-886.
37. C. Gréboval, A. Chu, N. Goubet, C. Livache, S. Ithurria, E. Lhuillier, Mercury Chalcogenide Quantum Dots: Material Perspective for Device Integration. Chem. Rev. 121, 3627-3700 (2021).
38. A. M. Smith, S. Nie, Bright and Compact Alloyed Quantum Dots with Broadly Tunable Near-Infrared Absorption and Fluorescence Spectra through Mercury Cation Exchange. J. Am. Chem. Soc. 133, 24-26 (2011).
39. S. Keuleyan, E. Lhuillier, V. Brajuskovic, P. Guyot-Sionnest, Mid-infrared HgTe colloidal quantum dot photodetectors. Nat. Photonics 5, 489-493 (2011).
40. J. A. Dean, Ed., Lange's Handbook of Chemistry (McGraw-Hill, Inc., New York, ed. 15th, 1999).
41. O. Madelung, Ed., Semiconductors—Basic Data (Springer Berlin Heidelberg, Berlin, Heidelberg, 1996).
42. K.-U. Gawlik, L. Kipp, M. Skibowski, N. Orlowski, R. Manzke, HgSe: Metal or Semiconductor?Phys. Rev. Lett. 78, 3165-3168 (1997).
43. Y. Wang, Y. Zhou, Y. Zhang, W. E. Buhro, Magic-Size II-VI Nanoclusters as Synthons for Flat Colloidal Nanocrystals. Inorg. Chem. 54, 1165-1177 (2015).

### GENERAL REFERENCES

1. Kagan, C. R., Bassett, L. C., Murray, C. B. & Thompson, S. M. Colloidal quantum dots as platforms for quantum information science. Chem. Rev. 121, 3186-3233 (2021).
2. Kagan, C. R., Lifshitz, E., Sargent, E. H. & Talapin, D. v. Building devices from colloidal quantum dots. Science 353, 885-892 (2016).
3. Murray, C. B., Norris, D. J. & Bawendi, M. G. Synthesis and characterization of nearly monodisperse CdE (E=sulfur, selenium, tellurium) semiconductor nanocrystallites. J. Am. Chem. Soc. 115, 8706-8715 (1993).
4. Peng, Z. A. & Peng, X. Formation of high-quality CdTe, CdSe, and CdS nanocrystals using CdO as precursor. J. Am. Chem. Soc. 123, 183-184 (2001).
5. Efros, A. L. & Brus, L. E. Nanocrystal Quantum Dots: From Discovery to Modern Development. ACS Nano 15, 6192-6210 (2021).
6. Boles, M. A., Ling, D., Hyeon, T. & Talapin, D. v. The surface science of nanocrystals. Nat. Mater. 15, 141-153 (2016).
7. Kagan, C. R. & Murray, C. B. Charge transport in strongly coupled quantum dot solids. Nat. Nanotechnol. 10, 1013-1026 (2015).
8. Yu, W. W., Qu, L., Guo, W. & Peng, X. Experimental Determination of the Extinction Coefficient of CdTe, CdSe, and CdS Nanocrystals. Chem. Mater. 15, 2854-2860 (2003).
9. Jin, R., Zeng, C., Zhou, M. & Chen, Y. Atomically precise colloidal metal nanoclusters and nanoparticles: fundamentals and opportunities. Chem. Rev. 116, 10346-10413 (2016).
10. Zeng, C., Chen, Y., Kirschbaum, K., Lambright, K. J. & Jin, R. Emergence of hierarchical structural complexities in nanoparticles and their assembly. Science 354, 1580-1584 (2016).
11. Tran, N. T., Powell, D. R. & Dahl, L. F. Nanosized Pd₁₄₅(CO)ₓ(PEt₃)₃₀ containing a capped three-shell 145-atom metal-core geometry of pseudo icosahedral symmetry. Angew. Chem. Int. Ed. 39, 4121-4125 (2000).
12. Jadzinsky, P. D., Calero, G., Ackerson, C. J., Bushnell, D. A. & Kornberg, R. D. Structure of a thiol monolayer-protected gold nanoparticle at 1.1 Å resolution. Science 318, 430-433 (2007).
13. Garcia-Rodriguez, R., Hendricks, M. P., Cossairt, B. M., Liu, H. & Owen, J. S. Conversion reactions of cadmium chalcogenide nanocrystal precursors. Chem. Mater. 25, 1233-1249 (2013).
14. Owen, J. The coordination chemistry of nanocrystal surfaces. Science 347, 615-616 (2015).
15. Jasieniak, J. & Mulvaney, P. From Cd-Rich to Se-Rich—the Manipulation of CdSe Nanocrystal Surface Stoichiometry. J. Am. Chem. Soc. 129, 2841-2848 (2007).
16. Wei, H. H.-Y. et al. Colloidal Semiconductor Quantum Dots with Tunable Surface Composition. Nano Lett. 12, 4465-4471 (2012).
17. B., W. C. et al. Chemically reversible isomerization of inorganic clusters. Science 363, 731-735 (2019).
18. Lee, G. S. H. et al. [S₄Cd₁₇(SPh)₂₃]²⁻, the first member of a third series of tetrahedral [S_{W}M_{X}(SR)_{y}]^{z-} clusters. J. Am. Chem. Soc. 110, 4863-4864 (1988).
19. Herron, N., Calabrese, J. C., Farneth, W. E. & Wang, Y. Crystal structure and optical properties of Cd₃₂S₁₄(SC₆H₅)₃₆. DMF₄, a cluster with a 15 angstrom CdS core. Science 259, 1426-1428 (1993).
20. Vossmeyer, T., Reck, G., Schulz, B., Katsikas, L. & Weller, H. Double-layer superlattice structure built up of Cd₃₂S₁₄(SCH₂CH(OH)CH₃)₃₆.4H₂O clusters. J. Am. Chem. Soc. 117, 12881-12882 (1995).
21. Soloviev, V. N., Eichhöfer, A., Fenske, D. & Banin, U. Size-dependent optical spectroscopy of a homologous series of CdSe cluster molecules. J. Am. Chem. Soc. 123, 2354-2364 (2001).
22. Beecher, A. N. et al. Atomic structures and gram scale synthesis of three tetrahedral quantum dots. J. Am. Chem. Soc. 136, 10645-10653 (2014).
23. Gary, D. C. et al. Single-crystal and electronic structure of a 1.3 nm indium phosphide nanocluster. J. Am. Chem. Soc. 138, 1510-1513 (2016).
24. Zeng, C. Precision at the nanoscale: on the structure and property evolution of gold nanoclusters. Pure Appl. Chem. 90, 1409-1428 (2018).
25. Anderson, P. W. More is different. Science 177, 393-396 (1972).
26. Yin, Y. & Alivisatos, A. P. Colloidal nanocrystal synthesis and the organic-inorganic interface. Nature 437, 664-670 (2005).
27. Silvera Batista, C. A., Larson, R. G. & Kotov, N. A. Nonadditivity of nanoparticle interactions. Science 350, (2015).
28. de Trizio, L. & Manna, L. Forging colloidal nanostructures via cation exchange reactions. Chem. Rev. 116, 10852-10887 (2016).
29. Rivest, J. B. & Jain, P. K. Cation exchange on the nanoscale: an emerging technique for new material synthesis, device fabrication, and chemical sensing. Chem. Soc. Rev. 42, 89-96 (2013).
30. Beberwyck, B. J., Surendranath, Y. & Alivisatos, A. P. Cation exchange: A versatile tool for nanomaterials synthesis. J. Phys. Chem. C 117, 19759-19770 (2013).
31. Gupta, S., Kershaw, S. v. & Rogach, A. L. 25th Anniversary Article: Ion Exchange in Colloidal Nanocrystals. Adv. Mater. 25, 6923-6944 (2013).
32. Zeng, C., Chen, Y., Das, A. & Jin, R. Transformation Chemistry of Gold Nanoclusters: From One Stable Size to Another. J. Phys. Chem. Lett. 6, 2976-2986 (2015).
33. Zeng, C., Liu, C., Pei, Y. & Jin, R. Thiol Ligand-Induced Transformation of Au₃₃(SC₂H₄Ph)₂₄ to Au₃₆(SPh-t-Bu)₂₄. ACS Nano 7, 6138-6145 (2013).
34. Singer, J. & Faeth, P. A. The orientation of Cu₂S formed on single crystal CdS. App. Phys. Lett. 11, 130-132 (1967).
35. Cook, W. R., Shiozawa, L. & Augustine, F. Relationship of copper sulfide and cadmium sulfide phases. J. Appl. Phys. 41, 3058-3063 (1970).
36. Szeto, W. & Somorjai, G. A. Optical Study of Copper Diffusion in Cadmium Sulfide Single Crystals. J. Chem. Phys. 44, 3490-3495 (1966).
37. Son, D. H., Hughes, S. M., Yin, Y. & Alivisatos, A. P. Cation exchange reactions in ionic nanocrystals. Science 306, 1009-1012 (2004).
38. Mews, A., Eychmueller, A., Giersig, M., Schooss, D. & Weller, H. Preparation, characterization, and photophysics of the quantum dot quantum well system cadmium sulfide/mercury sulfide/cadmium sulfide. J. Phys. Chem. 98, 934-941 (1994).
39. Camargo, P. H. C., Lee, Y. H., Jeong, U., Zou, Z. & Xia, Y. Cation Exchange: A Simple and Versatile Route to Inorganic Colloidal Spheres with the Same Size but Different Compositions and Properties. Langmuir 23, 2985-2992 (2007).
40. Luther, J. M., Zheng, H., Sadtler, B. & Alivisatos, A. P. Synthesis of PbS nanorods and other ionic nanocrystals of complex morphology by sequential cation exchange reactions. J. Am. Chem. Soc. 131, 16851-16857 (2009).
41. Li, H. et al. Sequential cation exchange in nanocrystals: Preservation of crystal phase and formation of metastable phases. Nano Lett. 11, 4964-4970 (2011).
42. Ha, D.-H. et al. Solid-Solid phase transformations induced through cation exchange and strain in 2D heterostructured copper sulfide nanocrystals. Nano Lett. 14, 7090-7099 (2014).
43. Mu, L., Wang, F., Sadtler, B., Loomis, R. A. & Buhro, W. E. Influence of the Nanoscale Kirkendall Effect on the Morphology of Copper Indium Disulfide Nanoplatelets Synthesized by Ion Exchange. ACS Nano 9, 7419-7428 (2015).
44. Fenton, J. L., Steimle, B. C. & Schaak, R. E. Tunable intraparticle frameworks for creating complex heterostructured nanoparticle libraries. Science 360, 513-517 (2018).
45. Steimle, B. C., Fenton, J. L. & Schaak, R. E. Rational construction of a scalable heterostructured nanorod megalibrary. Science 367, 418-424 (2020).
46. Zhao, Q. et al. Enhanced carrier transport in strongly coupled, epitaxially fused CdSe nanocrystal solids. Nano Lett. 21, 3318-3324 (2021).
47. Stein, J. L. et al. Cation Exchange Induced Transformation of InP Magic-Sized Clusters. Chem. Mater. 29, 7984-7992 (2017).
48. White, S. L., Banerjee, P., Chakraborty, I. & Jain, P. K. Ion exchange transformation of magic-sized clusters. Chem. Mater. 28, 8391-8398 (2016).
49. Deveson, A., Dehnen, S. & Fenske, D. Syntheses and structures of four new copper(I)-selenium clusters: size dependence of the cluster on the reaction conditions. J. Chem. Soc., Dalton Trans. 4491-4498 (1997).
50. Gui, J. et al. Phosphine-initiated cation exchange for precisely tailoring composition and properties of semiconductor nanostructures: old concept, new applications. Angew. Chem. Int. Ed. 54, 3683-3687 (2015).
51. Fuhr, O., Dehnen, S. & Fenske, D. Chalcogenide clusters of copper and silver from silylated chalcogenide sources. Chem. Soc. Rev. 42, 1871-1906 (2013).
52. Luther, J. M., Jain, P. K., Ewers, T. & Alivisatos, A. P. Localized surface plasmon resonances arising from free carriers in doped quantum dots. Nat. Mater. 10, 361-366 (2011).
53. Hagen, K. S., Stephan, D. W. & Holm, R. H. Metal ion exchange reactions in cage molecules: the systems [M₄₋ₙM′ₙ(SC₆H₅)₁₀]²⁻ (M, M′=Fe(II), Co(II), Zn(II), Cd(II)) with adamantane-like stereochemistry and the structure of [Fe₄(SC₆H₅)₁₀]²⁻. Inorg. Chem. 21, 3928-3936 (1982).
54. Zeng, C. et al. Controlling magnetism of Au₁₃₃(TBBT)₅₂ nanoclusters at single electron level and implication for nonmetal to metal transition. Chem. Sci. 10, 9684-9691 (2019).
55. Garcia-Rodríguez, R. & Liu, H. Solution structure of cadmium carboxylate and its implications for the synthesis of cadmium chalcogenide nanocrystals. Chem. Commun. 49, 7857 (2013).
56. Kessler, J. M. et al. Comparison of solid-state and solution structures of (R₃P)₂CdX₂, (Et₃P)₂Cd₂X₄ and (Bu₃P)₃Cd₂X₄ complexes. Magn. Reson. Chem. 29, S94-S105 (1991).
57. Kudera, S. et al. Sequential growth of magic-size CdSe nanocrystals. Adv. Mater. 19, 548-552 (2007).
58. Kasuya, A. et al. Ultra-stable nanoparticles of CdSe revealed from mass spectrometry. Nat. Mater. 3, 99-102 (2004).
59. Chen, O. et al. Surface-Functionalization-Dependent Optical Properties of II-VI Semiconductor Nanocrystals. J. Am. Chem. Soc. 133, 17504-17512 (2011).
60. Bootharaju, M. S. et al. Structure of a subnanometer-sized semiconductor Cd₁₄Se₁₃ cluster. Chem 8, 2978-2989 (2022).
61. Khadka, C. B., Eichhöfer, A., Weigend, F. & Corrigan, J. F. Zinc Chalcogenolate Complexes as Precursors to ZnE and Mn/ZnE (E=S, Se) Clusters. Inorg. Chem. 51, 2747-2756 (2012).
62. Wang, Y. et al. Isolation of the Magic-Size CdSe Nanoclusters [(CdSe)₁₃(n-octylamine)₁₃] and [(CdSe)₁₃(oleylamine)₁₃]. Angew. Chem. Int. Ed. 51, 6154-6157 (2012).
63. del Ben, M., Havenith, R. W. A., Broer, R. & Stener, M. Density Functional Study on the Morphology and Photoabsorption of CdSe Nanoclusters. J. Phys. Chem. C 115, 16782-16796 (2011).
64. Shiang, J. J., Kadavanich, A. v., Grubbs, R. K. & Alivisatos, A. P. Symmetry of annealed wurtzite CdSe nanocrystals: assignment to the C₃v point group. J. Phys. Chem. 99, 17417-17422 (1995).
65. Nevers, D. R., Williamson, C. B., Hanrath, T. & Robinson, R. D. Surface chemistry of cadmium sulfide magic-sized clusters: a window into ligand-nanoparticle interactions. Chem. Commun. 53, 2866-2869 (2017).
66. Mocatta, D. et al. Heavily doped semiconductor nanocrystal quantum dots. Science 332, 77-81 (2011).
67. Smith, A. M., Lane, L. A. & Nie, S. Mapping the spatial distribution of charge carriers in quantum-confined heterostructures. Nat. Commun. 5, 4506 (2014).
68. Lange's Handbook of Chemistry. (McGraw-Hill, Inc., 1999).
69. Goodsell, D. S. The Machinery of Life. (Springer New York, 2009).
70. Detty, M. R. & Seidler, M. D. Bis(trialkylsilyl) chalcogenides. 1. Preparation and reduction of group VIA oxides. J. Org. Chem. 47, 1354-1356 (1982).
71. J. A. Dean, Ed., Lange's Handbook of Chemistry (McGraw-Hill, Inc., New York, ed. 15th, 1999).

1. A method for precision synthesis of a reaction product nanocluster, wherein the reaction product is produced by reacting a template cluster and a coordination complex according to the following Cat¹-An¹-L¹+Cat²-X²-L²+L³→Cat²-An¹-X²-L²
wherein the First reagent, Cat¹-An¹-L¹, is a template nanocluster
wherein the Second reagent, Cat²-X²-L², is a metal-ligand coordination complex
wherein L3 is an optional reagent and is a soft-base ligand (such as phosphine), which is optionally included in the reaction to facilitate extraction of a soft cation (such as Cu⁺) when the soft-base ligand is not present in the Cat²-X²-L² coordination complex, and
wherein Cat²-An¹-X²-L² is a product nanocluster.

2. The method of claim 1, wherein Cat¹ is Cu(I) or Ag(I), An¹ is selected from S, Se, or Te, and L¹ is a surface ligand, wherein Cat² is selected from Cd²⁺, Zn²⁺, Hg²⁺, Pb²⁺, or other metal cations, X² is selected from halides (Cl⁻, Br⁻, I⁻), carboxylates (—O₂CR, R is R being an alkyl, alkenyl or aryl group), or other anionic ligands, and L² is a neutral surface ligand.

3. The method of claim 1, wherein L¹ is the original ligand that is carried in the template nanocluster, wherein L¹ is, optionally, PEt₂Ph.

4. The method of claim 1, wherein L² is selected from a phosphine, amine, carbene, alcohol, or other neutral ligands, wherein L² is, optionally, is PPr₃, NR₃ (R is various CₓH_{y} group, including H), multidentate ligands (R₂N—CₓH_{y}—NR₂), or optionally, (CH₃)₂NCH₂CH₂N(CH₃)₂.

5. The method of claim 1, wherein X² is selected from a halide, carboxylate, or other negatively charged ligands, wherein X² is, optionally, Cl⁻, Br⁻, I⁻, ⁻O₂CR, ⁻SR (R is an alkyl, alkenyl or aryl group).

6. The method of claim 1, wherein the template nanocluster is Cu₂₆Se₁₃(PEt₂Ph)₁₄.

7. The method of claim 1, wherein the coordination complex is CdI₂(PPr₃)₂.

8. The method of claim 7, wherein the nanocluster reaction product is Cd₂₆Se₁₇I₁₈(PPr₃)₁₀.

9. The method of claim 1, wherein the template nanocluster and/or coordination complex and/or nanocluster reaction product comprise at least one dopant.

10. The method of claim 8, wherein the dopant comprises Mn²⁺.

11. A nanocluster comprising Cat²-An¹-X²-L², wherein Cat² is selected from Cd²⁺, Zn²⁺, Hg²⁺, Pb²⁺ or other metal cations, wherein An¹ is selected from S, Se, or Te, wherein X² is selected from halides (Cl⁻, Br⁻, I⁻), carboxylates (⁻O₂CR, R is various CₓH_{y} group), or other anionic ligands, and wherein L² is a neutral surface ligand.

12. The nanocluster of claim 11, wherein L² is selected from a phosphine, amine, carbene, alcohol, or other neutral ligands, wherein L² is, optionally, is PPr₃, NR₃ (R is various CₓH_{y} group, including H), multidentate ligands (R₂N—CₓH_{y}—NR₂).

13. The nanocluster of claim 11, wherein the nanocluster comprises a size of 0.5-5 nm.

14. The nanocluster of claim 11, wherein the nanocluster comprises optionally a dopant cation.

15. The nanocluster of claim 14, wherein the dopant comprises Mn²⁺.

16. The nanocluster of claim 11, wherein the nanocluster is comprised of Cd₂₆Se₁₇I₁₈(PPr₃)₁₀, Zn₁₄Se₁₃L₆, Cd₁₄Se₁₃L₆, Hg₁₄Se₁₃L₆, where L is (CH₃)₂NCH₂CH₂N(CH₃)₂.

17. The nanocluster of claim 11 comprising a shape selected from tetrahedron, sphere, ellipsoidal, or triangular plate.

18. A nanocluster produced by the method of claim 1.

19. A solar cell comprising a plurality of nanoclusters according claim 1.

20. A light-emitting diode comprising a plurality of nanoclusters according to claim 1.
